(19) United States
(12) Patent Application Publication
(10) Pub. No.: US 2024/0247187 A1
(43) Pub. Date: Jul. 25, 2024

(54) THERMALLY ACTIVATED DELAYED FLUORESCENT PALLADIUM (II) COMPLEXES FOR OLED APPLICATIONS

(71) Applicants: Versitech Limited, Hong Kong (CN); Hong Kong Quantum AI Lab Limited, Hong Kong (CN)

(72) Inventors: Chi-Ming Che, Hong Kong (CN); Man-Ki Sit, Hong Kong (CN); Tsz-Lung Lam, Hong Kong (CN); Gang Cheng, Hong Kong (CN)

(21) Appl. No.: 18/563,286

(22) PCT Filed: May 31, 2022
(86) PCT No.: PCT/CN2022/096226

§ 371 Date: Nov. 21, 2023

Related U.S. Application Data
(60) Provisional application No. 63/195,142, filed on May 31, 2021.

(51) Int. Cl. C09K 11/06; H10K 50/11; H10K 85/30; H10K 101/10; H10K 101/20; H10K 102/00

(52) U.S. Cl. CPC C09K 11/06; H10K 50/11; H10K 85/341; C09K 2211/1029; C09K 2211/185; H10K 2101/10; H10K 2101/20; H10K 2102/351

(57) ABSTRACT

Described herein are compounds containing palladium(II), as the central metal atom, and tetradentate [N\hat{ }C\hat{ }C\hat{ }N] ligands. The compounds are charge neutral, and feature a donor-acceptor structure where a pendant substituted amino group (such as unsubstituted diphenylamine or substituted diphenylamine) and a heteroaryl group (such as pyridine group) serve as donor and acceptor, respectively. This donor-acceptor structure introduces a set of low-energy singlet and triplet charge-transfer excited states with small energy separation allowing for efficient thermally activated delayed fluorescence to take place.

### CROSS-REFERENCE TO RELATED APPLICATION

This application claims benefit of and priority to U.S. Provisional Application No. 63/195,142 filed May 31, 2021, which is incorporated herein by reference in its entirety.

### FIELD OF THE INVENTION

The disclosed invention is generally in the field of luminescent palladium(II) complexes, particularly thermally activated delayed fluorescence palladium(II) complexes containing cyclometalating tetradentate ligands, and their use in organic light-emitting devices (OLEDs).

### BACKGROUND OF THE INVENTION

Transition metal complexes have gained significant interest in commercial and academic settings as molecular probes, catalysts, and luminescent materials. As luminescent materials, transition metal complexes are increasingly being explored as potential alternatives to pure organic-based materials due to their potential for improved luminescence efficiency and device stability, compared to pure organic-based materials.

There has been growing attention and efforts in adopting luminescent d⁸ planar metal complexes (e.g., Pt(II) and Au(III) complexes) as OLED emitters. It is believed that these complexes have favorable horizontal emitting-dipole orientation in solid state and when dispersed in solid matrix, leading to higher out-coupling efficiencies than conventional Ir(III) emitters. In this regard, the development of luminescent Pd(II) complexes as OLED emitters has been largely overshadowed by their heavier Pt(II) counterparts. One reason for the little attention paid to Pd(II) complexes is their general inferior photoluminescence quantum efficiencies (PLQY) (<10%) at room temperature and intrinsically small radiative rate constants (kᵣ) (in the range of 10³ s⁻¹), which largely limit device efficiency and operational stability.

Recent studies have shown that the PLQY of phosphorescent Pd(II) complexes could be improved to >0.50 by deploying rigid tetradentate ligand scaffolds (Zhu, et al., Adv. Mater. 2015, 27, 2533-2537; Chow, et al., Chem. Sci., 2016, 7, 6083-6098; Li, et al., Inorg. Chem. 2020, 59, 18, 13502-13516). Nonetheless, boosting the kᵣ of Pd(II) emitters to a practical level, such as 10⁵ s⁻¹, remains a daunting challenge as this class of phosphors, in contrast to the Pt(II) counterparts, are bound to have emissive excited states with minute metal character that fails to accelerate the spin-forbidden radiative process. Accordingly, there remains a need to develop improved and efficient transition metal complexes so that OLED-containing products can have improved efficiencies.

Therefore, is an object of the present invention to provide new and superior luminescent transition metal complexes containing a palladium(II) center surrounded by a tetradentate cyclometalating ligand.

### SUMMARY OF THE INVENTION

Described are charge neutral Pd(II) compounds, supported by tetradentate [N\hat{ }C\hat{ }C\hat{ }N] ligands featuring a donor-acceptor structure where a pendant substituted amino group (such as a substituted diarylamine group or unsubstituted diarylamine group) and a heteroaryl group (such as a pyridine group) serve as donor and acceptor, respectively. This donor-acceptor structure introduces a set of low-energy singlet and triplet charge-transfer excited states with small energy separation allowing for efficient thermally activated delayed fluorescence to take place.

The compounds have a structure:

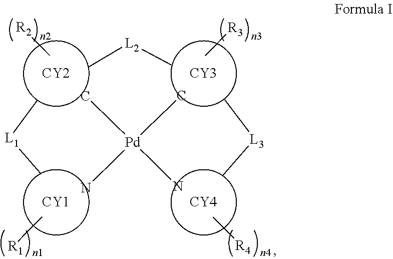

wherein:
the compound has an overall neutral, negative, or positive charge,
CY1 and CY4 are independently unsubstituted heteroaryl, substituted heteroaryl, unsubstituted polyheteroaryl, substituted polyheteroaryl, unsubstituted C₂-C₂₀ heterocyclyl, or substituted C₂-C₂₀ heterocyclyl,
CY2 and CY3 are independently unsubstituted aryl, substituted aryl, unsubstituted polyaryl, substituted polyaryl, unsubstituted heteroaryl, substituted heteroaryl, unsubstituted polyheteroaryl, substituted polyheteroaryl, unsubstituted C₃-C₂₀ cycloalkyl, substituted C₂-C₂₀cycloalkyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl,
each R₁, R₂, R₃, and R₄ is independently, absent, hydrogen, substituted amino, unsubstituted amino, substituted alkyl, unsubstituted alkyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, wherein at least one of R₁, R₂, R₃, and R₄ is present and is an electron donating group,
n1, n2, n3, and n4 are independently an integer between zero and 10, inclusive, with the proviso that at least one of n1, n2, n3, and n4 is not zero, and
L₁, L₂, and L₃ are independently a bond (single, double, or triple), absent, oxygen, sulfur, substituted amino, unsubstituted amino, unsubstituted alkylene, substituted alkylene, unsubstituted alkyl, substituted alkyl, substituted carbonyl, unsubstituted carbonyl, substituted amido, unsubstituted amido, substituted sulfonyl, unsubstituted sulfonyl, substituted sulfonic acid, unsubstituted sulfonic acid, substituted phosphoryl, unsubstituted phosphoryl, substituted phosphonyl, or unsubstituted phosphonyl.

In some forms, the compounds have a structure:

a structure:

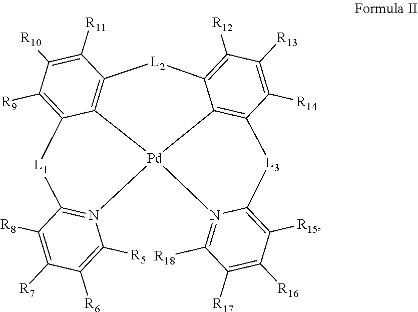

wherein:
R₅-R₈ are independently selected from R₁ listed above for Formula I,
R₉-R₁₁ are independently selected from R₂ listed above for Formula I,
R₁₂-R₁₄ are independently selected from R₃ listed above for Formula I, and
R₁₅-R₁₈ are independently selected from R₄ listed above for Formula I,
with proviso that at least one of R₉-R₁₁ or R₁₂-R₁₄ is an electron donating group. The electron donating group can be, independently, a substituted diarylamine, unsubstituted diarylamine, a substituted diheteroarylamine, unsubstituted diheteroarylamine, substituted arylamine, unsubstituted arylamine, substituted heteroarylamine, unsubstituted heteroarylamine, substituted di-C₃-C₂₀ cyclylamine, unsubstituted di-C₃-C₂₀ cyclylamine, substituted C₃-C₂₀ cyclylamine, unsubstituted C₃-C₂₀ cyclylamine, substituted diheterocyclylamine, unsubstituted diheterocyclylamine, substituted heterocyclylamine, unsubstituted heterocyclylamine, substituted heteroaryl, unsubstituted heteroaryl, substituted polyheteroaryl, unsubstituted polyheteroaryl, substituted heterocyclyl, unsubstituted heterocyclyl, substituted polyheterocyclyl, unsubstituted polyheterocyclyl, substituted dialkylamine, unsubstituted dialkylamine, substituted alkylamine, unsubstituted alkylamine, or —NH₂. In some forms of Formula II, at least one of R₉-R₁₁ or R₁₂-R₁₄ has a structure selected from:

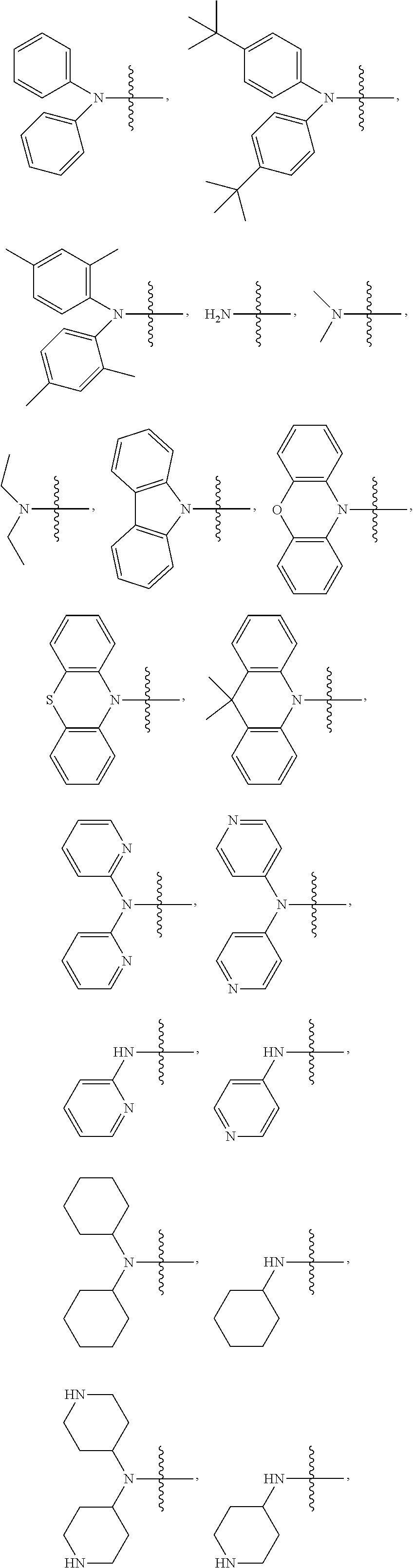

or a combination thereof. In some forms of Formula II, at least one of R₉-R₁₁ or R₁₂-R₁₄ has a structure selected from:

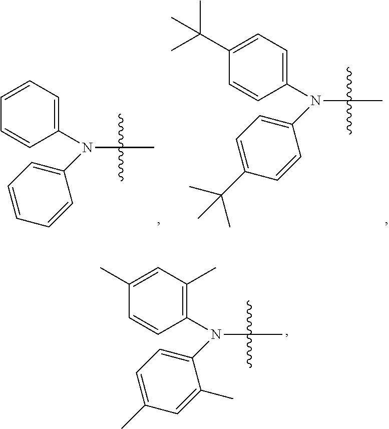

or a combination thereof.

In some forms, the compounds have a structure:

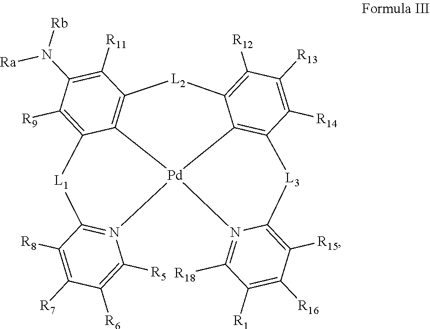

wherein:
R₅-R₈ are independently selected from R₁ listed above for Formula I,
R₉ and R₁ are independently selected from R₂ listed above for Formula I,
R₁₂-R₁₄ are independently selected from R₃ listed above for Formula I, and
R₁₅-R₁₈ are independently selected from R₄ listed above for Formula I,
Rₐ and R_{b} are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl, or —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl. In some forms of Formula III, —NRₐR_{b} can be a substituted diarylamine, unsubstituted diarylamine, substituted arylamine, unsubstituted arylamine, substituted heteroarylamine, unsubstituted heteroarylamine, substituted di-C₃-C₂₀ cyclylamine, unsubstituted di-C₃-C₂₀ cyclylamine, substituted C₃-C₂₀ cyclylamine, unsubstituted C₃-C₂₀ cyclylamine, substituted diheterocyclylamine, unsubstituted diheterocyclylamine, substituted heterocyclylamine, unsubstituted heterocyclylamine, substituted heteroaryl, unsubstituted heteroaryl, substituted polyheteroaryl, unsubstituted polyheteroaryl, substituted heterocyclyl, unsubstituted heterocyclyl, substituted polyheterocyclyl, unsubstituted polyheterocyclyl, substituted dialkylamine, unsubstituted dialkylamine, substituted alkylamine, unsubstituted alkylamine, or —NH₂. In some forms of Formula III, —NRₐR_{b} has a structure:

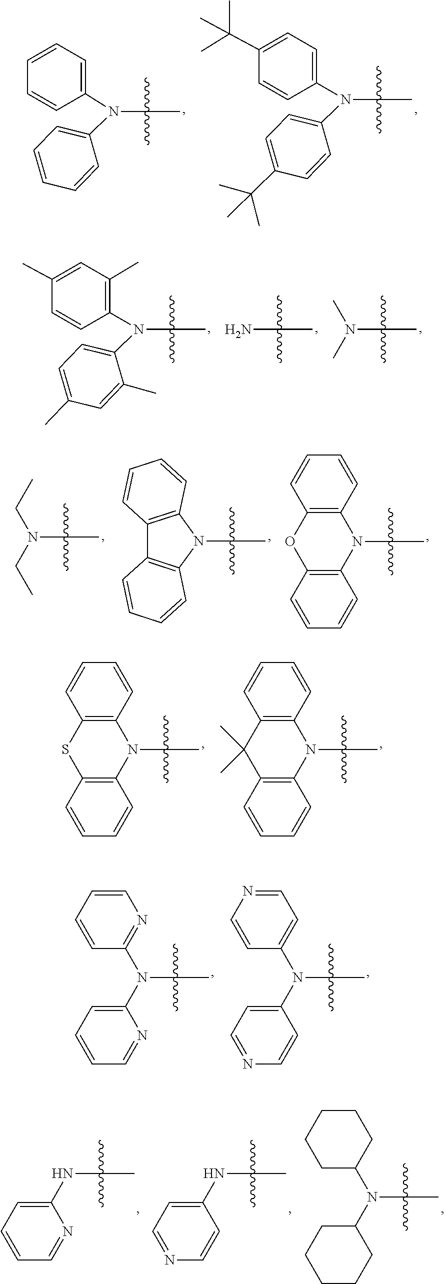

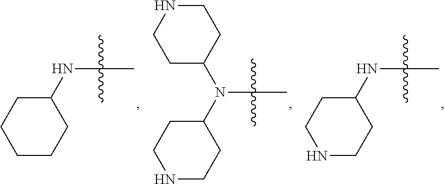 [SMILES: *NC1CCCCC1 ; *N(C1CCNCC1)C1CCNCC1 ; *NC1CCNCC1]

or a combination thereof. In some forms of Formula III, —NRₐR_{b} has a structure selected from:

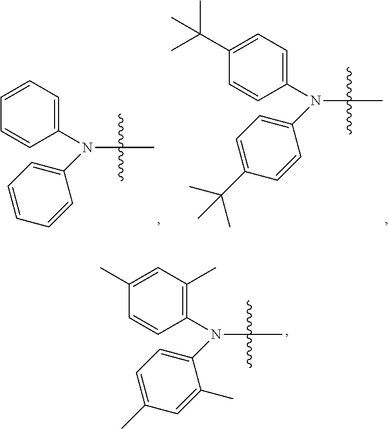

or a combination thereof.

The compounds can be included in organic light-emitting devices, for use in commercial applications.

### BRIEF DESCRIPTION OF THE DRAWINGS

FIGS. 1A-1D are line graphs showing electroluminescent data for an OLED fabricated with Pd04. The film includes: ITO/HAT-CN (5 nm)/TAPC (40 nm)/TCTA (10 nm)/Pd04:PPF (10 nm)/TmPyPb (50 nm)/LiF (1.2 nm)/Al (100 nm). The % wt/wt of Pd04 in OLEDs were 3% wt/wt, 6% wt/wt, or 12% wt/wt.

FIGS. 2A-2D are line graphs showing electroluminescent data for an OLED fabricated with Pd04. The film includes: ITO/HAT-CN (5 nm)/TAPC (40 nm)/TCTA (10 nm)/Pd04:PPF (10 nm)/DBF (10 nm)/TmPyPb (40 nm)/LiF (1.2 nm)/Al (100 nm). The % wt/wt of Pd04 in OLEDs were 16% wt/wt or 32% wt/wt.

FIGS. 3A-3D are line graphs showing electroluminescent data for an OLED fabricated with Pd04. The film includes: ITO/HAT-CN (5 nm)/TAPC (40 nm)/CCP (10 nm)/Pd04:PPF (10 nm)/PFF (10 nm)/TmPyPb (40 nm)/LiF (1 nm)/Al (100 nm). The % wt/wt of Pd04 in OLEDs were 4% wt/wt, 8% wt/wt, or 16% wt/wt.

FIGS. 4A-4D are line graphs showing electroluminescent data for an OLED fabricated with Pd05. The film includes: ITO/HAT-CN (5 nm)/TAPC (40 nm)/CCP (10 nm)/Pd05:PPF (10 nm)/PPF (10 nm)/TmPyPb (40 nm)/Liq (2 nm)/Al (100 nm). The % wt/wt of Pd05 in OLEDs were 4% wt/wt, 10% wt/wt, or 20% wt/wt.

FIGS. 5A-5D are line graphs showing electroluminescent data for an OLED fabricated with Pd05. The film includes: ITO/HAT-CN (5 nm)/TAPC (40 nm)/CCP (10 nm)/Pd05:PPF (10 nm)/PFF (10 nm)/TmPyPb (40 nm)/Liq (2 nm)/Al (100 nm). The % wt/wt of Pd05 in OLEDs were 4% wt/wt, 8% wt/wt, or 16% wt/wt.

FIGS. 6A and 6B-6E are a crystal structure and line graphs, respectively, with FIGS. 6B-6E showing electroluminescent data for an OLED fabricated with Pd07. The film includes: ITO/HAT-CN (5 nm)/TAPC (40 nm)/TCTA (10 nm)/Pd07:PPF (10 nm)/DBF(10 nm)/TmPyPb (50 nm)/Liq (2 nm)/Al (100 nm). The % wt/wt of Pd07 in OLEDs were 4% wt/wt, 10% wt/wt, or 14% wt/wt.

FIGS. 7A-7D are line graphs showing electroluminescent data for an OLED fabricated with Pd07. The film includes: ITO/HAT-CN (5 nm)/TAPC (40 nm)/CCP (10 nm)/Pd07:PPF (10 nm)/PFF (10 nm)/TmPyPb (40 nm)/Liq (1.2 nm)/Al (100 nm). The % wt/wt of Pd07 in OLEDs were 4% wt/wt, 8% wt/wt, or 16% wt/wt.

FIGS. 8A-8D are line graphs showing electroluminescent data for an OLED fabricated with Pd08. The film includes: ITO/HAT-CN (5 nm)/TAPC (40 nm)/CCP (10 nm)/Pd08:PPF (10 nm)/PFF (10 nm)/TmPyPb (40 nm)/Liq (2 nm)/Al (100 nm). The % wt/wt of Pd08 in OLEDs were 4% wt/wt, 8% wt/wt, or 16% wt/wt.

FIGS. 9A-9D are line graphs showing electroluminescent data for an OLED fabricated with Pd02. The film includes: ITO/HAT-CN (5 nm)/TAPC (40 nm)/TCTA (10 nm)/Pd02:DBF (10 nm)/TmPyPb (50 nm)/LiF (1.2 nm)/Al (100 nm). The % wt/wt of Pd02 in OLEDs were 4% wt/wt or 10% wt/wt.

FIGS. 10A-10D are line graphs showing electroluminescent data for an OLED fabricated with Pd05:v-DABNA. The film includes: ITO/HAT-CN (5 nm)/TAPC (40 nm)/CCP (10 nm)/Pd05:v-DABNA:PPF (20 nm)/PFF (10 nm)/TmPyPb (40 nm)/LiF (1.2 nm)/Al (100 nm). The % wt/wt of Pd05:v-DABNA in OLEDs were 10% wt/wt:1% wt/wt, 20% wt/wt:1% wt/wt.

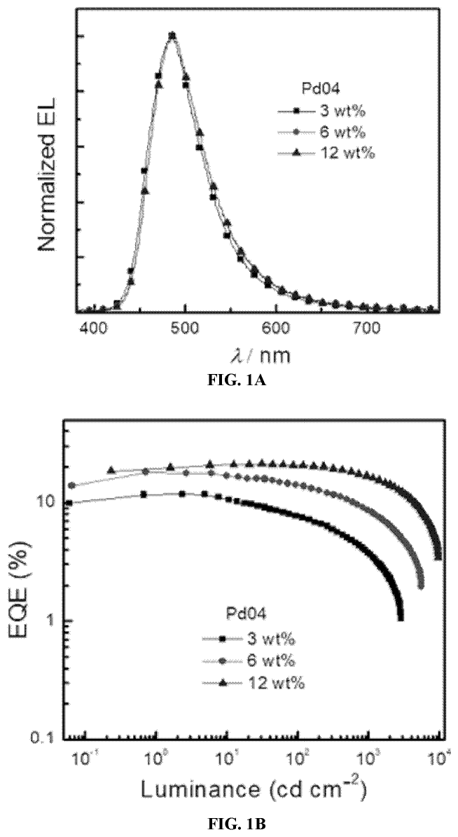

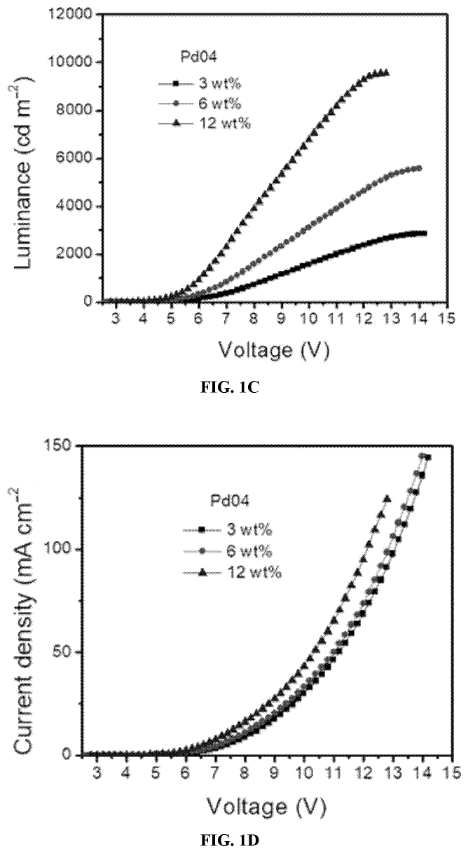

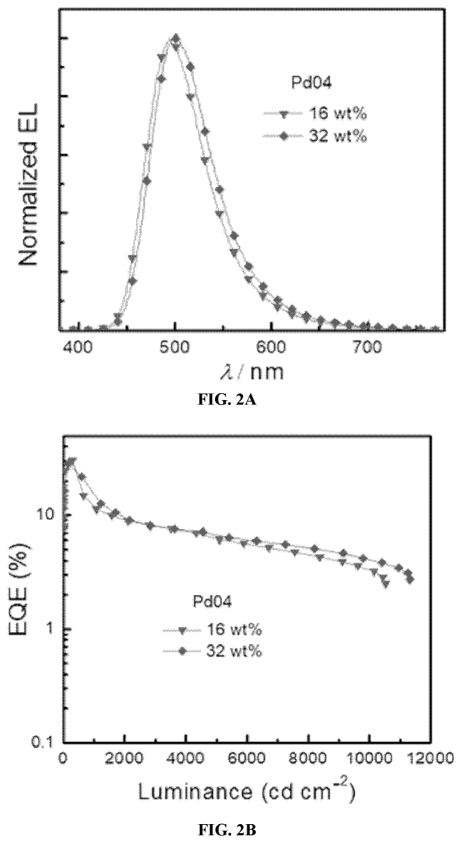

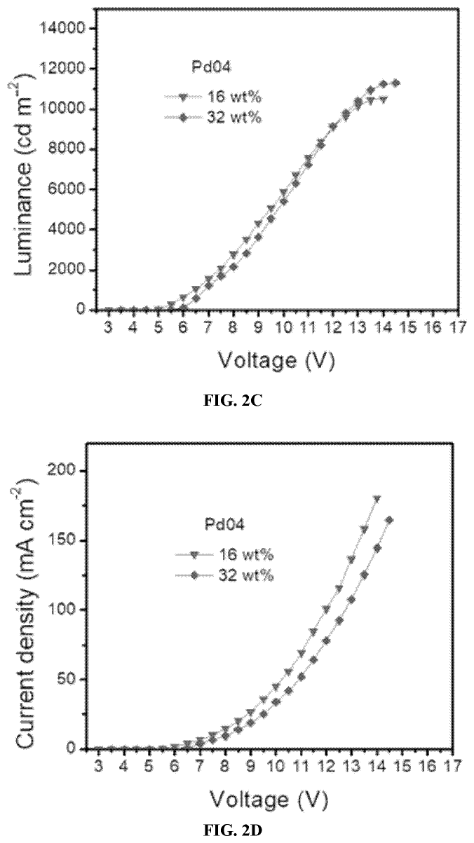

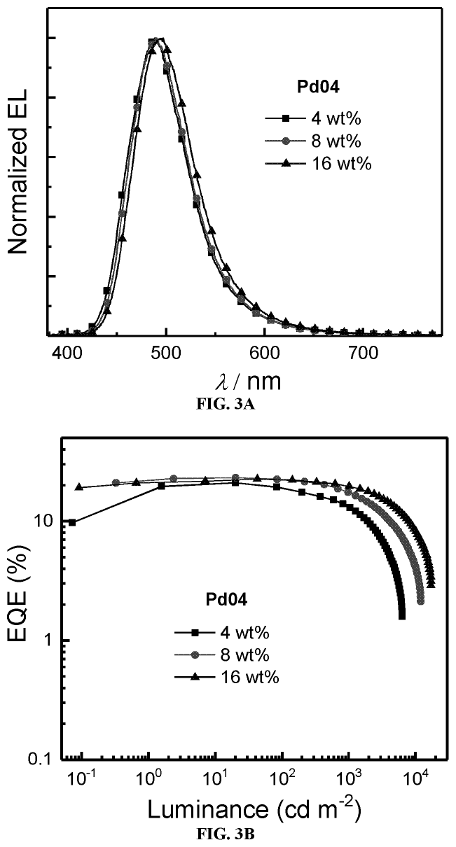

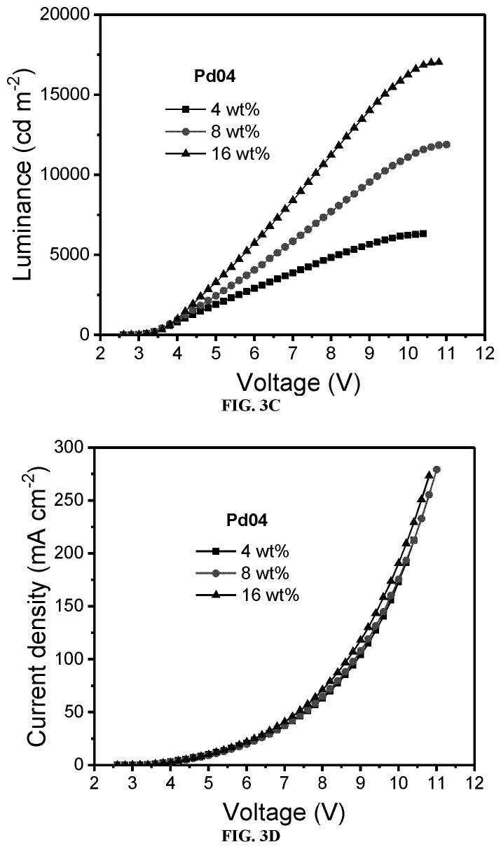

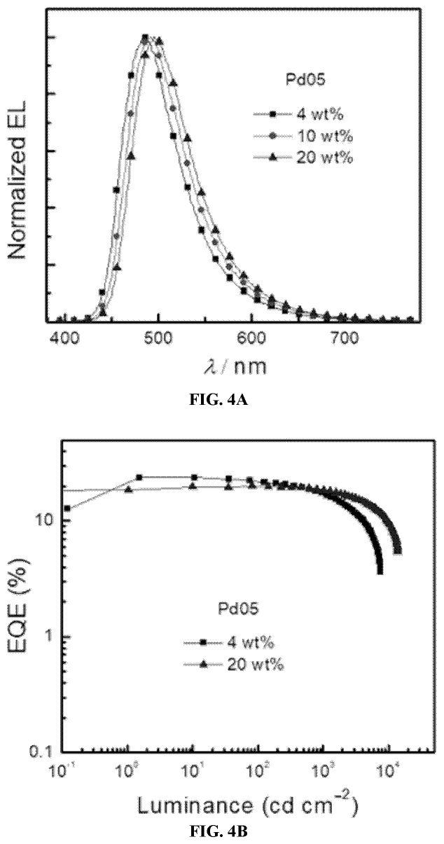

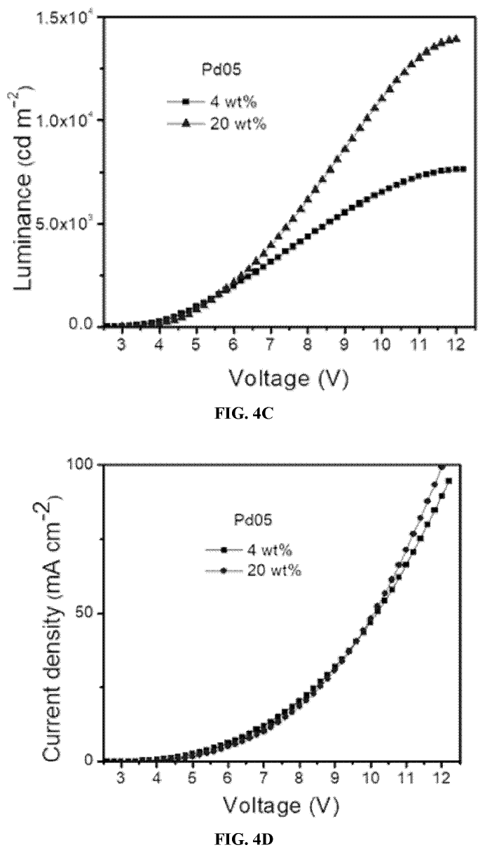

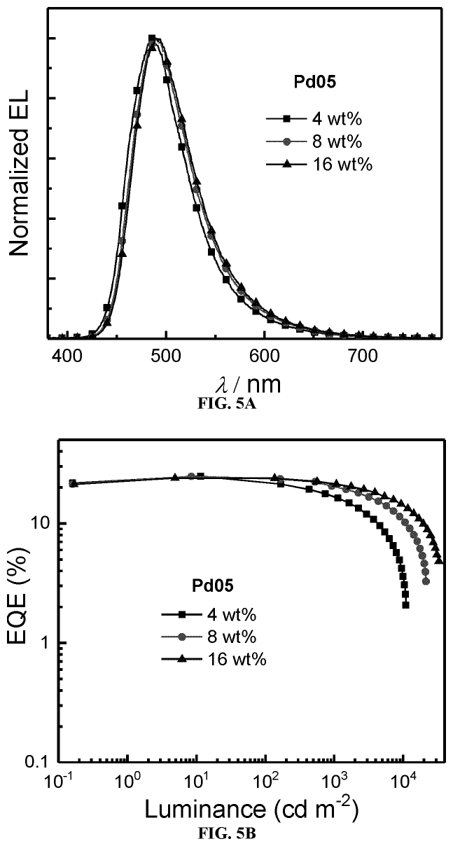

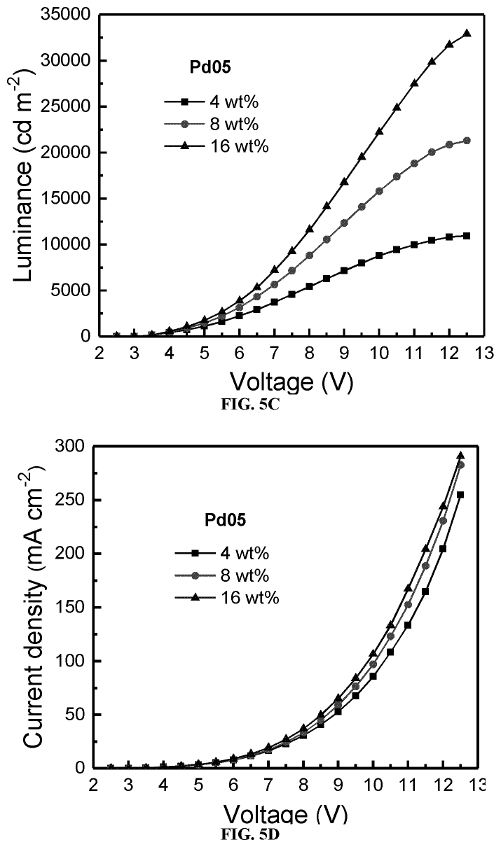

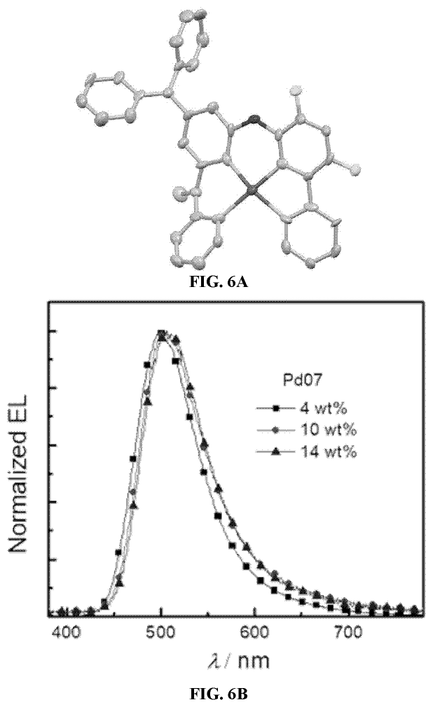

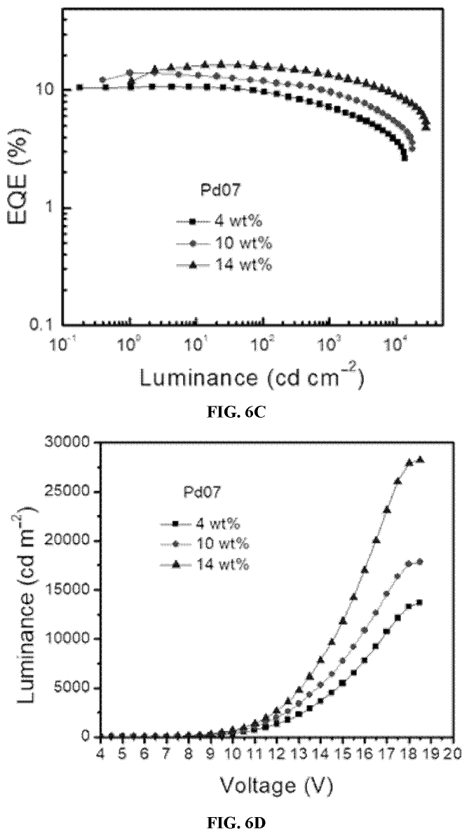

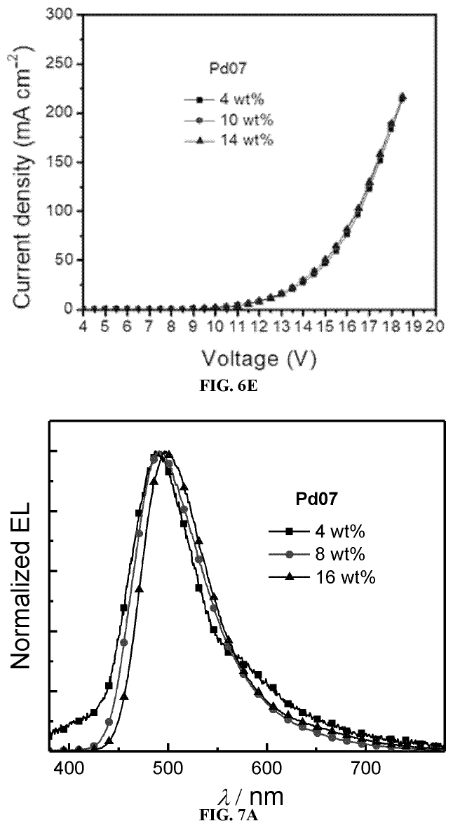

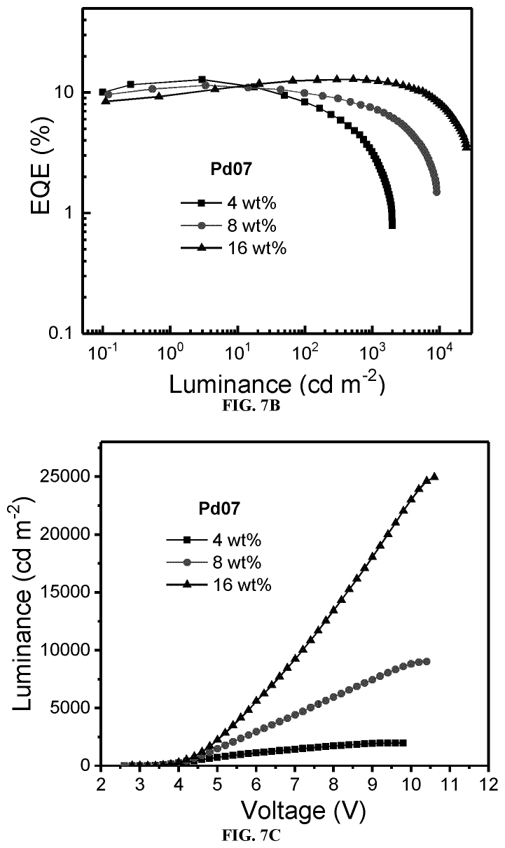

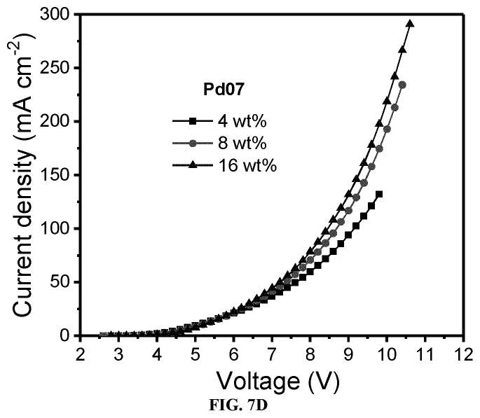

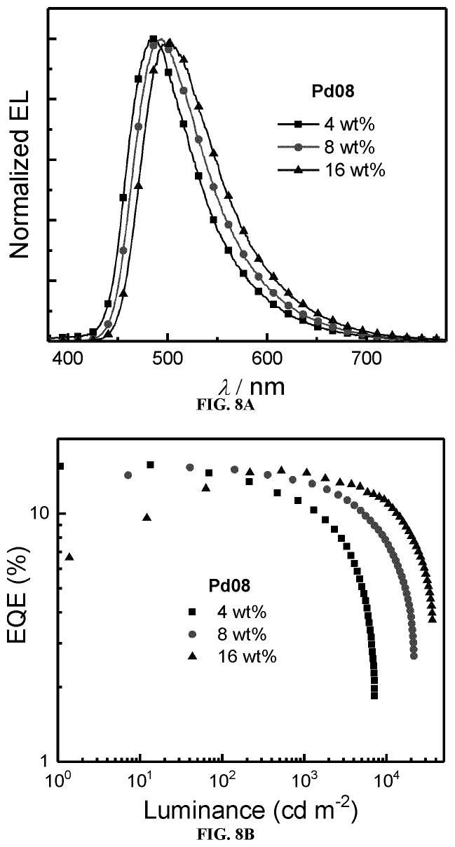

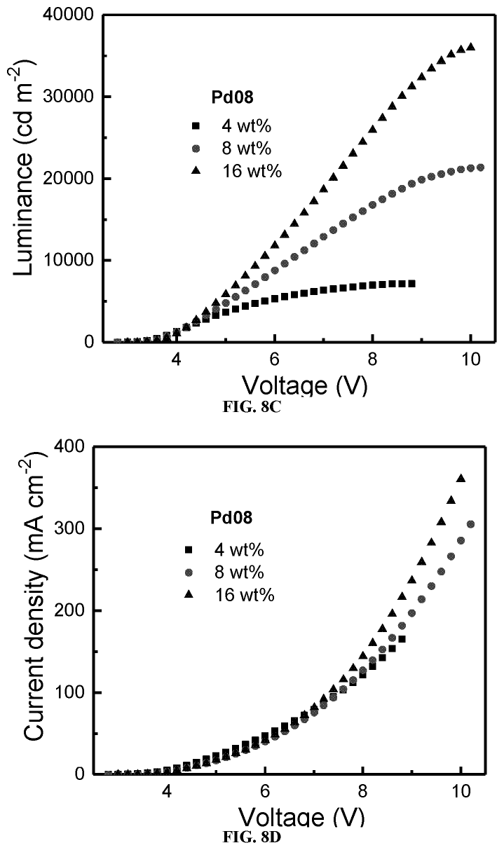

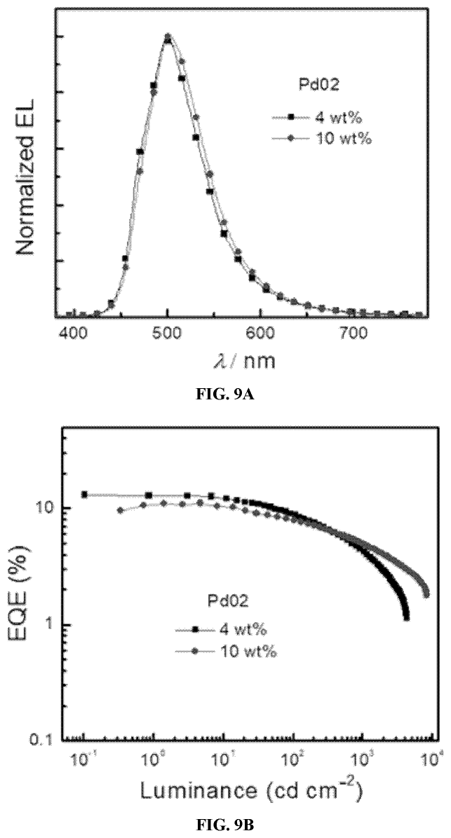

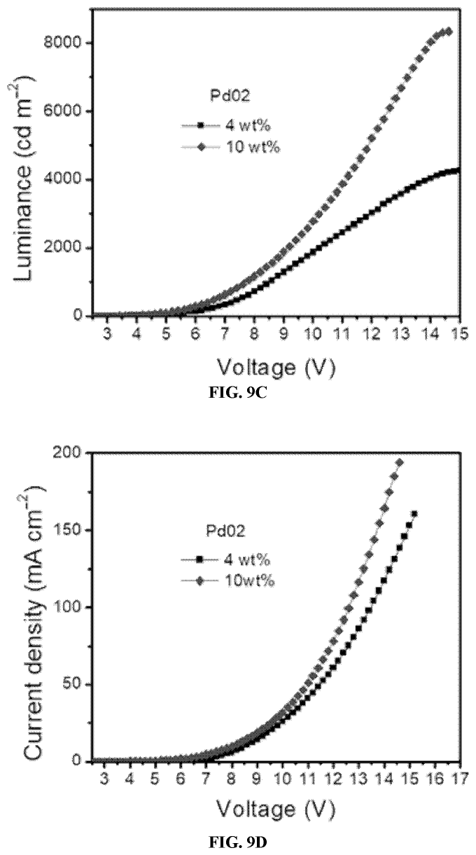

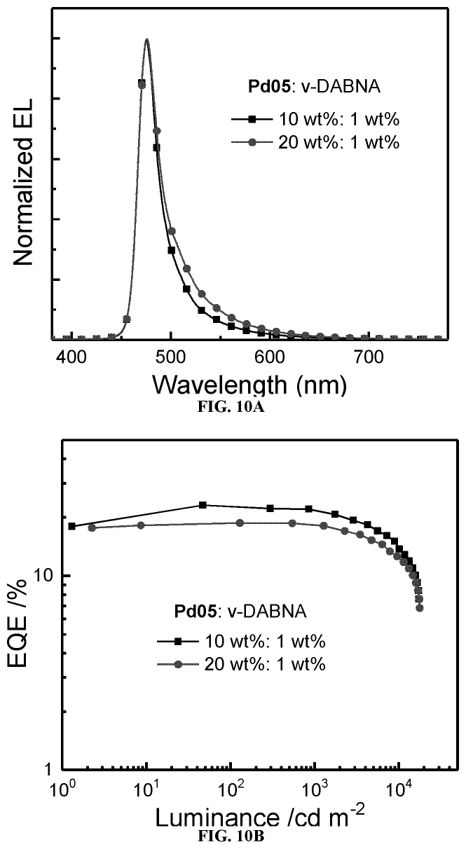

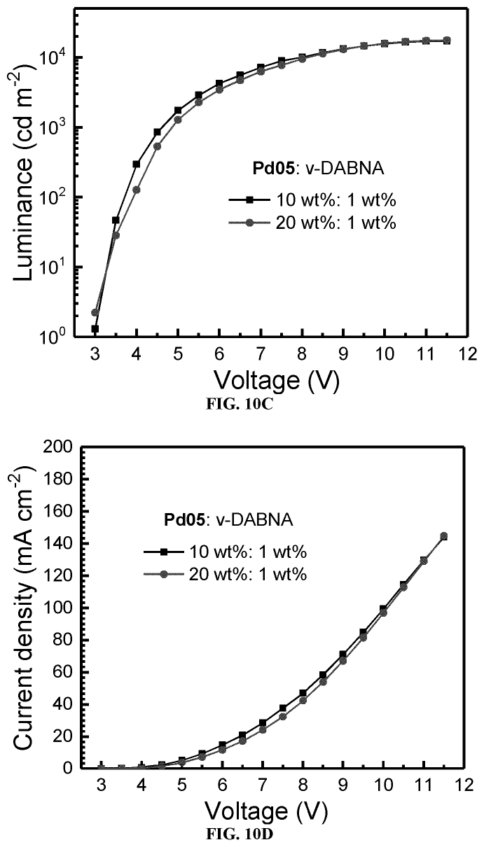

### DETAILED DESCRIPTION OF THE INVENTION

### I. Definitions

The term “room temperature” refers to a temperature between about 288 K and about 303 K, such as 298 K.

“Alkyl” includes straight and branched chain alkyl groups, as well as cycloalkyl groups with alkyl groups having a cyclic structure. Preferred alkyl groups are those containing between one to eighteen carbon atoms and includes methyl, ethyl, propyl, isopropyl, butyl, isobutyl, tert-butyl, and other similar compounds. In addition, the alkyl group may be optionally substituted with one or more substituents selected from hydrogen atom, deuterium atom, formaldehyde, cyano, alkylalkynyl, substituted alkylalkynyl, arylalkynyl, substituted arylalkynyl, heteroarylalkynyl, substituted heteroarylalkynyl, condensed polycyclic, substituted condensed polycyclic, aryl, alkyl, heteroaryl, nitro, trifluoromethane, cyano, arylether, alkylether, heteroarylether, diarylamine, dialkylamine, diheteroarylamine, diarylborane, triarylsilane, trialkylsilane, alkenyl, alkylaryl, cycloalkyl, haloformyl, hydroxyl, aldehyde, carboxamide, amine, amino, alkoxy, azo, benzyl, carbonate ester, carboxylate, carboxyl, ketamine, isocyanate, isocyanide, isothiocyanate, nitrile, nitro, nitroso, phosphine, phosphate, phosphono, pyridyl, sulfonyl, sulfo, sulfinyl, sulfhydryl, halo, aryl, substituted aryl, heteroaryl, substituted heteroaryl, heterocyclic and derivatives thereof.

It will be understood by those skilled in the art that the moieties substituted on the hydrocarbon chain can themselves be substituted, if appropriate. For instance, the substituents of a substituted alkyl may include halogen, hydroxy, nitro, thiols, amino, azido, imino, amido, phosphoryl (including phosphonate and phosphinate), sulfonyl (including sulfate, sulfonamido, sulfamoyl and sulfonate), and silyl groups, as well as ethers, alkylthios, carbonyls (including ketones, aldehydes, carboxylates, and esters), haloalkyls, —CN and the like. Cycloalkyls can be substituted in the same manner.

“Substituted,” as used herein, refers to all permissible substituents of the compounds or functional groups described herein. In the broadest sense, the permissible substituents include acyclic and cyclic, branched and unbranched, carbocyclic and heterocyclic, aromatic and nonaromatic substituents of organic compounds. Illustrative substituents include, but are not limited to, halogens, hydroxyl groups, or any other organic groupings containing any number of carbon atoms, preferably 1-14 carbon atoms, and optionally include one or more heteroatoms such as oxygen, sulfur, or nitrogen grouping in linear, branched, or cyclic structural formats. Representative substituents include alkyl, substituted alkyl, alkenyl, substituted alkenyl, alkynyl, substituted alkynyl, phenyl, substituted phenyl, aryl, substituted aryl, heteroaryl, substituted heteroaryl, halo, hydroxyl, alkoxy, substituted alkoxy, phenoxy, substituted phenoxy, aroxy, substituted aroxy, alkylthio, substituted alkylthio, phenylthio, substituted phenylthio, arylthio, substituted arylthio, cyano, isocyano, substituted isocyano, carbonyl, substituted carbonyl, carboxyl, substituted carboxyl, amino, substituted amino, amido, substituted amido, sulfonyl, substituted sulfonyl, sulfonic acid, phosphoryl, substituted phosphoryl, phosphonyl, substituted phosphonyl, polyaryl, substituted polyaryl, cyclic (such as C₃-C₂₀ cyclic), substituted cyclic (such as substituted C₃-C₂₀ cyclic), heterocyclic, substituted heterocyclic, amino acid, poly(lactic-co-glycolic acid), peptide, polypeptide, deuterium, unsubstituted alkylalkynyl, substituted alkylalkynyl, unsubstituted arylalkynyl, substituted arylalkynyl, unsubstituted heteroarylalkynyl, substituted heteroarylalkynyl, trihaloalkyl (trifluoromethyl), unsubstituted heteroarylether, substituted heteroarylether, unsubstituted diarylamino, substituted diarylamino, unsubstituted dialkylamino, substituted dialkylamino, unsubstituted diheteroarylamino, substituted diheteroarylamino, unsubstituted diarylboraneyl, substituted diarylboraneyl, unsubstituted triarylsilyl, substituted triarylsilyl, unsubstituted trialkylsilyl, substituted trialkylsilyl, azo, carbonate ester, ketamine, nitro, nitroso, phosphino, pyridyl, NRR′, SR, C(O)R, COOR, C(O)NR, SOR, SOR, and BRR′ groups, wherein and R and R′ are independently selected from hydrogen atom, deuterium atom, formaldehyde, cyano, alkylalkynyl, substituted alkylalkynyl, arylalkynyl, substituted arylalkynyl, heteroarylalkynyl, substituted heteroarylalkynyl, condensed polycyclic, substituted condensed polycyclic, aryl, alkyl, heteroaryl, nitro, trifluoromethane, cyano, arylether, alkylether, heteroarylether, diarylamine, dialkylamine, diheteroarylamine, diarylborane, triarylsilane, trialkylsilane, alkenyl, alkylaryl, cycloalkyl, haloformyl, hydroxyl, aldehyde, carboxamide, amine, amino, alkoxy, azo, benzyl, carbonate ester, carboxylate, carboxyl, ketamine, isocyanate, isocyanide, isothiocyanate, nitrile, nitro, nitroso, phosphine, phosphate, phosphono, pyridyl, sulfonyl, sulfo, sulfinyl, sulfhydryl, halo, aryl, substituted aryl, heteroaryl, substituted heteroaryl, and heterocyclic groups. Such alkyl, substituted alkyl, alkenyl, substituted alkenyl, alkynyl, substituted alkynyl, phenyl, substituted phenyl, aryl, substituted aryl, heteroaryl, substituted heteroaryl, halo, hydroxyl, alkoxy, substituted alkoxy, phenoxy, substituted phenoxy, aroxy, substituted aroxy, alkylthio, substituted alkylthio, phenylthio, substituted phenylthio, arylthio, substituted arylthio, cyano, isocyano, substituted isocyano, carbonyl, substituted carbonyl, carboxyl, substituted carboxyl, amino, substituted amino, amido, substituted amido, sulfonyl, substituted sulfonyl, sulfonic acid, phosphoryl, substituted phosphoryl, phosphonyl, substituted phosphonyl, polyaryl, substituted polyaryl, cyclic (such as C₃-C₂₀ cyclic), substituted cyclic (such as substituted C₃-C₂₀ cyclic), heterocyclic, substituted heterocyclic, amino acid, poly(lactic-co-glycolic acid), peptide, polypeptide, deuterium, substituted alkylalkynyl, substituted alkylalkynyl, unsubstituted arylalkynyl, substituted arylalkynyl, unsubstituted heteroarylalkynyl, substituted heteroarylalkynyl, trihaloalkyl (trifluoromethyl), unsubstituted heteroarylether, substituted heteroarylether, unsubstituted diarylamino, substituted diarylamino, unsubstituted dialkylamino, substituted dialkylamino, unsubstituted diheteroarylamino, substituted diheteroarylamino, unsubstituted diarylboraneyl, substituted diarylboraneyl, unsubstituted triarylsilyl, substituted triarylsilyl, unsubstituted trialkylsilyl, substituted trialkylsilyl, azo, carbonate ester, ketamine, nitro, nitroso, phosphide, phosphino, and pyridyl groups can be further substituted.

The term “heteroatom” as used herein includes, but is not limited to, S, O, N, P, Se, Te, As, Sb, Bi, B, Si, Ge, Sn and Pb. Heteroatoms such as nitrogen may have hydrogen substituents and/or any permissible substituents of organic compounds described herein which satisfy the valences of the heteroatoms. It is understood that “substitution” or “substituted” includes the implicit proviso that such substitution is in accordance with permitted valence of the substituted atom and the substituent, and that the substitution results in a stable compound, i.e. a compound that does not spontaneously undergo transformation such as by rearrangement, cyclization, elimination, etc.

The term “alkenyl” as used herein is a hydrocarbon group having, for example, from 2 to 24 carbon atoms and a structural formula containing at least one carbon-carbon double bond. Asymmetric structures such as (AB)C=C(CD) are intended to include both the E and Z isomers. This may be presumed in structural formulae herein wherein an asymmetric alkene is present, or it may be explicitly indicated by the bond symbol C.

The term “alkynyl group” as used herein is a hydrocarbon group having, for example, 2 to 24 carbon atoms and a structural formula containing at least one carbon-carbon triple bond.

The term “aryl” as used herein is any C₅-C₂₆ carbon-based aromatic group, fused aromatic, fused heterocyclic, or biaromatic ring systems. Broadly defined, “aryl,” as used herein, includes 5-, 6-, 7-, 8-, 9-, 10-, 14-, 18-, and 24-membered single-ring aromatic groups, including, but not limited to, benzene, naphthalene, anthracene, phenanthrene, chrysene, pyrene, corannulene, coronene, etc. “Aryl” further encompasses polycyclic ring systems having two or more cyclic rings in which two or more carbons are common to two adjoining rings (i.e., “fused rings”) wherein at least one of the rings is aromatic, e.g., the other cyclic ring or rings can be cycloalkyls, cycloalkenyls, cycloalkynyls, aryls and/or heterocycles. The aryl group can be substituted with one or more groups including, but not limited to, alkyl, alkynyl, alkenyl, aryl, halide, nitro, amino, ester, ketone, aldehyde, hydroxy, carboxylic acid, or alkoxy.

The term “substituted aryl” refers to an aryl group, wherein one or more hydrogen atoms on one or more aromatic rings are substituted with one or more substituents including, but not limited to, halogen, azide, alkyl, aralkyl, alkenyl, alkynyl, cycloalkyl, hydroxyl, alkoxy, carbonyl (such as a ketone, aldehyde, carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, imino, alkylthio, sulfate, sulfonate, sulfamoyl, sulfonamido, sulfonyl, heterocyclyl, alkylaryl, haloalkyl (such as CF3, —CH₂—CF₃, —CCl₃), —CN, aryl, heteroaryl, and combinations thereof.

“Heterocycle,” “heterocyclic” and “heterocyclyl” are used interchangeably, and refer to a cyclic radical attached via a ring carbon or nitrogen atom of a monocyclic or bicyclic ring containing 3-10 ring atoms, and preferably from 5-6 ring atoms, consisting of carbon and one to four heteroatoms each selected from the group consisting of non-peroxide oxygen, sulfur, and N(Y) wherein Y is absent or is H, O, C₁-C₁₀ alkyl, phenyl or benzyl, and optionally containing 1-3 double bonds and optionally substituted with one or more substituents. Heterocyclyl are distinguished from heteroaryl by definition. Examples of heterocycles include, but are not limited to piperazinyl, piperidinyl, piperidonyl, 4-piperidonyl, dihydrofuro[2,3-b]tetrahydrofuran, morpholinyl, piperazinyl, piperidinyl, piperidonyl, 4-piperidonyl, piperonyl, pyranyl, 2H-pyrrolyl, 4H-quinolizinyl, quinuclidinyl, tetrahydrofuranyl, 6H-1,2,5-thiadiazinyl. Heterocyclic groups can optionally be substituted with one or more substituents as defined above for alkyl and aryl.

The term “heteroaryl” refers to C₅-C₂₆-membered aromatic, fused aromatic, biaromatic ring systems, or combinations thereof, in which one or more carbon atoms on one or more aromatic ring structures have been substituted with a heteroatom. Suitable heteroatoms include, but are not limited to, oxygen, sulfur, and nitrogen. Broadly defined, “heteroaryl,” as used herein, includes 5-, 6-, 7-, 8-, 9-, 10-, 14-, 18-, and 24-membered single-ring aromatic groups that may include from one to four heteroatoms, for example, pyrrole, furan, thiophene, imidazole, oxazole, thiazole, triazole, tetrazole, pyrazole, pyridine, pyrazine, pyridazine and pyrimidine, and the like. The heteroaryl group may also be referred to as “aryl heterocycles” or “heteroaromatics.” “Heteroaryl” further encompasses polycyclic ring systems having two or more rings in which two or more carbons are common to two adjoining rings (i.e., “fused rings”) wherein at least one of the rings is heteroaromatic, e.g., the other cyclic ring or rings can be cycloalkyls, cycloalkenyls, cycloalkynyls, aryls, heterocycles, or combinations thereof. Examples of heteroaryl rings include, but are not limited to, benzimidazolyl, benzofuranyl, benzothiofuranyl, benzothiophenyl, benzoxazolyl, benzoxazolinyl, benzthiazolyl, benztriazolyl, benztetrazolyl, benzisoxazolyl, benzisothiazolyl, benzimidazolinyl, carbazolyl, 4aH-carbazolyl, carbolinyl, chromanyl, chromenyl, cinnolinyl, decahydroquinolinyl, 2H,6H-1,5,2-dithiazinyl, furanyl, furazanyl, imidazolidinyl, imidazolinyl, imidazolyl, 1H-indazolyl, indolenyl, indolinyl, indolizinyl, indolyl, 3H-indolyl, isatinoyl, isobenzofuranyl, isochromanyl, isoindazolyl, isoindolinyl, isoindolyl, isoquinolinyl, isothiazolyl, isoxazolyl, methylenedioxyphenyl, naphthyridinyl, octahydroisoquinolinyl, 1,2,3-oxadiazolyl, 1,2,4-oxadiazolyl, 1,2,5-oxadiazolyl, 1,3,4-oxadiazolyl, oxazolidinyl, oxazolyl, oxindolyl, pyrimidinyl, phenanthridinyl, phenanthrolinyl, phenazinyl, phenothiazinyl, phenoxathinyl, phenoxazinyl, phthalazinyl, pteridinyl, purinyl, pyrazinyl, pyrazolidinyl, pyrazolinyl, pyrazolyl, pyridazinyl, pyridooxazole, pyridoimidazole, pyridothiazole, pyridinyl, pyridyl, pyrimidinyl, pyrrolidinyl, pyrrolinyl, pyrrolyl, quinazolinyl, quinolinyl, quinoxalinyl, tetrahydroisoquinolinyl, tetrahydroquinolinyl, tetrazolyl, 1,2,3-thiadiazolyl, 1,2,4-thiadiazolyl, 1,2,5-thiadiazolyl, 1,3,4-thiadiazolyl, thianthrenyl, thiazolyl, thienyl, thienothiazolyl, thienooxazolyl, thienoimidazolyl, thiophenyl and xanthenyl. One or more of the rings can be substituted as defined below for “substituted heteroaryl”.

The term “substituted heteroaryl” refers to a heteroaryl group in which one or more hydrogen atoms on one or more heteroaromatic rings are substituted with one or more substituents including, but not limited to, halogen, azide, alkyl, aralkyl, alkenyl, alkynyl, cycloalkyl, hydroxyl, alkoxy, carbonyl (such as a ketone, aldehyde, carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, imino, alkylthio, sulfate, sulfonate, sulfamoyl, sulfonamido, sulfonyl, heterocyclyl, alkylaryl, haloalkyl (such as CF3, —CH₂—CF₃, —CCl), —CN, aryl, heteroaryl, and combinations thereof.

The term “substituted alkenyl” refers to alkenyl moieties having one or more substituents replacing one or more hydrogen atoms on one or more carbons of the hydrocarbon backbone. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “substituted alkynyl” refers to alkynyl moieties having one or more substituents replacing one or more hydrogen atoms on one or more carbons of the hydrocarbon backbone. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “cycloalkyl” as used herein is a non-aromatic carbon-based ring composed of at least three carbon atoms. Examples of cycloalkyl groups include, but are not limited to, cyclopropyl, cyclobutyl, cyclopentyl, cyclohexyl, etc. The term “heterocycloalkyl group” is a cycloalkyl group as defined above where at least one of the carbon atoms of the ring is substituted with a heteroatom such as, but not limited to, nitrogen, oxygen, sulphur, or phosphorus.

The term “aralkyl” as used herein is an aryl group having an alkyl, alkynyl, or alkenyl group as defined above attached to the aromatic group. An example of an aralkyl group is a benzyl group.

“Carbonyl,” as used herein, is art-recognized and includes such moieties as can be represented by the general formula:

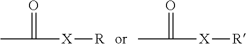

wherein X is a bond, or represents an oxygen or a sulfur, and R represents a hydrogen, a substituted or unsubstituted alkyl, substituted or unsubstituted alkenyl, substituted or unsubstituted alkynyl, substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl, —(CH₂)ₘ—R″, or a pharmaceutical acceptable salt, R′ represents a hydrogen, substituted or unsubstituted alkyl, substituted or unsubstituted alkenyl, substituted or unsubstituted alkynyl, substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl or —(CH₂)ₘ—R″; R″ represents a hydroxy group, substituted or unsubstituted carbonyl group, an aryl, a cycloalkyl ring, a cycloalkenyl ring, a heterocycle, or a polycycle; and m is zero or an integer ranging from 1 to 8. Where X is oxygen and R is defines as above, the moiety is also referred to as a carboxyl group. When X is oxygen and R is hydrogen, the formula represents a ‘carboxylic acid’. Where X is oxygen and R′ is hydrogen, the formula represents a ‘formate’. Where X is oxygen and R or R′ is not hydrogen, the formula represents an “ester”. In general, where the oxygen atom of the above formula is replaced by a sulfur atom, the formula represents a ‘thiocarbonyl’ group. Where X is sulfur and R or R′ is not hydrogen, the formula represents a ‘thioester.’ Where X is sulfur and R is hydrogen, the formula represents a ‘thiocarboxylic acid.’ Where X is sulfur and R′ is hydrogen, the formula represents a ‘thioformate.’ Where X is a bond and R is not hydrogen, the above formula represents a ‘ketone.’ Where X is a bond and R is hydrogen, the above formula represents an ‘aldehyde.’

The term “substituted carbonyl” refers to a carbonyl, as defined above, wherein one or more hydrogen atoms in R, R′ or a group to which the moiety

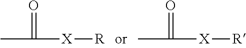

is attached, are independently substituted. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “carboxyl” is as defined above for the formula

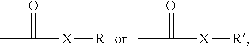

and is defined more specifically by the formula —R^{iv}COOH, wherein R^{iv} is an alkyl, alkenyl, alkynyl, cycloalkyl, heterocyclyl, alkylaryl, arylalkyl, aryl, or heteroaryl. In preferred forms, a straight chain or branched chain alkyl, alkenyl, and alkynyl have 30 or fewer carbon atoms in its backbone (e.g., C₁-C₃₀ for straight chain alkyl, C₃-C₃₀ for branched chain alkyl, C₂-C₃₀ for straight chain alkenyl and alkynyl, C₃-C₃₀ for branched chain alkenyl and alkynyl), preferably 20 or fewer, more preferably 15 or fewer, most preferably 10 or fewer. Likewise, preferred cycloalkyls, heterocyclyls, aryls and heteroaryls have from 3-10 carbon atoms in their ring structure, and more preferably have 5, 6 or 7 carbons in the ring structure.

The term “substituted carboxyl” refers to a carboxyl, as defined above, wherein one or more hydrogen atoms in R^{iv} are substituted. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “phenoxy” is recognized, and refers to a compound of the formula —OR^{v} wherein R^{v} is (i.e., —O—C₆H₅). One of skill in the art recognizes that a phenoxy is a species of the aroxy genus.

The term “substituted phenoxy” refers to a phenoxy group, as defined above, having one or more substituents replacing one or more hydrogen atoms on one or more carbons of the phenyl ring. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The terms “aroxy” and “aryloxy,” as used interchangeably herein, are represented by —O-aryl or —O-heteroaryl, wherein aryl and heteroaryl are as defined herein.

The terms “substituted aroxy” and “substituted aryloxy,” as used interchangeably herein, represent —O-aryl or —O-heteroaryl, having one or more substituents replacing one or more hydrogen atoms on one or more ring atoms of the aryl and heteroaryl, as defined herein. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “alkylthio” refers to an alkyl group, as defined above, having a sulfur radical attached thereto. The “alkylthio” moiety is represented by —S-alkyl. Representative alkylthio groups include methylthio, ethylthio, and the like. The term “alkylthio” also encompasses cycloalkyl groups having a sulfur radical attached thereto.

The term “substituted alkylthio” refers to an alkylthio group having one or more substituents replacing one or more hydrogen atoms on one or more carbon atoms of the alkylthio backbone. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “phenylthio” is art recognized, and refers to —S—C₆H₅, i.e., a phenyl group attached to a sulfur atom.

The term “substituted phenylthio” refers to a phenylthio group, as defined above, having one or more substituents replacing a hydrogen on one or more carbons of the phenyl ring. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

“Arylthio” refers to —S-aryl or —S-heteroaryl groups, wherein aryl and heteroaryl as defined herein.

The term “substituted arylthio” represents —S-aryl or —S-heteroaryl, having one or more substituents replacing a hydrogen atom on one or more ring atoms of the aryl and heteroaryl rings as defined herein. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The terms “amide” or “amido” are used interchangeably, refer to both “unsubstituted amido” and “substituted amido” and are represented by the general formula:

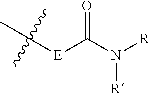

wherein, E is absent, or E is substituted or unsubstituted alkyl, substituted or unsubstituted alkenyl, substituted or unsubstituted alkynyl, substituted or unsubstituted aralkyl, substituted or unsubstituted cycloalkyl, substituted or unsubstituted aryl, substituted or unsubstituted heteroaryl, substituted or unsubstituted heterocyclyl, wherein independently of E, R and R′ each independently represent a hydrogen, substituted or unsubstituted alkyl, substituted or unsubstituted alkenyl, substituted or unsubstituted alkynyl, substituted or unsubstituted carbonyl, substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl, —(CH₂)ₘ—R′″ or R and R′ taken together with the N atom to which they are attached complete a heterocycle having from 3 to 14 atoms in the ring structure; R′″ represents a hydroxy group, substituted or unsubstituted carbonyl group, an aryl, a cycloalkyl ring, a cycloalkenyl ring, a heterocycle, or a polycycle; and m is zero or an integer ranging from 1 to 8. In preferred forms, only one of R and R′ can be a carbonyl, e.g., R and R′ together with the nitrogen do not form an imide. In preferred forms, R and R′ each independently represent a hydrogen atom, substituted or unsubstituted alkyl, a substituted or unsubstituted alkenyl, or —(CH₂)ₘ—R′″.

When E is oxygen, a carbamate is formed. The carbamate cannot be attached to another chemical species, such as to form an oxygen-oxygen bond, or other unstable bonds, as understood by one of ordinary skill in the art.

The term “sulfonyl” is represented by the formula

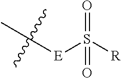

wherein E is absent, or E is alkyl, alkenyl, alkynyl, aralkyl, alkylaryl, cycloalkyl, aryl, heteroaryl, heterocyclyl, wherein independently of E, R represents a hydrogen, substituted or unsubstituted alkyl, substituted or unsubstituted alkenyl, substituted or unsubstituted alkynyl, substituted or unsubstituted amine, substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl, —(CH₂)ₘ—R′″ or E and R taken together with the S atom to which they are attached complete a heterocycle having from 3 to 14 atoms in the ring structure; R′″ represents a hydroxy group, substituted or unsubstituted carbonyl group, an aryl, a cycloalkyl ring, a cycloalkenyl ring, a heterocycle, or a polycycle; and m is zero or an integer ranging from 1 to 8. In preferred forms, only one of E and R can be substituted or unsubstituted amine, to form a “sulfonamide” or “sulfonamido.” The substituted or unsubstituted amine is as defined above.

The term “substituted sulfonyl” represents a sulfonyl in which E, R, or both, are independently substituted. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “sulfonic acid” refers to a sulfonyl, as defined above, wherein R is hydroxyl, and E is absent, or E is substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl.

The term “sulfate” refers to a sulfonyl, as defined above, wherein E is absent, oxygen, alkoxy, aroxy, substituted alkoxy or substituted aroxy, as defined above, and R is independently hydroxyl, alkoxy, aroxy, substituted alkoxy or substituted aroxy, as defined above. When E is oxygen, the sulfate cannot be attached to another chemical species, such as to form an oxygen-oxygen bond, or other unstable bonds, as understood by one of ordinary skill in the art.

The term “sulfonate” refers to a sulfonyl, as defined above, wherein E is oxygen, alkoxy, aroxy, substituted alkoxy or substituted aroxy, as defined above, and R is independently hydrogen, substituted or unsubstituted alkyl, substituted or unsubstituted alkenyl, substituted or unsubstituted alkynyl, substituted or unsubstituted amine, substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl, —(CH₂)ₘ—R′″ R′″ represents a hydroxy group, substituted or unsubstituted carbonyl group, an aryl, a cycloalkyl ring, a cycloalkenyl ring, a heterocycle, or a polycycle; and m is zero or an integer ranging from 1 to 8. When E is oxygen, sulfonate cannot be attached to another chemical species, such as to form an oxygen-oxygen bond, or other unstable bonds, as understood by one of ordinary skill in the art.

The term “sulfamoyl” refers to a sulfonamide or sulfonamide represented by the formula

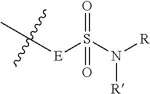

wherein E is absent, or E is substituted or unsubstituted alkyl, substituted or unsubstituted alkenyl, substituted or unsubstituted alkynyl, substituted or unsubstituted aralkyl, substituted or unsubstituted alkylaryl, substituted or unsubstituted cycloalkyl, substituted or unsubstituted aryl, substituted or unsubstituted heteroaryl, substituted or unsubstituted heterocyclyl, wherein independently of E, R and R′ each independently represent a hydrogen, substituted or unsubstituted alkyl, substituted or unsubstituted alkenyl, substituted or unsubstituted alkynyl, substituted or unsubstituted carbonyl, substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl, —(CH₂)ₘ—R′″ or R and R′ taken together with the N atom to which they are attached complete a heterocycle having from 3 to 14 atoms in the ring structure; R′″ represents a hydroxy group, substituted or unsubstituted carbonyl group, an aryl, a cycloalkyl ring, a cycloalkenyl ring, a heterocycle, or a polycycle; and m is zero or an integer ranging from 1 to 8. In preferred forms, only one of R and R′ can be a carbonyl, e.g., R and R′ together with the nitrogen do not form an imide.

The term “phosphonyl” is represented by the formula

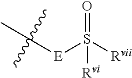

wherein E is absent, or E is substituted or unsubstituted alkyl, substituted or unsubstituted alkenyl, substituted or unsubstituted alkynyl, substituted or unsubstituted aralkyl, substituted or unsubstituted alkylaryl, substituted or unsubstituted cycloalkyl, substituted or unsubstituted aryl, substituted or unsubstituted heteroaryl, substituted or unsubstituted heterocyclyl, wherein, independently of E, R^{vi} and R^{vii} are independently hydrogen, substituted or unsubstituted alkyl, substituted or unsubstituted alkenyl, substituted or unsubstituted alkynyl, substituted or unsubstituted carbonyl, substituted or unsubstituted cycloalkyl, substituted or unsubstituted heterocyclyl, substituted or unsubstituted alkylaryl, substituted or unsubstituted arylalkyl, substituted or unsubstituted aryl, or substituted or unsubstituted heteroaryl, —(CH₂)ₘ—R′″ or R and R′ taken together with the P atom to which they are attached complete a heterocycle having from 3 to 14 atoms in the ring structure; R′″ represents a hydroxy group, substituted or unsubstituted carbonyl group, an aryl, a cycloalkyl ring, a cycloalkenyl ring, a heterocycle, or a polycycle; and m is zero or an integer ranging from 1 to 8.

The term “substituted phosphonyl” represents a phosphonyl in which E, R^{vi} and R^{vii} are independently substituted. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “phosphoryl” defines a phosphonyl in which E is absent, oxygen, alkoxy, aroxy, substituted alkoxy or substituted aroxy, as defined above, and independently of E, R^{vi} and R^{vii} are independently hydroxyl, alkoxy, aroxy, substituted alkoxy or substituted aroxy, as defined above. When E is oxygen, the phosphoryl cannot be attached to another chemical species, such as to form an oxygen-oxygen bond, or other unstable bonds, as understood by one of ordinary skill in the art. When E, R^{vi} and R^{vii} are substituted, the substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The term “polyaryl” refers to a chemical moiety that includes two or more aryls, heteroaryls, and combinations thereof. The aryls, heteroaryls, and combinations thereof, are fused, or linked via a single bond, ether, ester, carbonyl, amide, sulfonyl, sulfonamide, alkyl, azo, and combinations thereof. When two or more heteroaryls are involved, the chemical moiety can be referred to as a “polyheteroaryl.”

The term “substituted polyaryl” refers to a polyaryl in which one or more of the aryls, heteroaryls are substituted, with one or more substituents including, but not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof. When two or more heteroaryls are involved, the chemical moiety can be referred to as a “substituted polyheteroaryl.”

The term “cyclic” refers to a substituted or unsubstituted cycloalkyl, substituted or unsubstituted cycloalkenyl, substituted or unsubstituted cycloalkynyl, substituted or unsubstituted heterocyclyl that, preferably, have from 3 to 20 carbon atoms, as geometric constraints permit. The cyclic structures are formed from single or fused ring systems. The substituted cycloalkyls, cycloalkenyls, cycloalkynyls and heterocyclyls are substituted as defined above for the alkyls, alkenyls, alkynyls and heterocyclyls, respectively.

### II. Compositions

Boosting the radiative rate constants (kᵣ) of Pd(II) emitters to a practical level, such as 10⁵ s⁻¹, remains a daunting challenge as this class of phosphors, in contrast to the Pt(II) counterparts, are bound to have emissive excited states with minute metal character that fails to accelerate the spin-forbidden radiative process. It has been discovered that these problems can be circumvented by an approach that harvests the fast-emitting singlet excitons by opening up the thermally activated delayed fluorescence (TADF) decay channel in a new class of Pd(II) emitters. The approach demonstrably circumvents the inefficient phosphorescence processes and significantly increases the kᵣ.

The newly discovered Pd(II) emitters, are preferably charge neutral, and are supported by tetradentate [N\hat{ }C\hat{ }C\hat{ }N] ligands featuring donor-acceptor structure where, in a non-limiting example, a pendant substituted amino group (such as a substituted diarylamine group or unsubstituted diarylamine group) and a heteroaryl group (such as a pyridine group) serve as donor and acceptor, respectively. This donor-acceptor structure introduces a set of low-energy singlet and triplet charge-transfer excited states with small energy separation allowing for efficient TADF to take place.

The disclosed compounds have the structure:

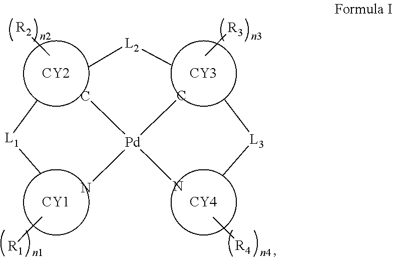

wherein:
the compound has an overall neutral, negative, or positive charge, preferably an overall neutral charge,
CY1 and CY4 are independently unsubstituted heteroaryl, substituted heteroaryl, unsubstituted polyheteroaryl, substituted polyheteroaryl, unsubstituted C₂-C₂₀ heterocyclyl, or substituted C₂-C₂₀ heterocyclyl,
CY2 and CY3 are independently unsubstituted aryl, substituted aryl, unsubstituted polyaryl, substituted polyaryl, unsubstituted heteroaryl, substituted heteroaryl, unsubstituted polyheteroaryl, substituted polyheteroaryl, unsubstituted C₃-C₂₀ cycloalkyl, substituted C₂-C₂₀ cycloalkyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl,
each R₁, R₂, R₃, and R₄ is independently, absent, hydrogen, substituted amino, unsubstituted amino, substituted alkyl, unsubstituted alkyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, wherein at least one of R₁, R₂, R₃, and R₄ is present and is an electron donating group,
n1, n2, n3, and n4 are independently an integer between zero and 10, inclusive, with the proviso that at least one of n1, n2, n3, and n4 is not zero, and
L₁, L₂, and L₃ are independently a bond (single, double, or triple), absent, oxygen, sulfur, substituted amino, unsubstituted amino, unsubstituted alkylene, substituted alkylene, unsubstituted alkyl, substituted alkyl, substituted carbonyl, unsubstituted carbonyl, substituted amido, unsubstituted amido, substituted sulfonyl, unsubstituted sulfonyl, substituted sulfonic acid, unsubstituted sulfonic acid, substituted phosphoryl, unsubstituted phosphoryl, substituted phosphonyl, or unsubstituted phosphonyl.

In some forms of Formula I, each R₁, R₂, R₃, and R₄ is independently absent, hydrogen, substituted amino, substituted alkyl, unsubstituted alkyl, substituted aryl, halogen, hydroxyl, thiol, unsubstituted alkoxy, substituted alkoxy, unsubstituted aroxy, substituted aroxy, unsubstituted alkylthio, or substituted alkylthio. In some forms of Formula I, each R₁, R₂, R₃, and R₄ is independently hydrogen, substituted amino, substituted alkyl, unsubstituted alkyl, substituted aryl, unsubstituted alkoxy, or halogen. In some forms of Formula I, at least one R₂ has a structure —NRₐR_{b}, wherein Rₐ and R_{b} are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl, or —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl. In some forms of Formula I, at least one R₂ has a structure —NRₐR_{b}, wherein at least one of Rₐ and R_{b} is an unsubstituted aryl or substituted aryl, preferably substituted with C₁-C₁₀ unsubstituted alkyl such as methyl, C₃-C₁₀ substituted alkyl such as t-butyl, or a combination thereof. In some forms of Formula I, at least one R₂ has a structure —NRₐR_{b}, wherein Rₐ and R_{b} are both an unsubstituted aryl or substituted aryl, preferably substituted with C₁-C₁₀ unsubstituted alkyl such as methyl. In some forms of Formula I, at least one R₂ has a structure —NRₐR_{b}, wherein Rₐ and R_{b} are both an unsubstituted aryl or substituted aryl, preferably substituted with a C₃-C₁₀ substituted alkyl such as t-butyl.

In some forms, the compound is as described above for Formula I, except that CY1 and CY4 are independently unsubstituted heteroaryl or substituted heteroaryl.

In some forms, the compound is as described above for Formula I, except that CY2 and CY3 are independently unsubstituted aryl, substituted aryl, unsubstituted heteroaryl or substituted heteroaryl.

In some forms, the compound is as described above for Formula I, except that L₁, L₂, and L₃ are independently a single bond, oxygen, substituted alkyl, or substituted amino. The substituted alkyl can be a C₁-C₅ substituted alkyl, such as iso-propyl. The amino can be substituted with C₁-C₁₀ unsubstituted alkyl such as methyl, C₃-C₁₀ substituted alkyl such as t-butyl, or a combination thereof.

In some forms, the compound is as described above for Formula I, except that the compound has a structure:

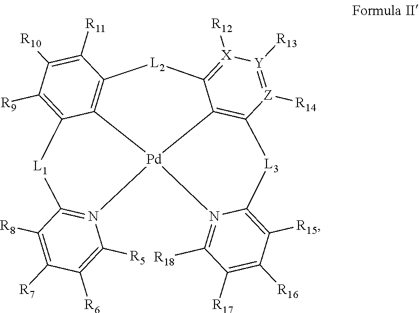

wherein:
either X and Z are nitrogen, and Y is carbon, or X and Z are carbon and Y is nitrogen,
R₅-R₁₈ are independently absent, hydrogen, substituted amino, unsubstituted amino, substituted alkyl, unsubstituted alkyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, wherein at least one of R₅-R₁₈ is present and is an electron donating group, and
L₁, L₂, and L₃ are independently a bond (single, double, or triple), absent, oxygen, sulfur, substituted amino, unsubstituted amino, unsubstituted alkylene, substituted alkylene, unsubstituted alkyl, substituted alkyl, substituted carbonyl, unsubstituted carbonyl, substituted amido, unsubstituted amido, substituted sulfonyl, unsubstituted sulfonyl, substituted sulfonic acid, unsubstituted sulfonic acid, substituted phosphoryl, unsubstituted phosphoryl, substituted phosphonyl, or unsubstituted phosphonyl.

In some forms of Formula II′, X and Z are nitrogen, and Y is carbon.

In some forms of Formula II′, X and Z are carbon and Y is nitrogen.

In some forms, the compound is as described above for Formula II′, except that L₁ is oxygen or NR_{c}, wherein R_{c} is hydrogen, unsubstituted alkyl, substituted alkyl, unsubstituted aryl, substituted aryl, unsubstituted heteroaryl, or substituted heteroaryl.

In some forms, the compound is as described above for Formula II′, except that L₁ is oxygen.

In some forms, the compound is as described above for Formula II′, except that L₁ is NR_{c}, wherein R_{c} is hydrogen, unsubstituted alkyl, substituted alkyl, unsubstituted aryl, substituted aryl, unsubstituted heteroaryl, or substituted heteroaryl.

In some forms, the compound is as described above for Formula II′, except that L₂ is oxygen.

In some forms, the compound is as described above for Formula II′, except that L₂ is C₁-C₅ substituted alkyl, such as iso-propyl.

In some forms, the compound is as described above for Formula II′, except that L₃ is a single bond.

In some forms, the compound is as described above for Formula II′, except that R₁₀ has a structure —NRₐR_{b}, wherein Rₐ and R_{b} are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl, or —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl. In some forms, the compound is as described above for Formula II′, except that R₁₀ has a structure —NRₐR_{b}, wherein at least one of Rₐ and R_{b} is an unsubstituted aryl or substituted aryl, preferably substituted with C₃-C₁₀ substituted alkyl such as t-butyl or C₁-C₁₀ unsubstituted alkyl such as methyl, or —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl. In some forms, the compound is as described above for Formula II′, except that R₁₀ has a structure —NRₐR_{b}, wherein at least one of Rₐ and R_{b} is an unsubstituted aryl or substituted aryl, preferably substituted with C₃-C₁₀ substituted alkyl such as t-butyl or C₁-C₁₀ unsubstituted alkyl such as methyl. In some forms, the compound is as described above for Formula II′, except that R₁₀ has a structure —NRₐR_{b}, wherein Rₐ and R_{b} are both an unsubstituted aryl or substituted aryl, preferably substituted with C₃-C₁₀ substituted alkyl such as t-butyl or C₁-C₁₀ unsubstituted alkyl such as methyl. In some forms, the compound is as described above for Formula II′, except that R₁₀ has a structure —NRₐR_{b}, wherein —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl.

In some forms, the compound is as described above for Formula II′, except that R₁₀ has a structure:

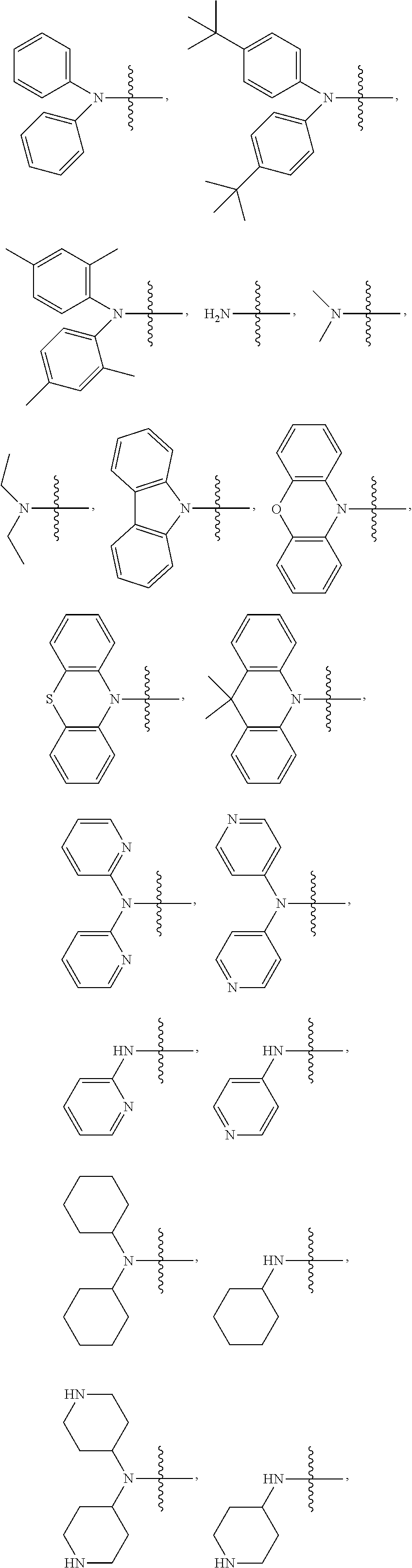

or a
combination thereof. In some forms, the compound is as described above for Formula II′, except that R₁₀ has a structure:

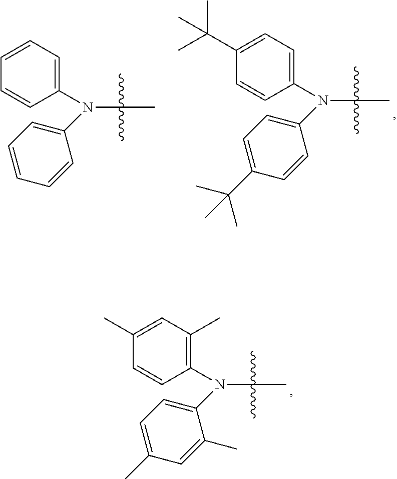 [SMILES: *N(c1ccccc1)c1ccccc1 ; *N(c1ccc(C(C)(C)C)cc1)c1ccc(C(C)(C)C)cc1 ; *N(c1ccc(C)cc1C)c1ccc(C)cc1C]

or a combination thereof.

In some forms, the compound is as described above for Formula II′, except that R₇ is hydrogen, substituted alkyl, or substituted aryl. In some forms, the compound is as described above for Formula II′, except that R₇ is a C₃-C₁₀ substituted alkyl, preferably t-butyl. In some forms, the compound is as described above for Formula II′, except that R₇ is substituted aryl, preferably substituted with between one and five C₁-C₁₀ unsubstituted alkyl groups. In some forms, the compound is as described above for Formula II′, except that R₇ has a structure:

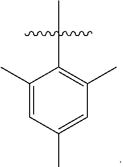

In some forms, the compound is as described above for Formula II′, except that R₁₂-R₁₄ are independently hydrogen or halogen. In some forms, the compound is as described above for Formula II′, except that (i) R₁₂ and R₁₄ are halogen, or (ii) R₁₂-R₁₄ are halogen, preferably wherein the halogen is fluorine.

In some forms, the compound is as described above for Formula II′, except that R₁₆ is hydrogen, substituted alkyl, unsubstituted alkyl, substituted aryl, unsubstituted aryl, substituted alkoxy, unsubstituted alkoxy, or —NR_{d}Rₑ, wherein R_{d} and Rₑ are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl, or —NR_{d}Rₑ together form a substituted polyheteroaryl, unsubstituted polyheteroaryl, substituted polyheterocyclyl, unsubstituted polyheterocyclyl, substituted heterocyclyl, or unsubstituted heterocyclyl.

In some forms, the compound is as described above for Formula II′, except that R₁₆ is —NR_{d}Rₑ, wherein R_{d} and Rₑ are C₁-C₅ unsubstituted alkyl, preferably methyl.

In some forms, the compound is as described above for Formula II′, except that R₁₆ is hydrogen.

In some forms, the compound is as described above for Formula II′, except that R₁₆ is a substituted alkyl, such as t-butyl.

In some forms, the compound is as described above for Formula II′, except that R₁₆ is substituted aryl, preferably substituted with between one and five C₁-C₁₀ unsubstituted alkyl groups. In some forms, the compound is as described above for Formula II′, except that R₁₆ has a structure:

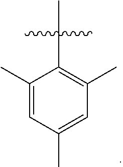

In some forms, the compound is as described above for Formula II′, except that R₁₆ is an unsubstituted alkoxy, such as C₁-C₅ unsubstituted alkoxy, preferably methoxy.

In some forms, the compound is as described above for Formula I, except that the compound has a structure:

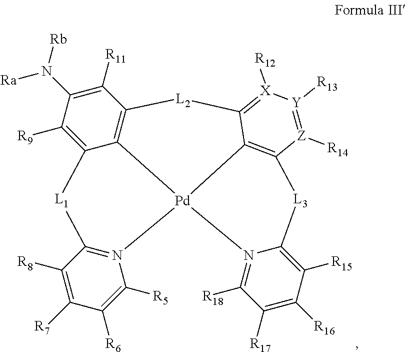

wherein:
either X and Z are nitrogen, and Y is carbon, or X and Z are carbon and Y is nitrogen,
R₅-R₉ and R₁₁-R₁₈ are independently absent, hydrogen, substituted amino, unsubstituted amino, substituted alkyl, unsubstituted alkyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl,
Rₐ and R_{b} are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl, or —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl, and
L₁, L₂, and L₃ are independently a bond (single, double, or triple), absent, oxygen, sulfur, substituted amino, unsubstituted amino, unsubstituted alkylene, substituted alkylene, unsubstituted alkyl, substituted alkyl, substituted carbonyl, unsubstituted carbonyl, substituted amido, unsubstituted amido, substituted sulfonyl, unsubstituted sulfonyl, substituted sulfonic acid, unsubstituted sulfonic acid, substituted phosphoryl, unsubstituted phosphoryl, substituted phosphonyl, or unsubstituted phosphonyl.

In some forms of Formula III′, X and Z are nitrogen, and Y is carbon.

In some forms of Formula III′, X and Z are carbon and Y is nitrogen.

In some forms, the compound is as described above for Formula III′, except that Li is oxygen or NR, wherein R_{c} is hydrogen, unsubstituted alkyl, substituted alkyl, unsubstituted aryl, substituted aryl, unsubstituted heteroaryl, or substituted heteroaryl.

In some forms, the compound is as described above for Formula III′, except that Li is oxygen.

In some forms, the compound is as described above for Formula III′, except that Li is NR, wherein R_{c} is hydrogen, unsubstituted alkyl, substituted alkyl, unsubstituted aryl, substituted aryl, unsubstituted heteroaryl, or substituted heteroaryl.

In some forms, the compound is as described above for Formula III′, except that L₂ is oxygen.

In some forms, the compound is as described above for Formula III′, except that L₂ is C₁-C₅ substituted alkyl, such as iso-propyl.

In some forms, the compound is as described above for Formula III′, except that L₃ is a single bond.

In some forms, the compound is as described above for Formula III′, except that at least one of Rₐ and R_{b} is an unsubstituted aryl or substituted aryl, preferably substituted with C₃-C₁₀ substituted alkyl such as t-butyl or C₁-C₁₀ unsubstituted alkyl such as methyl, or —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl.

In some forms, the compound is as described above for Formula III′, except that at least one of Rₐ and R_{b} is an unsubstituted aryl or substituted aryl, preferably substituted with C₃-C₁₀ substituted alkyl such as t-butyl or C₁-C₁₀ unsubstituted alkyl such as methyl.

In some forms, the compound is as described above for Formula III′, except that Rₐ and R_{b} are both an unsubstituted aryl or substituted aryl, preferably substituted with C₃-C₁₀ substituted alkyl such as t-butyl or C₁-C₁₀ unsubstituted alkyl such as methyl.

In some forms, the compound is as described above for Formula III′, except that —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl.

In some forms, the compound is as described above for Formula III′, except that —NRₐR_{b} has a structure:

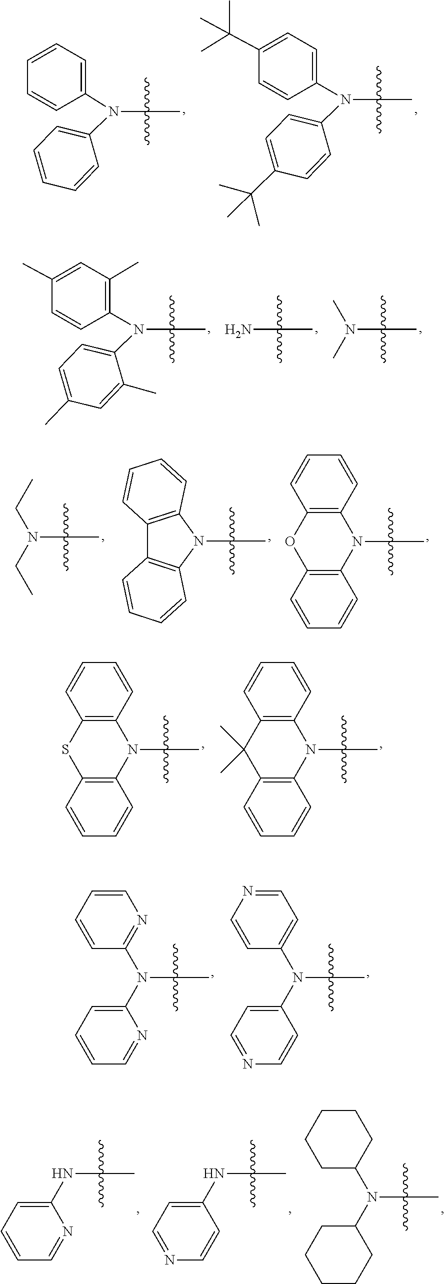

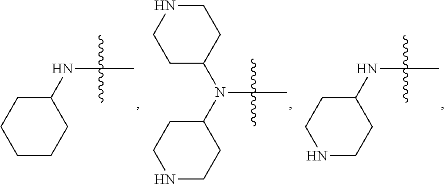 [SMILES: *NC1CCCCC1 ; *N(C1CCNCC1)C1CCNCC1 ; *NC1CCNCC1]

or a combination thereof. In some forms, the compound is as described above for Formula III′, except that —NRₐR_{b} has a structure:

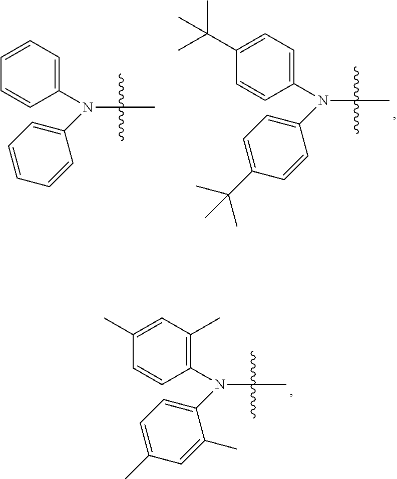 [SMILES: *N(c1ccccc1)c1ccccc1 ; *N(c1ccc(C(C)(C)C)cc1)c1ccc(C(C)(C)C)cc1 ; *N(c1ccc(C)cc1C)c1ccc(C)cc1C]

or a combination thereof.

In some forms, the compound is as described above for Formula III′, except that R₇ is hydrogen, substituted alkyl, or substituted aryl.

In some forms, the compound is as described above for Formula III′, except that R₇ is a C₃-C₁₀ substituted alkyl, preferably t-butyl.

In some forms, the compound is as described above for Formula III′, except that R₇ is substituted aryl, preferably substituted with between one and five C₁-C₁₀ unsubstituted alkyl groups. In some forms, the compound is as described above for Formula III′, except that R₇ has a structure:

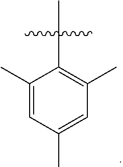

In some forms, the compound is as described above for Formula III′, except that R₁₂-R₁₄ are independently hydrogen or halogen. In some forms, the compound is as described above for Formula III′, except that (i) R₁₂ and R₁₄ are halogen, or (ii) R₁₂-R₁₄ are halogen, preferably wherein the halogen is fluorine.

In some forms, the compound is as described above for Formula III′, except that R₁₆ is hydrogen, substituted alkyl, unsubstituted alkyl, substituted aryl, unsubstituted aryl, unsubstituted alkoxy, unsubstituted alkoxy, or —NR_{d}Rₑ, wherein R_{d} and Rₑ are independently hydrogen, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, unsubstituted aryl, substituted alkyl, or unsubstituted alkyl, or —NR_{d}Rₑ together form a substituted polyheteroaryl, unsubstituted polyheteroaryl, substituted polyheterocyclyl, unsubstituted polyheterocyclyl, substituted heterocyclyl, or unsubstituted heterocyclyl.

In some forms, the compound is as described above for Formula III′, except that R₁₆ is —NR_{d}Rₑ, wherein R_{d} and Rₑ are C₁-C₅ unsubstituted alkyl, preferably methyl.

In some forms, the compound is as described above for Formula III′, except that —NRₐR_{b} has a structure:

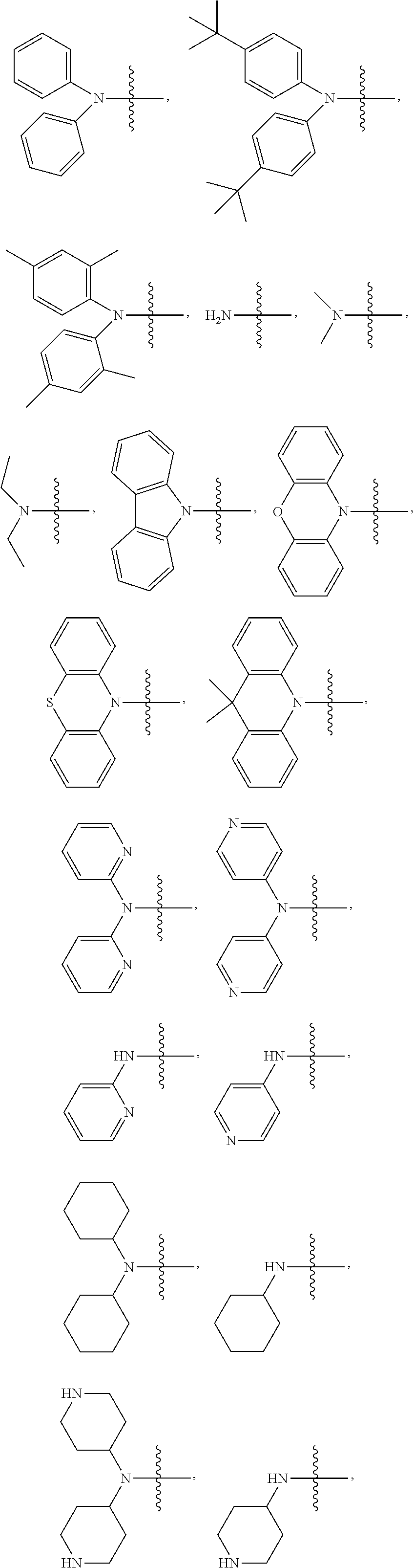

or a combination thereof.

In some forms, the compound is as described above for Formula III′, except that R₁₆ is hydrogen.

In some forms, the compound is as described above for Formula III′, except that R₁₆ is a substituted alkyl, such as t-butyl.

In some forms, the compound is as described above for Formula III′, except that R₁₆ is substituted aryl, preferably substituted with between one and five C₁-C₁₀ unsubstituted alkyl groups. In some forms, the compound is as described above for Formula III′, except that R₁₆ has a structure:

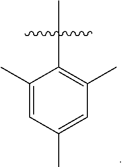

In some forms, the compound is as described above for Formula III′, except that R₁₆ is an unsubstituted alkoxy, such as C₁-C₅ unsubstituted alkoxy, preferably methoxy.

In some forms, the compound is as described above for Formula I, except that the compound has a structure:

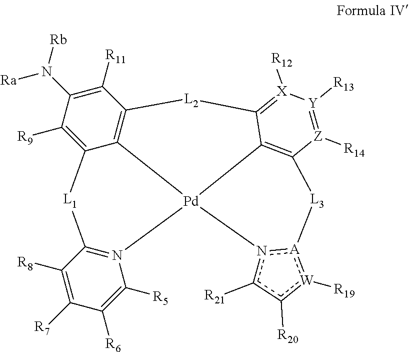

wherein:
either X and Z are nitrogen, and Y is carbon, or X and Z are carbon and Y is nitrogen,
A is nitrogen or carbon,
W is nitrogen, carbon, oxygen, or sulfur,
the dashed lines denote the presence or absence of a bond, according to valency,
R₅-R₉, R₁₁-R₁₄, and R₁₉-R₂₁ are independently absent, hydrogen, substituted amino, unsubstituted amino, substituted alkyl, unsubstituted alkyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl,
Rₐ and R_{b} are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl, or —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl, and
L₁, L₂, and L₃ are independently a bond (single, double, or triple), absent, oxygen, sulfur, substituted amino, unsubstituted amino, unsubstituted alkylene, substituted alkylene, unsubstituted alkyl, substituted alkyl, substituted carbonyl, unsubstituted carbonyl, substituted amido, unsubstituted amido, substituted sulfonyl, unsubstituted sulfonyl, substituted sulfonic acid, unsubstituted sulfonic acid, substituted phosphoryl, unsubstituted phosphoryl, substituted phosphonyl, or unsubstituted phosphonyl.

In some forms of Formula IV′, X and Z are nitrogen, and Y is carbon.

In some forms of Formula IV′, X and Z are carbon and Y is nitrogen.

In some forms of Formula IV′, A is carbon and W is oxygen. In some forms of Formula IV′, A is nitrogen and W is carbon. In some forms of Formula IV′, A is carbon and W is nitrogen.

In some forms, the compound is as described above for Formula IV′, except that Li is oxygen or NR, wherein R_{c} is hydrogen, unsubstituted alkyl, substituted alkyl, unsubstituted aryl, substituted aryl, unsubstituted heteroaryl, or substituted heteroaryl.

In some forms, the compound is as described above for Formula IV′, except that Li is oxygen.

In some forms, the compound is as described above for Formula IV′, except that Li is NR, wherein R_{c} is hydrogen, unsubstituted alkyl, substituted alkyl, unsubstituted aryl, substituted aryl, unsubstituted heteroaryl, or substituted heteroaryl.

In some forms, the compound is as described above for Formula IV′, except that L₂ is oxygen.

In some forms, the compound is as described above for Formula IV′, except that L₂ is C₁-C₅ substituted alkyl, such as iso-propyl.

In some forms, the compound is as described above for Formula IV′, except that L₃ is a single bond.

In some forms, the compound is as described above for Formula IV′, except that at least one of Rₐ and R_{b} is an unsubstituted aryl or substituted aryl, preferably substituted with C₃-C₁₀ substituted alkyl such as t-butyl or C₁-C₁₀ unsubstituted alkyl such as methyl, or —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl. In some forms, the compound is as described above for Formula IV′, except that at least one of Rₐ and R_{b} is an unsubstituted aryl or substituted aryl, preferably substituted with C₃-C₁₀ substituted alkyl such as t-butyl or C₁-C₁₀ unsubstituted alkyl such as methyl. In some forms, the compound is as described above for Formula IV′, except that Rₐ and R_{b} are both an unsubstituted aryl or substituted aryl, preferably substituted with C₃-C₁₀ substituted alkyl such as t-butyl or C₁-C₁₀ unsubstituted alkyl such as methyl. In some forms, the compound is as described above for Formula IV′, except that —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl.

In some forms, the compound is as described above for Formula IV′, except that —NRₐR_{b} has a structure:

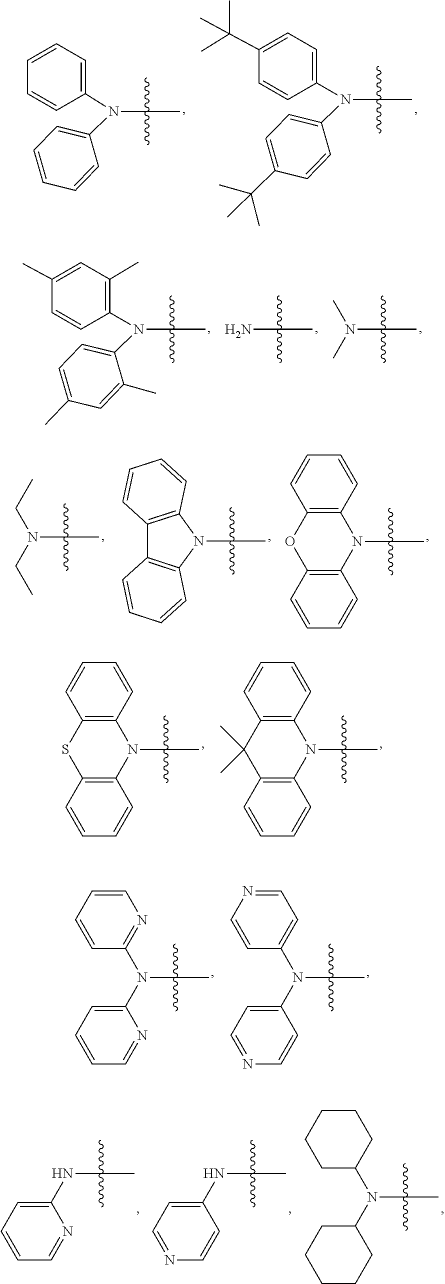

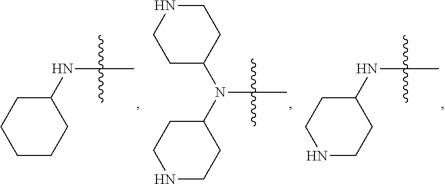 [SMILES: *NC1CCCCC1 ; *N(C1CCNCC1)C1CCNCC1 ; *NC1CCNCC1]

or a combination thereof. In some forms, the compound is as described above for Formula IV′, except that —NRₐR_{b} has a structure:

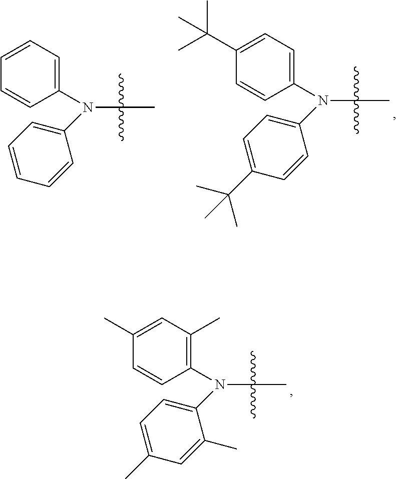 [SMILES: *N(c1ccccc1)c1ccccc1 ; *N(c1ccc(C(C)(C)C)cc1)c1ccc(C(C)(C)C)cc1 ; *N(c1ccc(C)cc1C)c1ccc(C)cc1C]

or a combination thereof.

In some forms, the compound is as described above for Formula IV′, except that R₅-R₉ and R₁₁ are hydrogen.

In some forms, the compound is as described above for Formula IV′, except that R₁₂-R₁₄ are independently hydrogen or halogen. In some forms, the compound is as described above for Formula IV′, except that (i) R₁₂ and R₁₄ are halogen, or (ii) R₁₂-R₁₄ are halogen, preferably wherein the halogen is fluorine.

In some forms, the compound is as described above for Formula IV′, except that A is carbon, W is nitrogen, and R₁₉ is hydrogen, unsubstituted alkyl, or substituted alkyl. Preferably, in these forms, R₁₉ is unsubstituted C₁-C₅ alkyl, such as methyl.

In some forms, the compound is as described above for Formula IV′, except that R₂₀ and R₂₁ are hydrogen.

In some forms, the compound of Formula I, Formula II′, Formula III′, or Formula IV′ has a structure:

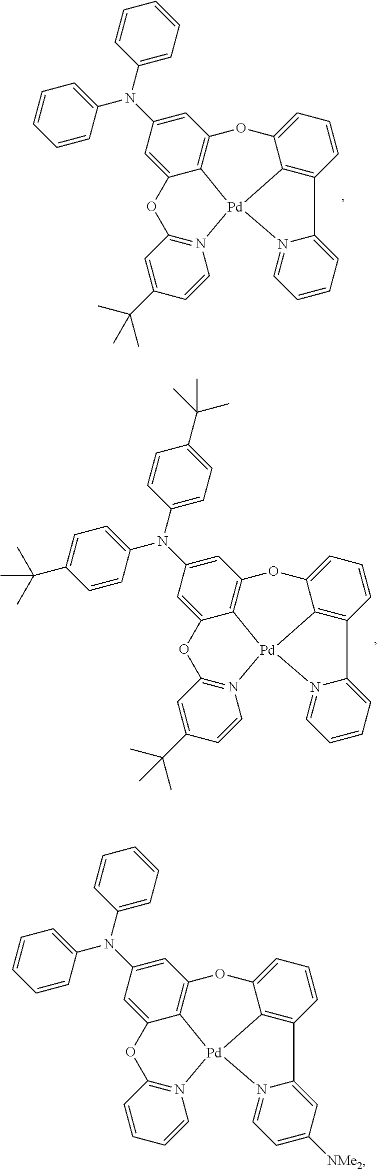

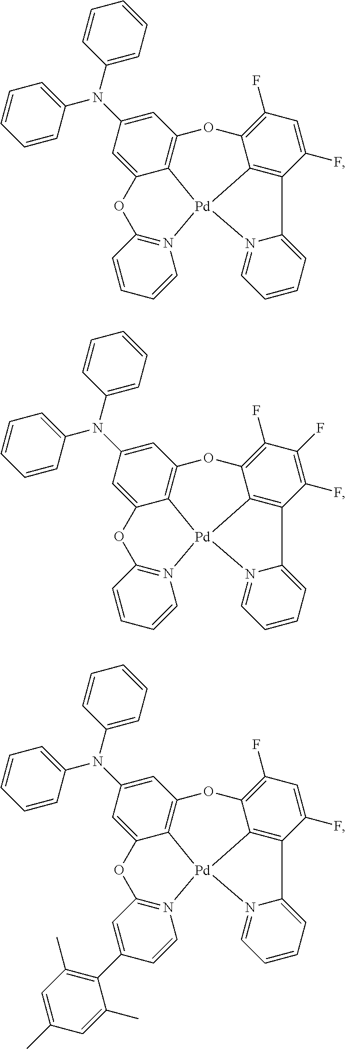

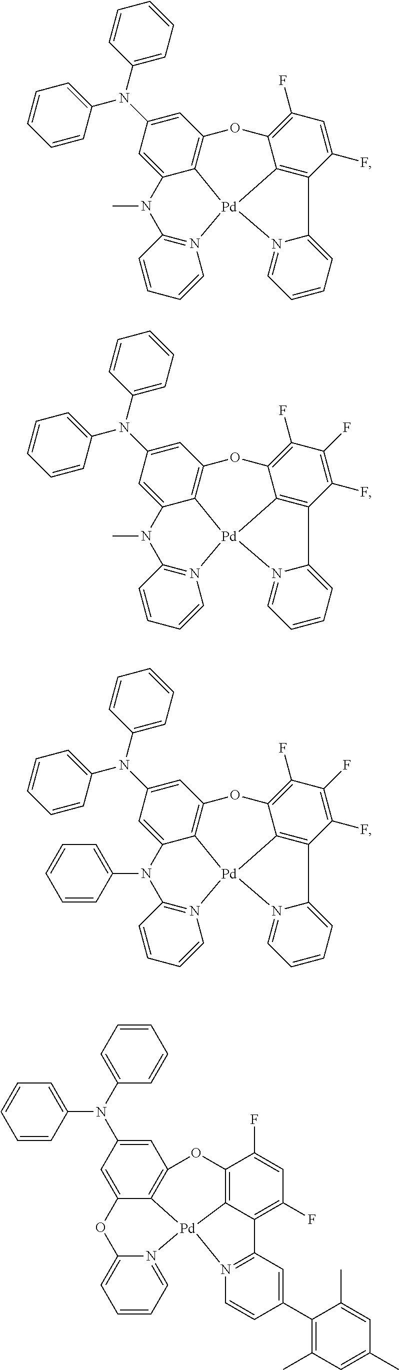

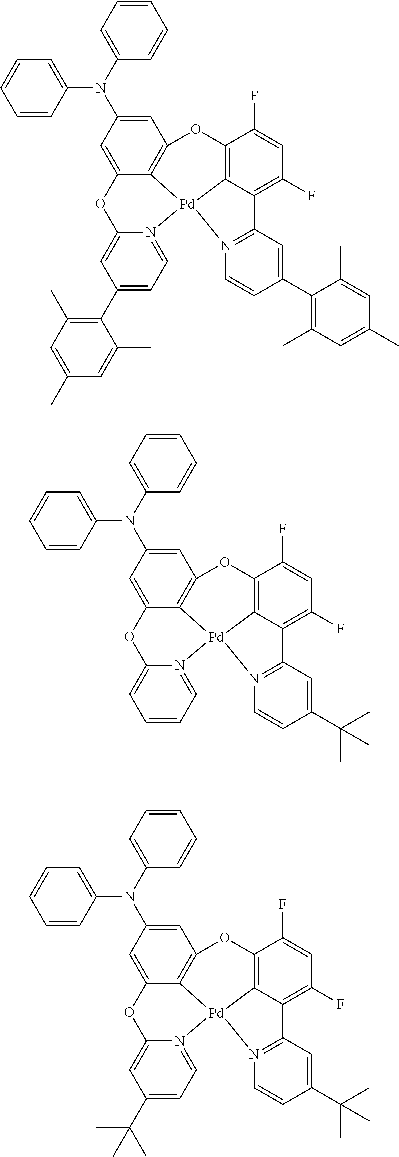

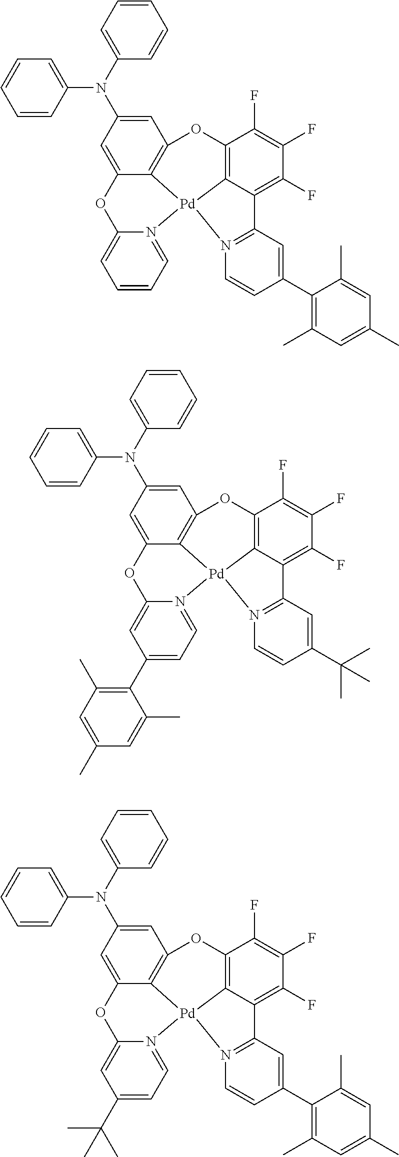

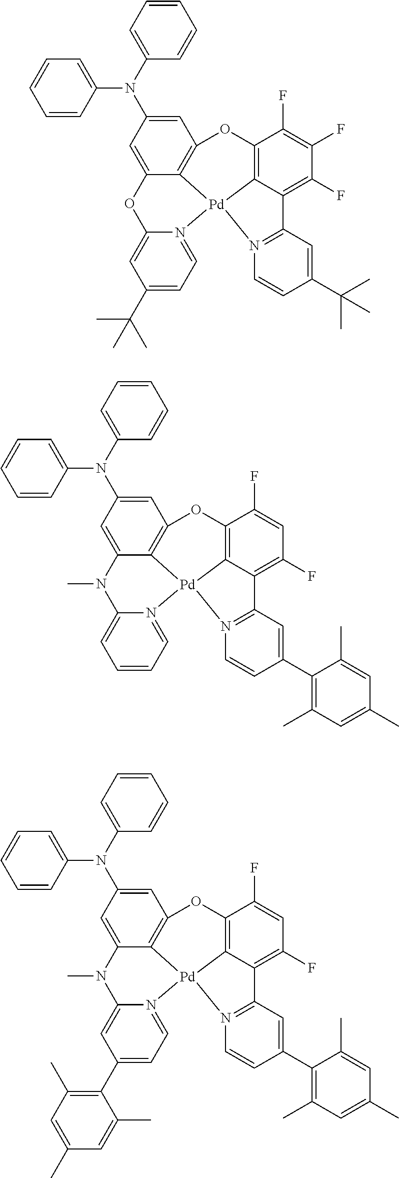

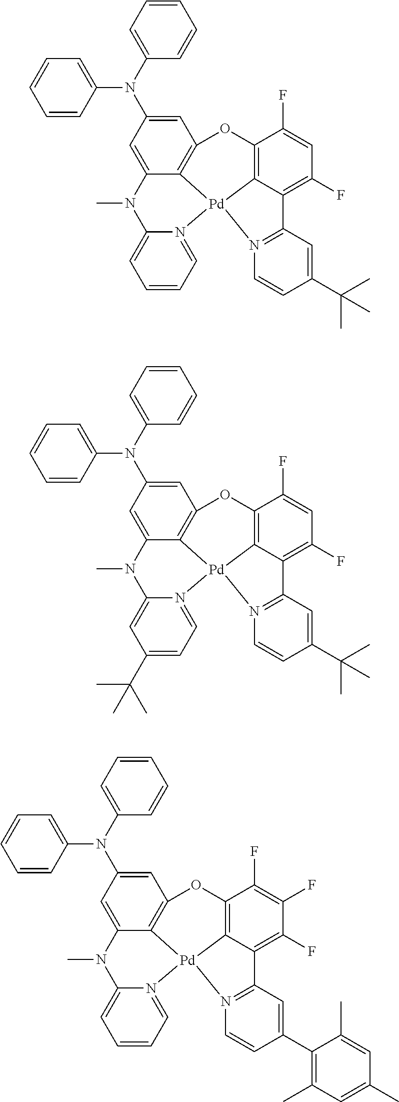

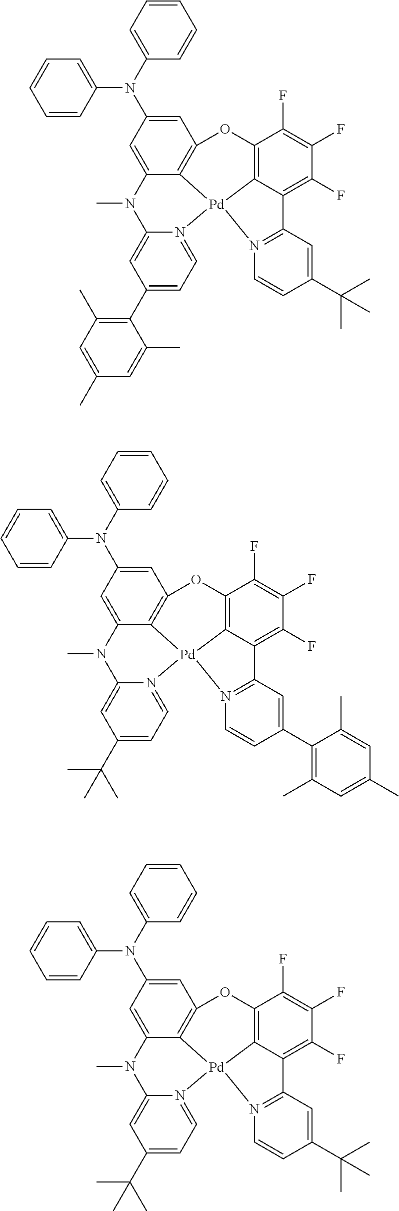

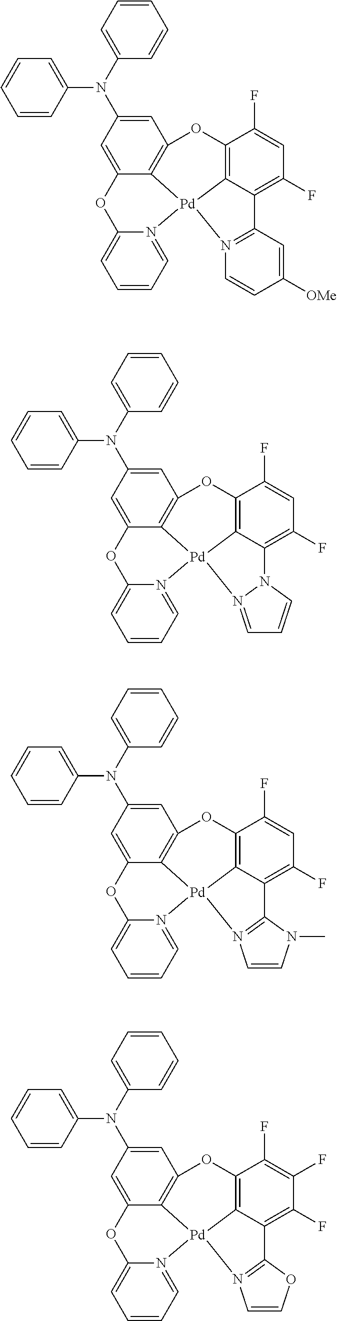

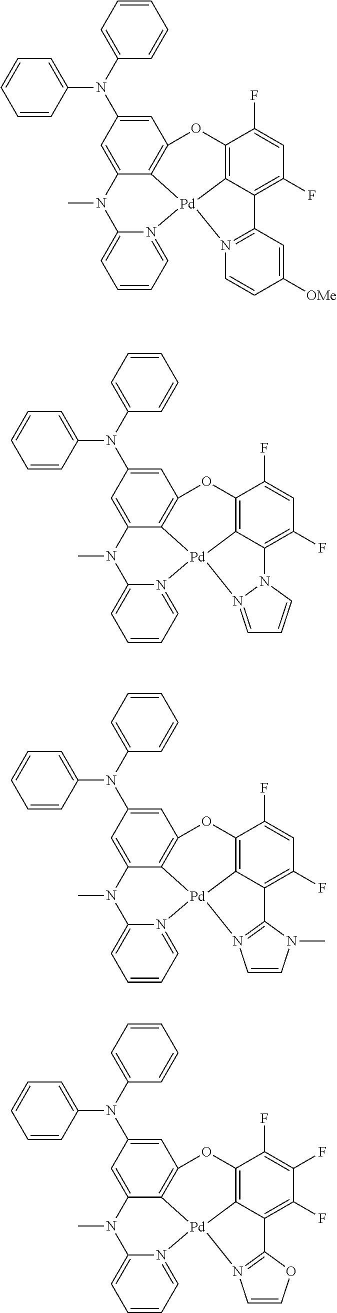

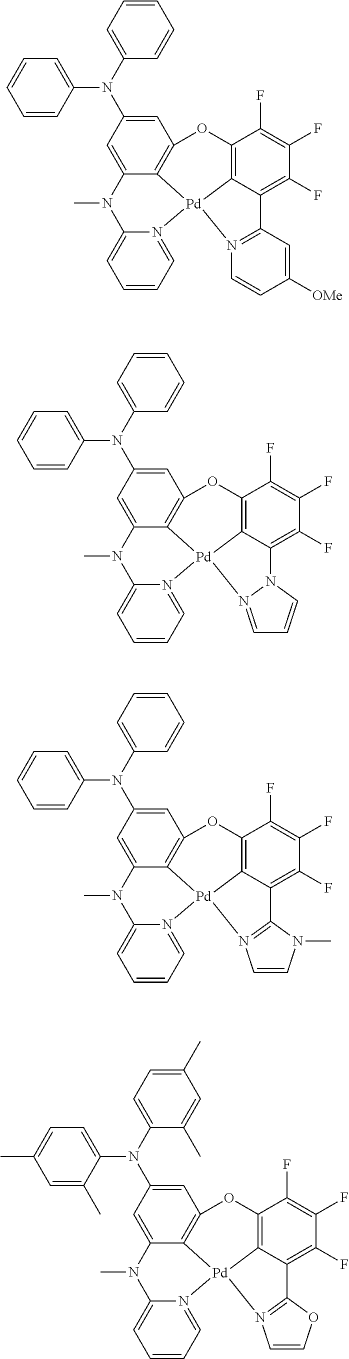

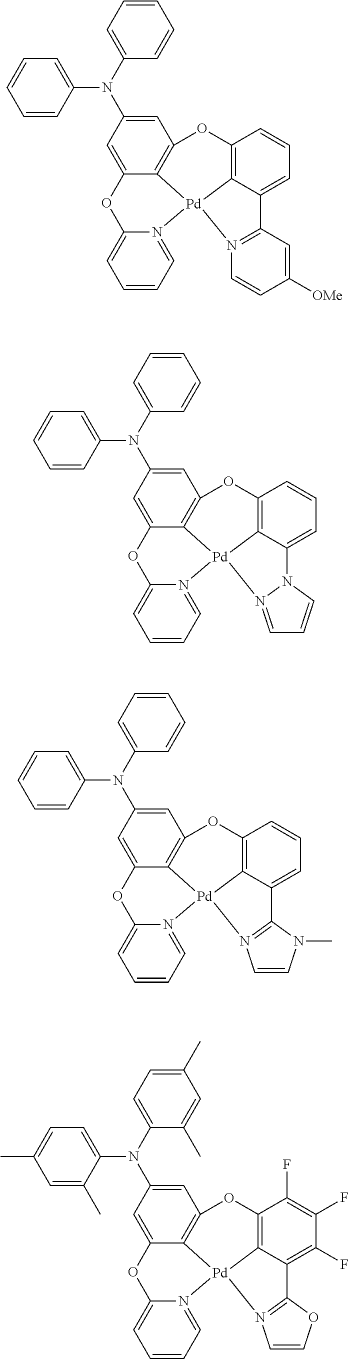

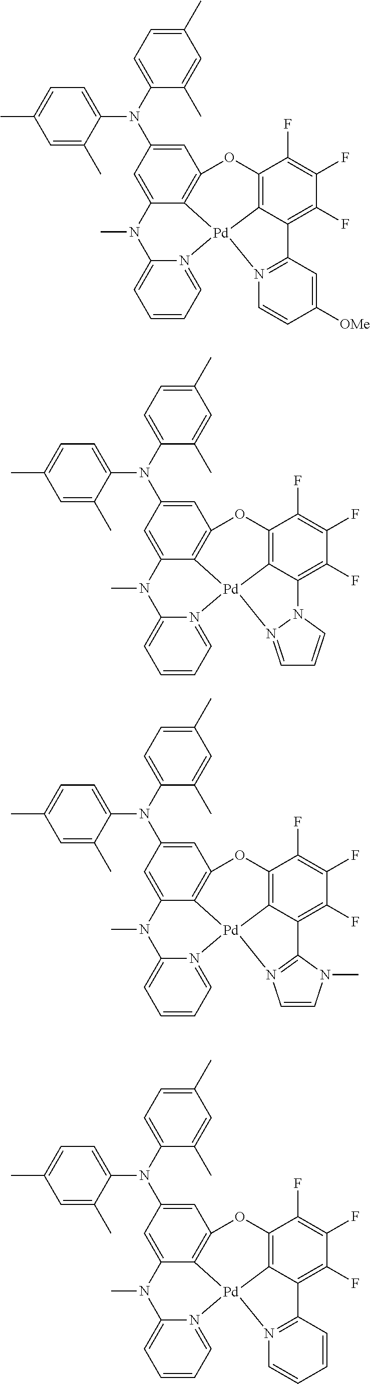

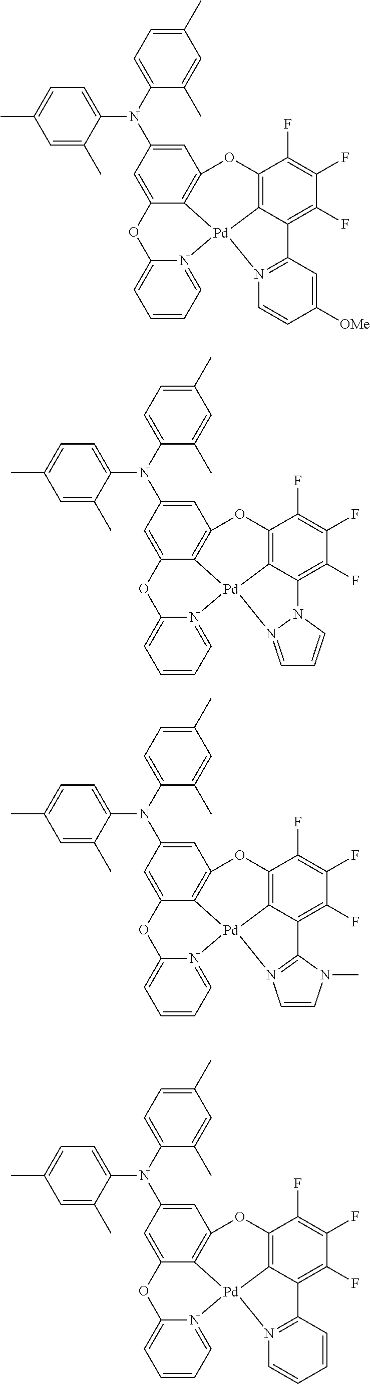

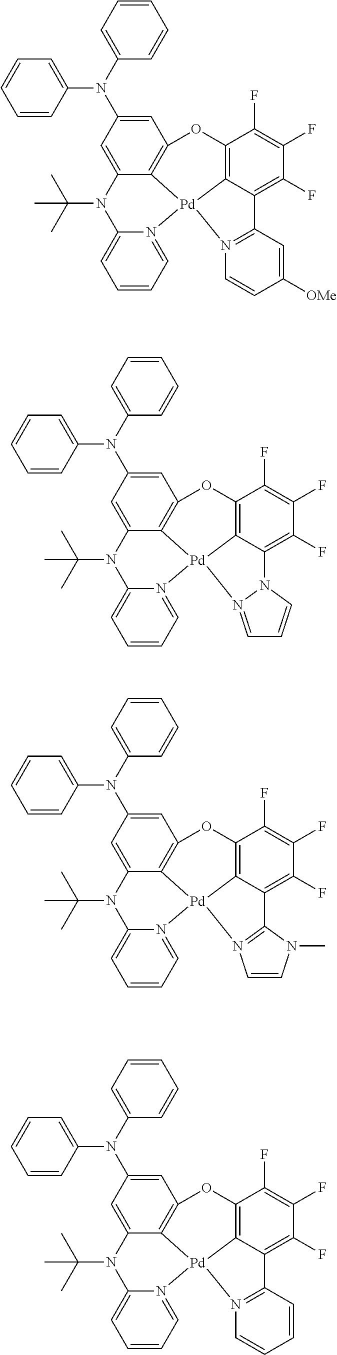

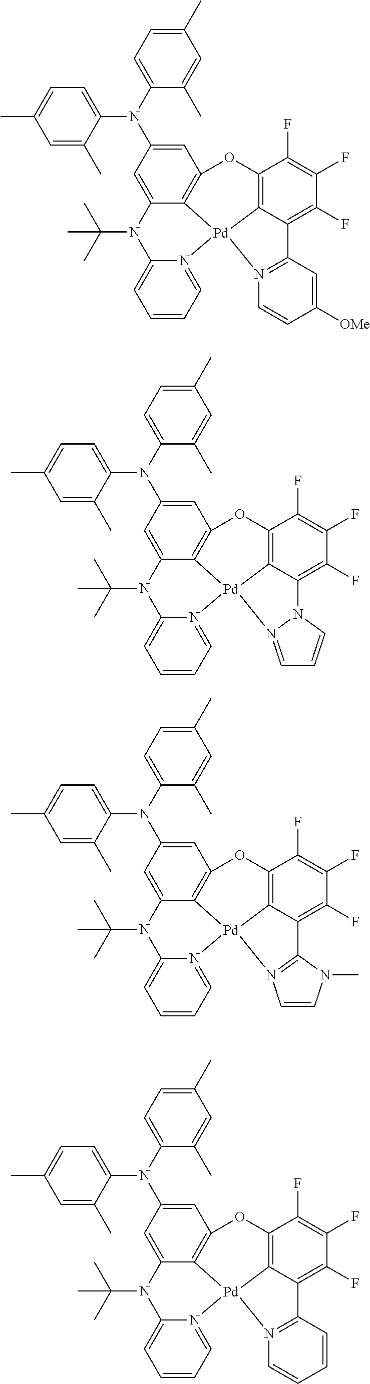

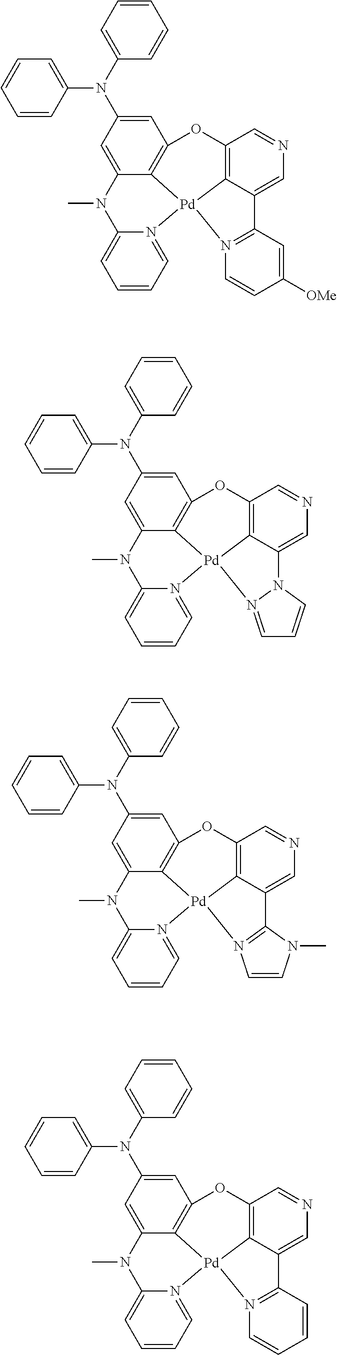

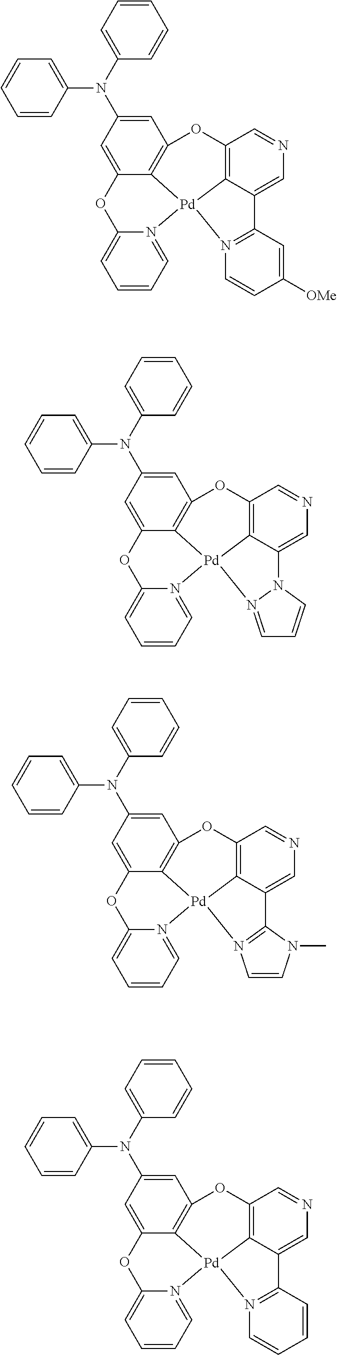

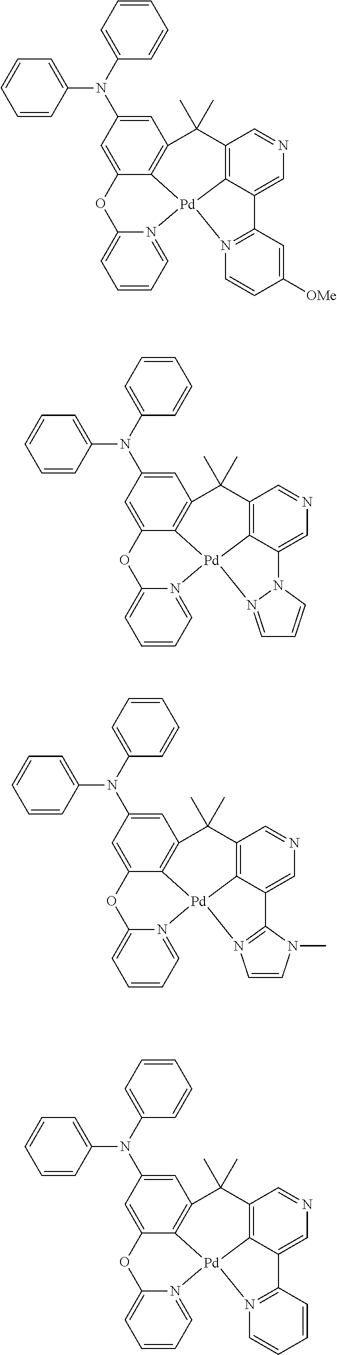

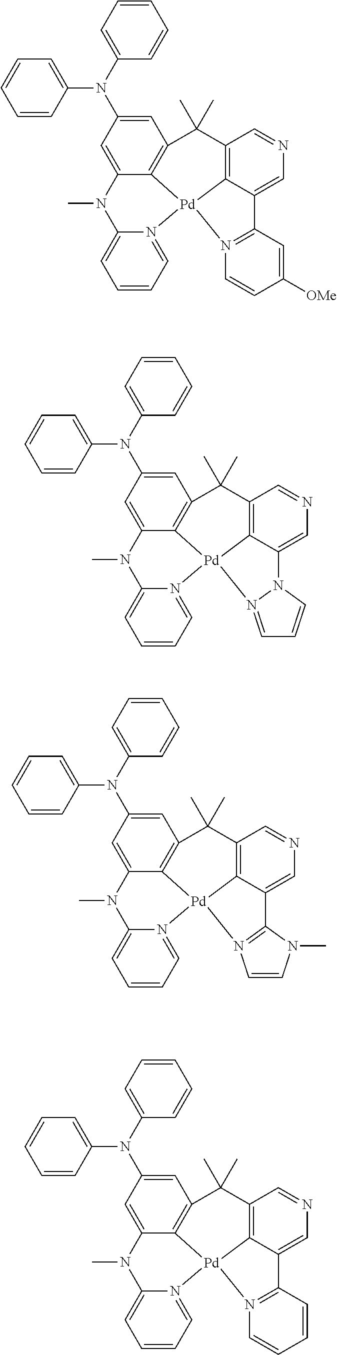

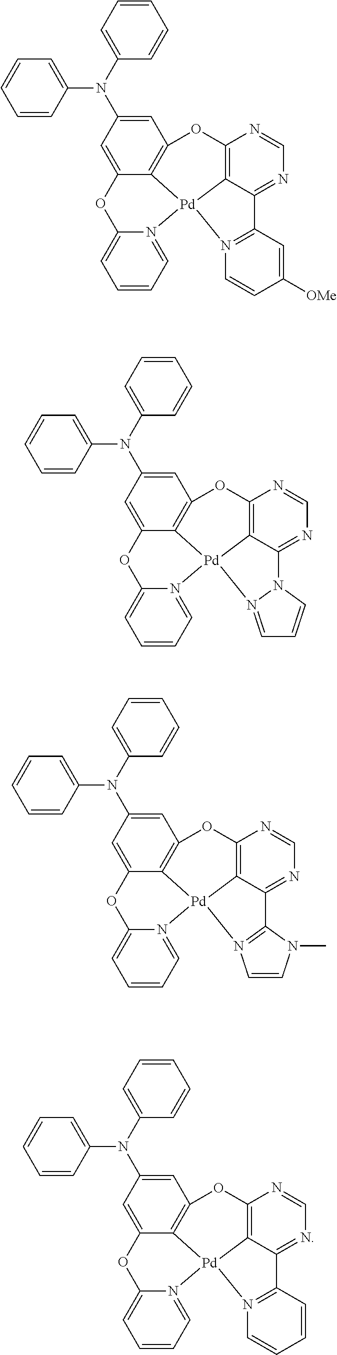

In some forms, the compounds have an emission lifetime (τ) between 1.0 μs and 10 μs, inclusive, or between 1.1 μs and 8.7 μs, inclusive, in solution, such as 1.1 μs or 8.7 μs. In some forms, the compounds have a radiative rate constant between 1.0×10⁵ s⁻¹ and 10.0×10⁵ s⁻¹, inclusive, between 1.0×10⁵ s⁻¹ and 8.0×10⁵ s⁻¹, inclusive, or between 2.0×10⁵ s⁻¹ and 7.0×10⁵ s⁻¹, inclusive, in solution, such as 6.0×10⁵ s⁻¹. In some forms, the compounds have a photoluminescence quantum yield (PLQY) between 10% and 80%, inclusive, in solution, at room temperature. In some forms, the PLQY is for an emission in solution, with an emission maximum between 430 nm and 650 nm, inclusive, such as between 496 nm and 558 nm, inclusive. Exemplary solutions include those that contain an organic solvent. Organic solvents are known in the art and include dichloromethane and toluene.

In some forms, the compounds have an emission lifetime (τ) between 3.5 μs and 40 μs, inclusive, or between 4.4 μs and 35 μs, inclusive, in thin films, such as 4.4 μs or 35 μs. In some forms, the compounds have a radiative rate constant between 1.0×10⁵ s⁻¹ and 7.5×10⁵ s⁻¹, inclusive, between 1.0×10⁵ s⁻¹ and 5.0×10⁵ s⁻¹, inclusive, or between 1.5×10⁵ s⁻¹ and 4.0×10⁵ s⁻¹, inclusive, in thin films. In some forms, the compounds have a PLQY between 15% and 65%, inclusive, between 40% and 65%, inclusive, between 45% and 65%, inclusive, between 50% and 65%, inclusive, or between 55% and 60%, inclusive, in thin films. In some forms, the PLQY is for an emission in thin films, with an emission maximum between 430 nm and 650 nm, inclusive, such as between 476 nm and 560 nm, inclusive. Suitable thin films include films having a thickness between 10 nm and 5 μm, inclusive, preferably between 10 nm and 200 nm, inclusive. The films can also contain organic compounds. Exemplary organic compounds include, but are not limited to, host materials such as 2,8-bis(diphenylphosphoryl)dibenzo[b,d]furan (PPF), bis[2-(diphenylphosphino)phenyl]ether oxide (DPEPO), 1,3-bis(N-carbazolyl)benzene (mCP), 3,3′-di(9H-carbazol-9-yl)-1,1′-biphenyl (mCBP), poly(methyl methacrylate) (PMMA), polystyrene (PS), or a combination thereof.

### III. Methods of Making and Reagents Therefor

### A. Compounds

The transition metal complexes and their ligands described herein can be synthesized using methods known in the art of organic chemical synthesis. The target compound can be synthesized by reacting the corresponding tetradentate ligand, a corresponding tetradentate ligand precursor, or a combination thereof, with a palladium compound in a solvent or solution. Exemplary solvents include organic solvents, such as acetic acid. The solution containing a corresponding tetradentate ligand, a corresponding tetradentate ligand precursor, or a combination thereof, and a palladium compound can be refluxed for a suitable time to form the target compound. Specific compounds, such as those containing palladium(II) are disclosed in the Examples.

### B. Organic Light-Emitting Devices

Also described are methods of making organic light-emitting devices, such as OLEDs, containing one or more transition metal complexes described above for Formula I. A preferred method of making the OLEDs involves vacuum deposition or solution processing techniques such as spin-coating and ink printing (such as, ink-jet printing or roll-to-roll printing). A method of making an OLED including a transition metal complex described herein is disclosed in the Examples.

### IV. Methods of Using

Preferably, the transition metal complexes described herein are photo-stable, and are emissive at room temperatures, low temperatures, or a combination thereof. Accordingly, the compounds described herein can be incorporated into OLEDs, an organic photovoltaic cell (OPV), and organic field-effect transistor (OFET), or a light-emitting electrochemical cell (LEEC), and used in a stationary visual display unit, a mobile visual display unit, or an illumination device. Examples of units or devices include commercial applications such as smart phones, televisions, monitors, digital cameras, tablet computers, keyboards, clothes ornaments, garment accessories, wearable devices, medical monitoring devices, wall papers, advertisement panels, laptops, household appliances, office appliances, and lighting fixtures. Preferably, these units or devices are those that usually operate at room temperatures.

In some forms, the compounds can be included in light-emitting layer. In some forms, the light-emitting layer can be included in an OLED.

The disclosed compounds, methods of using, and methods of making can be further understood through the following enumerated paragraphs or embodiments.

1. A compound having a structure:

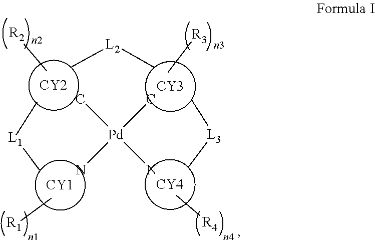

wherein:
the compound has an overall neutral, negative, or positive charge,
CY1 and CY4 are independently unsubstituted heteroaryl, substituted heteroaryl, unsubstituted polyheteroaryl, substituted polyheteroaryl, unsubstituted C₂-C₂₀ heterocyclyl, or substituted C₂-C₂₀ heterocyclyl,
CY2 and CY3 are independently unsubstituted aryl, substituted aryl, unsubstituted polyaryl, substituted polyaryl, unsubstituted heteroaryl, substituted heteroaryl, unsubstituted polyheteroaryl, substituted polyheteroaryl, unsubstituted C₃-C₂₀ cycloalkyl, substituted C₂-C₂₀cycloalkyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl,
each R₁, R₂, R₃, and R₄ is independently, absent, hydrogen, substituted amino, unsubstituted amino, substituted alkyl, unsubstituted alkyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, wherein at least one of R₁, R₂, R₃, and R₄ is present and is an electron donating group,
n1, n2, n3, and n4 are independently an integer between zero and 10, inclusive, with the proviso that at least one of n1, n2, n3, and n4 is not zero, and
L₁, L₂, and L₃ are independently a bond (single, double, or triple), absent, oxygen, sulfur, substituted amino, unsubstituted amino, unsubstituted alkylene, substituted alkylene, unsubstituted alkyl, substituted alkyl, substituted carbonyl, unsubstituted carbonyl, substituted amido, unsubstituted amido, substituted sulfonyl, unsubstituted sulfonyl, substituted sulfonic acid, unsubstituted sulfonic acid, substituted phosphoryl, unsubstituted phosphoryl, substituted phosphonyl, or unsubstituted phosphonyl.

2. The compound of paragraph 1, having an overall neutral charge.

3. The compound of paragraph 1 or 2, wherein each R₁, R₂, R₃, and R₄ is independently absent, hydrogen, substituted amino, unsubstituted amino, substituted alkyl, unsubstituted alkyl, substituted aryl, halogen, hydroxyl, thiol, unsubstituted alkoxy, substituted alkoxy, unsubstituted aroxy, substituted aroxy, unsubstituted alkylthio, or substituted alkylthio.

4. The compound of any one of paragraphs 1 to 3, wherein each R₁, R₂, R₃, and R₄ is independently hydrogen, substituted amino, unsubstituted amino, substituted alkyl, unsubstituted alkyl, substituted aryl, or halogen.

5. The compound of any one of paragraphs 1 to 4, wherein CY1 and CY4 are independently unsubstituted heteroaryl or substituted heteroaryl.

6. The compound of any one of paragraphs 1 to 5, wherein CY2 and CY3 are independently unsubstituted aryl, substituted aryl, unsubstituted heteroaryl, or substituted heteroaryl.

7. The compound of any one of paragraphs 1 to 6, wherein L₁, L₂, and L₃ are independently a single bond, oxygen, substituted alkyl, or substituted amino.

8. The compound of any one of paragraphs 1 to 7, wherein at least one R₂ has a structure —NRₐR_{b}, wherein Rₐ and R_{b} are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl, or —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl.

9. The compound of any one of paragraphs 1 to 8, wherein at least one R₂ has a structure —NRₐR_{b}, wherein at least one of Rₐ and R_{b} is an unsubstituted aryl or substituted aryl, preferably substituted with C₁-C₁₀ unsubstituted alkyl such as methyl, C₃-C₁₀ substituted alkyl such as t-butyl, or a combination thereof.

10. The compound of any one of paragraphs 1 to 9, wherein at least one R₂ has a structure —NRₐR_{b}, wherein Rₐ and R_{b} are both an unsubstituted aryl or substituted aryl, preferably substituted with (i) C₃-C₁₀ substituted alkyl such as t-butyl or (ii) C₁-C₁₀ unsubstituted alkyl such as methyl.

11. The compound of any one of paragraphs 1 to 10, having a structure:

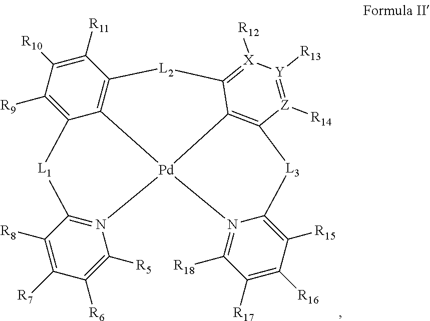

wherein for Formula II′:
either X and Z are nitrogen, and Y is carbon, or X and Z are carbon and Y is nitrogen,
R₅-R₈ are independently selected from R₁,
R₉-R₁₁ are independently selected from R₂,
R₁₂-R₁₄ are independently selected from R₃, and
R₁₅-R₁₈ are independently selected from R₄.

12. The compound of paragraph 11, wherein for Formula II′ L₁ is oxygen or NR_{c}, wherein R_{c} is hydrogen, unsubstituted alkyl, substituted alkyl, unsubstituted aryl, substituted aryl, unsubstituted heteroaryl, or substituted heteroaryl.

13. The compound of paragraph 11 or 12, wherein for Formula II′ L₁ is oxygen.

14. The compound of paragraph 11 or 12, wherein for Formula II′ L₁ is NR_{c}, wherein R_{c} is hydrogen, unsubstituted alkyl, substituted alkyl, unsubstituted aryl, substituted aryl, unsubstituted heteroaryl, or substituted heteroaryl.

15. The compound of any one of paragraphs 11 to 14, wherein for Formula II′ L₂ is oxygen or substituted alkyl.

16. The compound of any one of paragraphs 11 to 15, wherein for Formula II′ L₃ is a single bond.

17. The compound of any one of paragraphs 11 to 16, wherein for Formula II′ R₁₀ has a structure —NRₐR_{b}, wherein Rₐ and R_{b} are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl, or —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl.

18. The compound of any one of paragraphs 11 to 17, wherein for Formula II′ R₁₀ has a structure —NRₐR_{b}, wherein at least one of Rₐ and R_{b} is an unsubstituted aryl or substituted aryl, preferably substituted with C₁-C₁₀ unsubstituted alkyl such as methyl or C₃-C₁₀ substituted alkyl such as t-butyl.

19. The compound of any one of paragraphs 11 to 18, wherein for Formula II′ R₁₀ has a structure —NRₐR_{b}, wherein Rₐ and R_{b} are both an unsubstituted aryl or substituted aryl, preferably substituted with C₁-C₁₀ unsubstituted alkyl such as methyl or C₃-C₁₀ substituted alkyl such as t-butyl.

20. The compound of any one of paragraphs 11 to 19, wherein for Formula II′ R₁₀ has a structure:

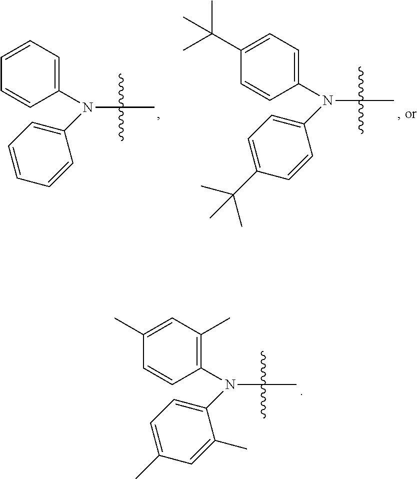 [SMILES: *N(c1ccccc1)c1ccccc1 ; *N(c1ccc(C(C)(C)C)cc1)c1ccc(C(C)(C)C)cc1 ; *N(c1ccc(C)cc1C)c1ccc(C)cc1C]

21. The compound of any one of paragraphs 11 to 20, wherein for Formula II′ R₇ is hydrogen, unsubstituted alkyl, substituted alkyl, unsubstituted aryl, or substituted aryl.

22. The compound of any one of paragraphs 11 to 21, wherein for Formula II′ R₇ is a C₃-C₁₀ substituted alkyl, preferably t-butyl.

23. The compound of any one of paragraphs 11 to 21, wherein for Formula II′ R₇ substituted aryl, preferably substituted with between one and five C₁-C₁₀ unsubstituted alkyl groups.

24. The compound of any one of paragraphs 11 to 21, or 23, wherein for Formula II′ R₇ has a structure:

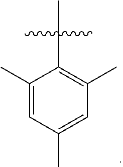

25. The compound of any one of paragraphs 11 to 24, wherein for Formula II′ R₁₂-R₁₄ are independently hydrogen or halogen.

26. The compound of any one of paragraphs 11 to 25, wherein for Formula II′ (i) R₁₂ and R₁₄ are halogen, or (ii) R₁₂-R₁₄ are halogen, preferably wherein the halogen is fluorine.

27. The compound of any one of paragraphs 11 to 26, wherein for Formula II′ R₁₆— is hydrogen, substituted alkyl, unsubstituted alkyl, substituted aryl, unsubstituted aryl, substituted alkoxy, unsubstituted alkoxy, or NR_{d}Rₑ, wherein R_{d} and Rₑ are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl, or —NR_{d}Rₑ together form a substituted polyheteroaryl, unsubstituted polyheteroaryl, substituted polyheterocyclyl, unsubstituted polyheterocyclyl, substituted heterocyclyl, or unsubstituted heterocyclyl.

28. The compound of any one of paragraphs 11 to 27, wherein for Formula II′ R₁₆ is hydrogen, unsubstituted alkoxy, substituted aryl, or unsubstituted aryl, or —NR_{d}Rₑ, wherein R_{d} and Rₑ are substituted aryl, unsubstituted aryl, or C₁-C₅ unsubstituted alkyl, preferably methyl.

29. The compound of any one of paragraphs 1 to 10, having a structure:

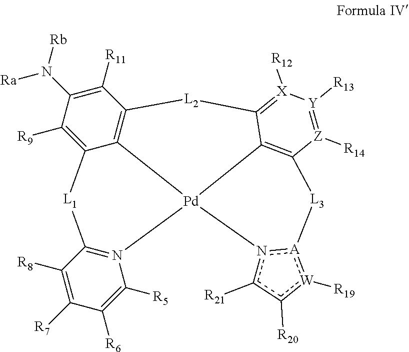

wherein for Formula IV′:
either X and Z are nitrogen, and Y is carbon, or X and Z are carbon and Y is nitrogen,
A is nitrogen or carbon,
W is nitrogen, carbon, oxygen, or sulfur,
the dashed lines denote the presence or absence of a bond, according to valency,
R₅-R₉, R₁₁-R₁₄, and R₁₉-R₂₁ are independently absent, hydrogen, substituted amino, unsubstituted amino, substituted alkyl, unsubstituted alkyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl,
Rₐ and R_{b} are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl, or —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl, and
L₁, L₂, and L₃ are independently a bond (single, double, or triple), absent, oxygen, sulfur, substituted amino, unsubstituted amino, unsubstituted alkylene, substituted alkylene, unsubstituted alkyl, substituted alkyl, substituted carbonyl, unsubstituted carbonyl, substituted amido, unsubstituted amido, substituted sulfonyl, unsubstituted sulfonyl, substituted sulfonic acid, unsubstituted sulfonic acid, substituted phosphoryl, unsubstituted phosphoryl, substituted phosphonyl, or unsubstituted phosphonyl.

30. The compound of any one of paragraphs 11 to 29, having a structure:

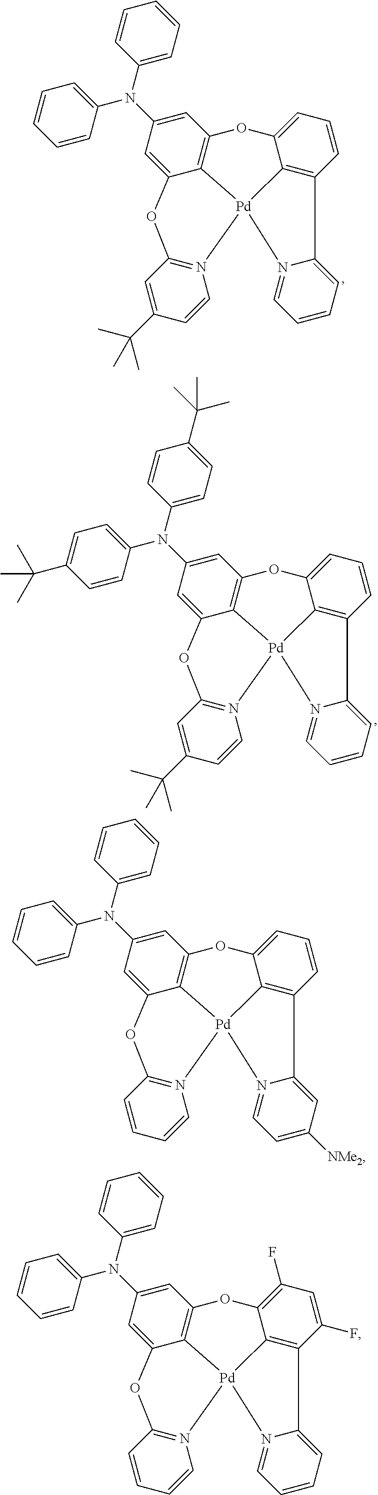

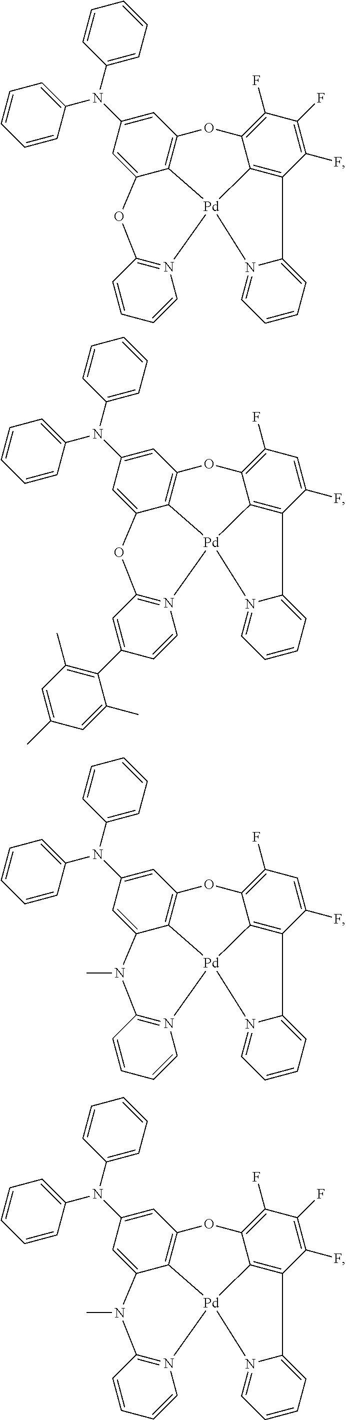

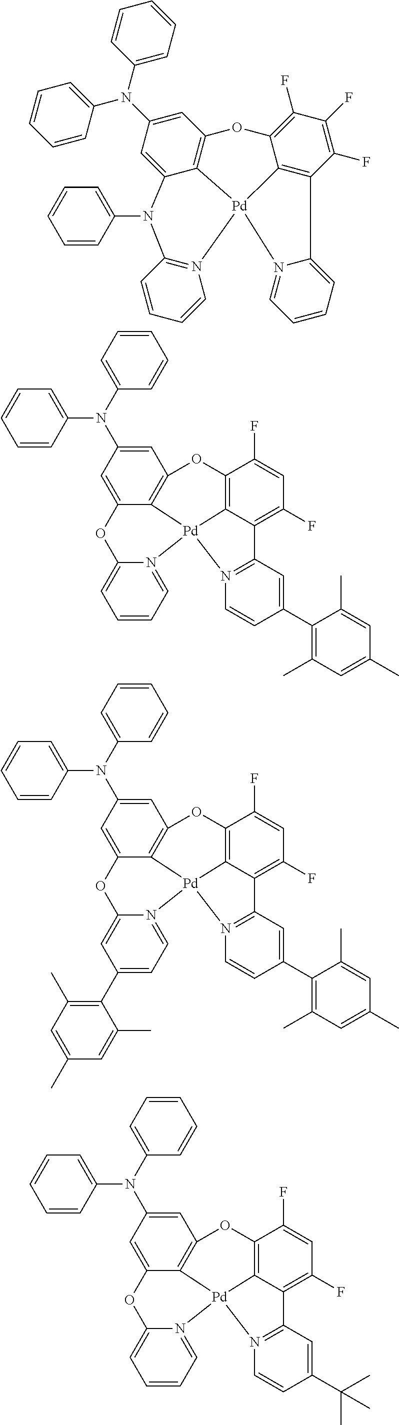

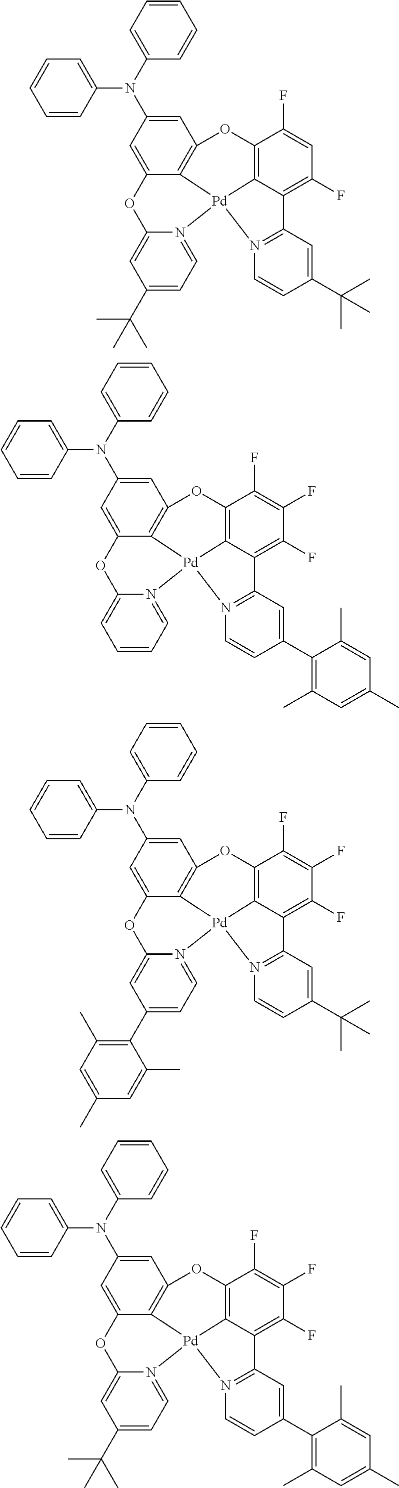

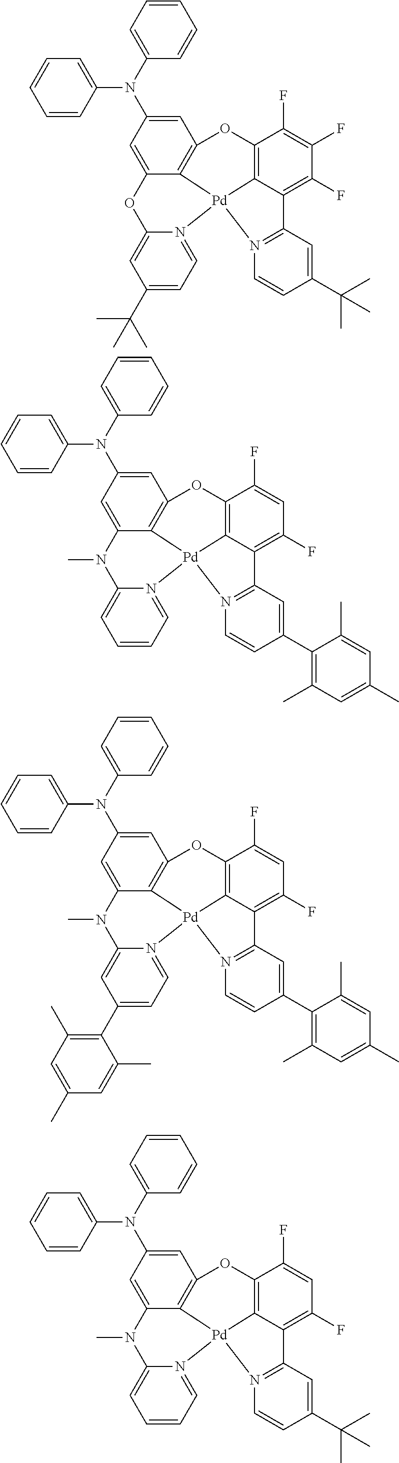

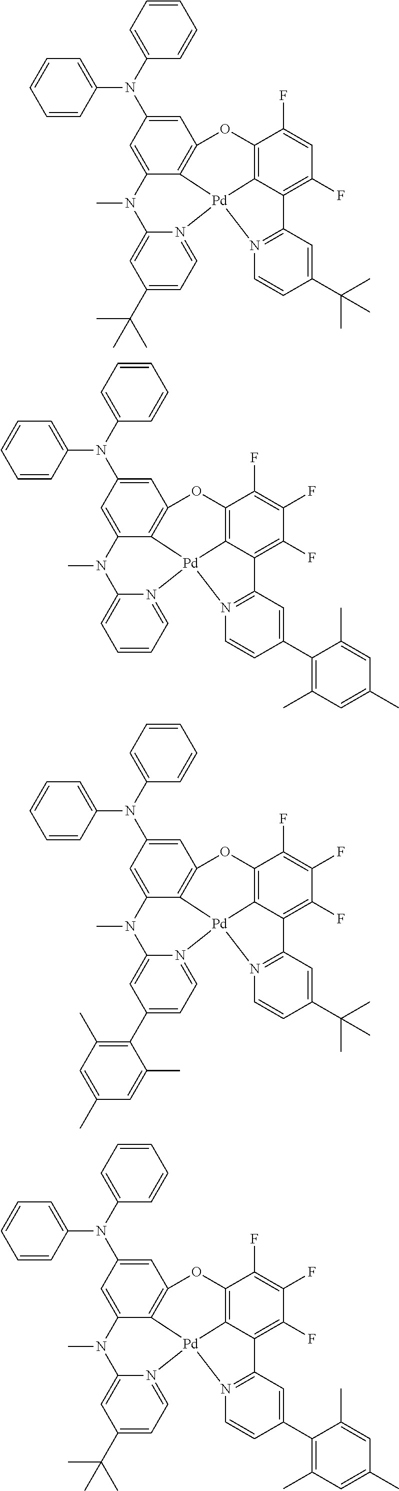

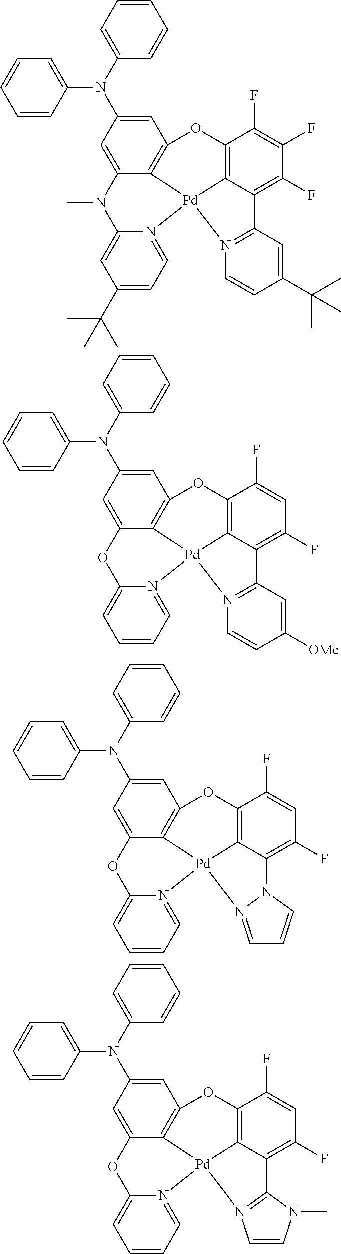

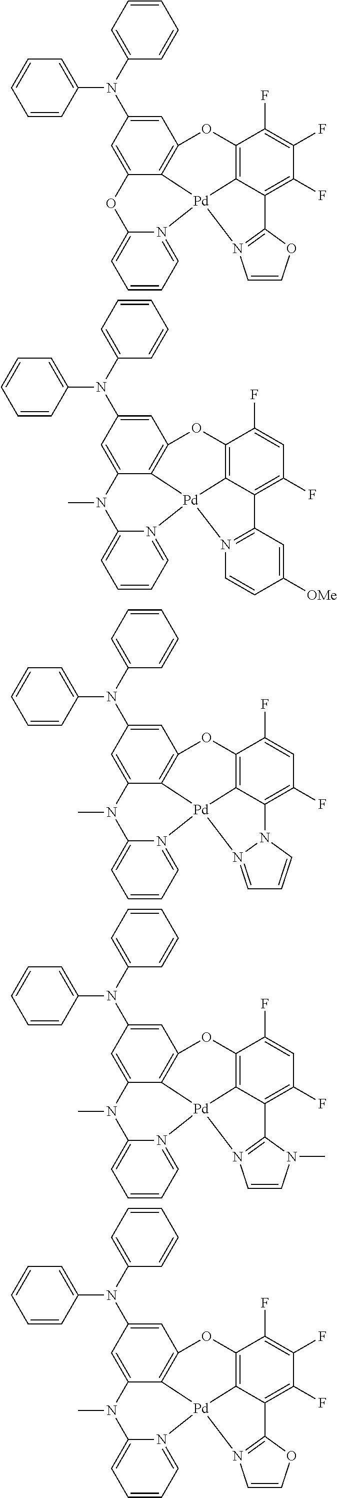

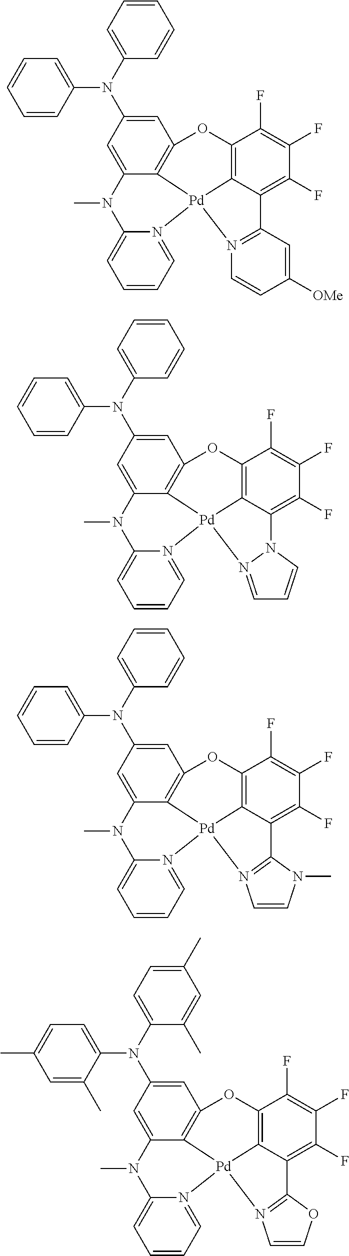

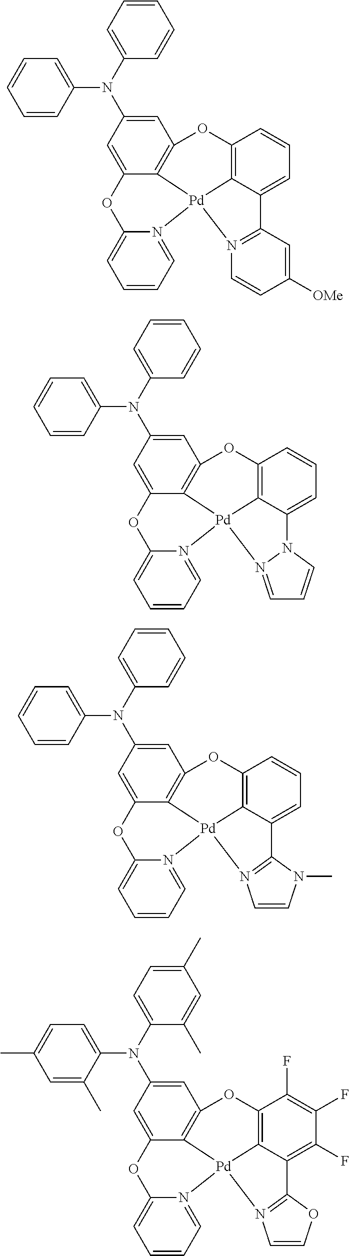

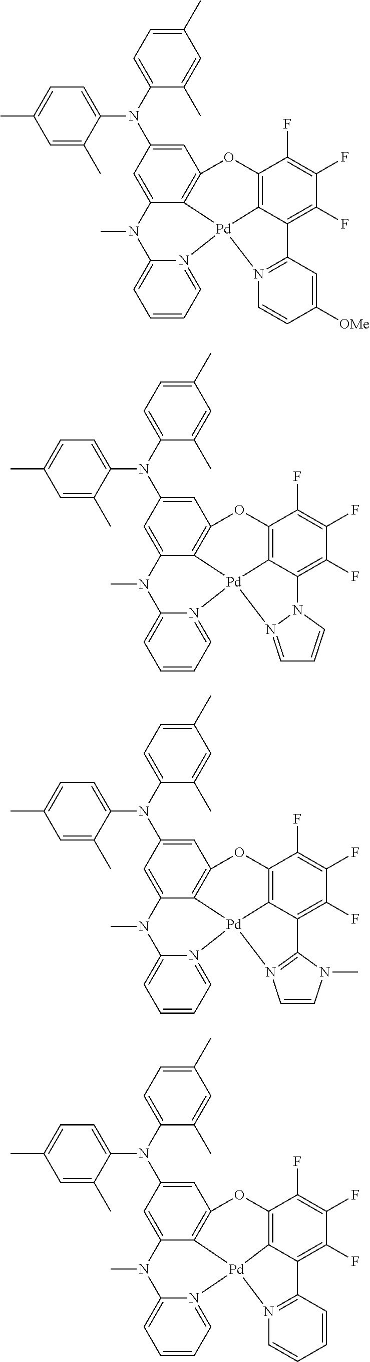

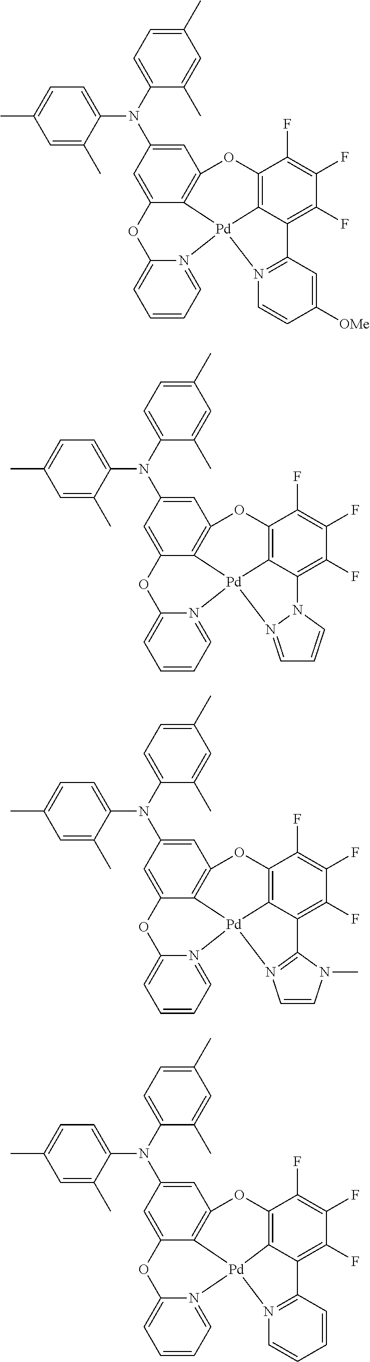

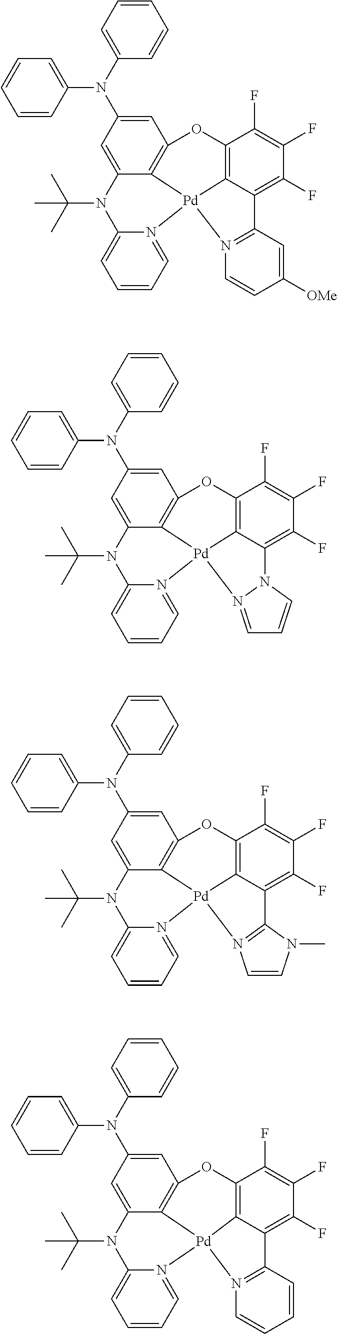

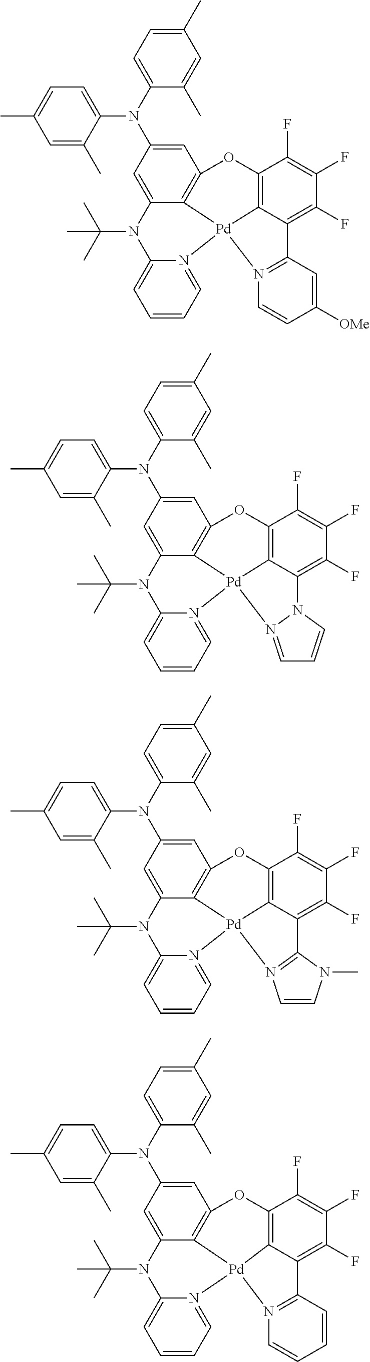

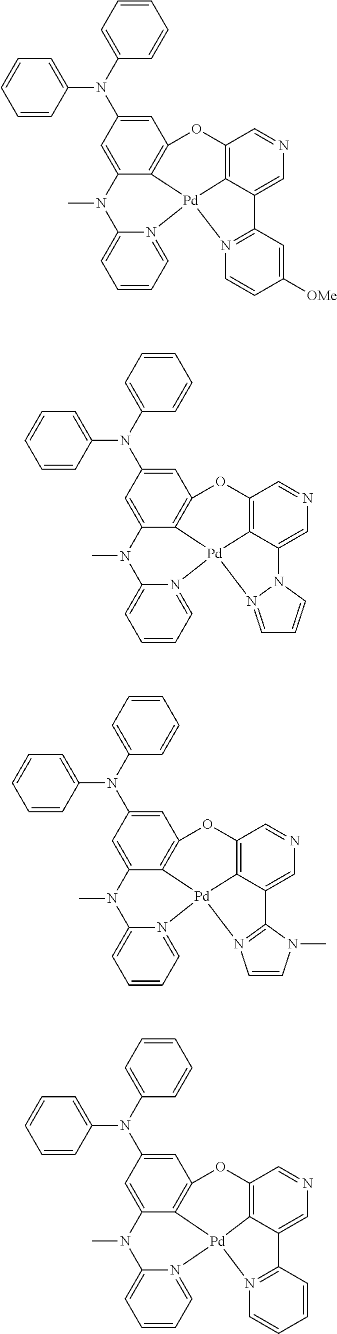

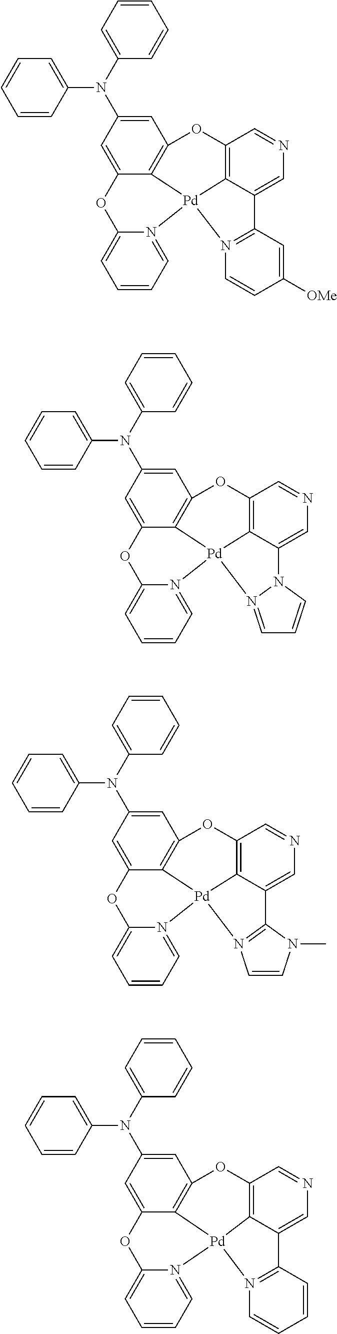

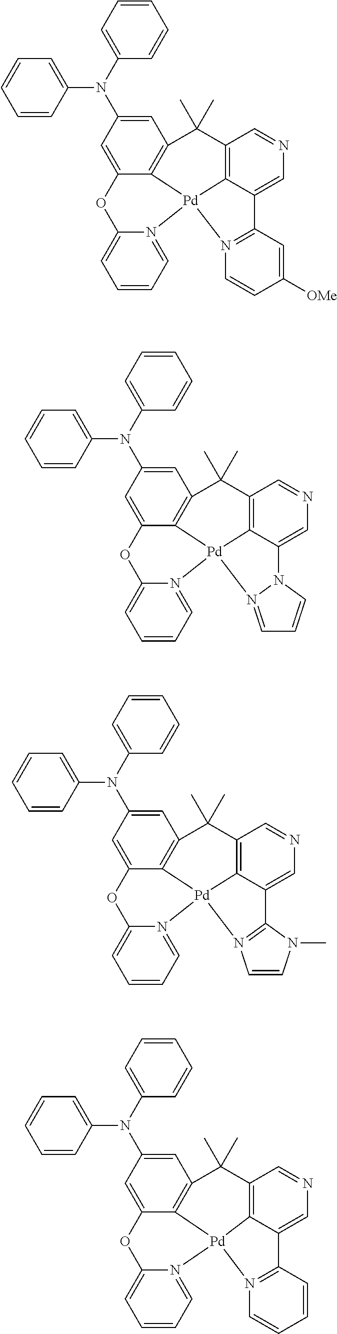

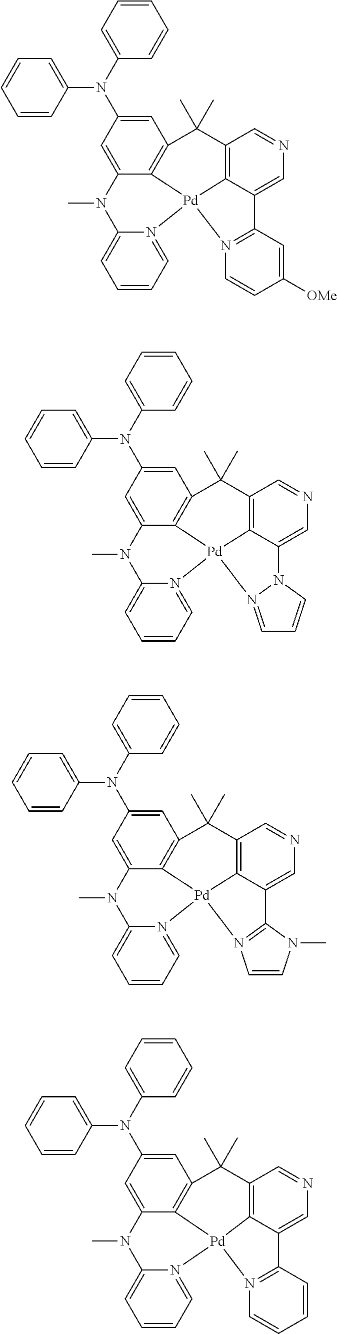

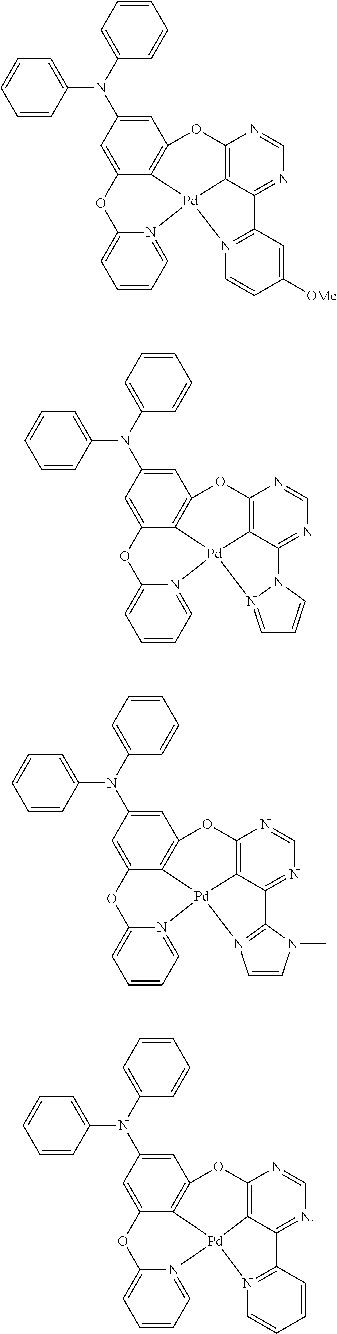

31. The compound of any one of paragraphs 1 to 30, having an emission lifetime (τ) between 1.0 μs and 10 μs, inclusive, or between 1.1 μs and 8.7 μs, inclusive, in solution, such as 1.1 μs or 8.7 μs.

32. The compound of any one of paragraphs 1 to 31, having an emission lifetime (τ), between 3.5 μs and 40 μs, inclusive, or between 4.4 μs and 35 μs, inclusive, such as 4.4 μs or 35 μs, in thin films having a thickness between 10 nm and 50 μm, such as between 10 nm and 200 nm.

33. The compound of any one of paragraphs 1 to 32, having a radiative rate constant between 1.0×10⁵ s⁻¹ and 10.0×10⁵ s⁻¹ inclusive, between 1.0×10⁵ s⁻¹ and 8.0×10⁵ s⁻¹, inclusive, or between 2.0×10⁵ s⁻¹ and 7.0×10⁵ s⁻¹, inclusive, in solution, such as 6.0×10⁵ s⁻¹.

34. The compound of any one of paragraphs 1 to 33, having a radiative rate constant between 1.0×10⁵ s⁻¹ and 7.5×10⁵ s⁻¹, inclusive, between 1.0×10⁵ s⁻¹ and 5.0×10⁵ s₋₁, inclusive, or between 1.5×10⁵ s⁻¹ and 4.0×10⁵ s⁻¹, inclusive, such as 2.2×10⁵ s⁻¹, in thin films, having a thickness between 10 nm and 50 μm, such as between 10 nm and 200 nm.

35. The compound of any one of paragraphs 1 to 34, having a photoluminescence quantum yield (PLQY) between 10% and 80%, inclusive, in solution (such as organic solution) at room temperature.

36. The compound of paragraph 35, wherein the PLQY in solution is for an emission maximum between 430 nm and 650 nm, inclusive, such as between 496 nm and 558 nm, inclusive.

37. The compound of any one of paragraphs 1 to 36, having a PLQY between 15% and 65%, inclusive, between 40% and 65%, inclusive, between 45% and 65%, inclusive, between 50% and 65%, inclusive, or between 55% and 60%, inclusive, at room temperature, in thin films having a thickness between 10 nm and 50 μm, such as between 10 nm and 200 nm.

38. The compound of paragraph 37, wherein PLQY in thin films is for an emission maximum between 430 nm and 650 nm, inclusive, such as between 476 nm and 560 nm, inclusive.

39. An organic electronic component containing the compound of any one of paragraphs 1 to 38.

40. The organic electronic component of paragraph 39, wherein the organic electronic component is an organic light-emitting diode (OLED) or a light-emitting electrochemical cell (LEEC).

41. The organic electronic component of paragraph 39 or 40, wherein the compounds are in a light-emitting layer.

42. A light-emitting layer containing the compound of any one of paragraphs 1 to 38.

43. An OLED, containing the light-emitting layer of paragraph 42.

44. A device, containing the OLED of paragraph 43, wherein the device is selected from stationary visual display units, mobile visual display units, or illumination units, keyboards, clothes, ornaments, garment accessories, wearable devices, medical monitoring devices, wall papers, tablet computers, laptops, advertisement panels, panel display units, household appliances, or office appliances.

45. The organic electronic component of paragraph 41, wherein the light-emitting layer is fabricated by spin-coating or ink printing (such as, ink-jet printing or roll-to-roll printing).

46. A device, containing a light-emitting layer containing the compound of any one of paragraphs 1 to 38, wherein the device has a maximum external quantum efficiency (EQE) between 10% and 40%, inclusive, between 10% and 35%, inclusive, between 15% and 40%, inclusive, or between 15% and 35%, inclusive, such as between 16.4% and 30.3%, inclusive.

47. A device, containing a light-emitting layer containing the compound of any one of paragraphs 1 to 38, wherein the device has a current efficiency (CE) between 30 cd/A and 80 cd/A, inclusive, between 30 cd/A and 75 cd/A, inclusive, between 35 cd/A and 80 cd/A, inclusive, between 35 cd/A and 75 cd/A, inclusive, between 40 cd/A and 80 cd/A, inclusive, or between 40 cd/A and 75 cd/A, inclusive, such as between 44.4 cd/A and 70.1 cd/A, inclusive.

48. A process for preparing the compound of any one of paragraphs 1 to 38, involving:
contacting a palladium compound with a corresponding tetradentate ligand, a corresponding tetradentate ligand precursor, or a combination thereof.

### EXAMPLES

### Example 1: Synthesis and Characterization of Compounds

### Materials and Methods

The materials used for synthesis were purchased from commercial sources such as Dieckmann, J & K Scientific, BLDpharm, Bidepharm, Strem Chemicals, Duksan, RCI Labscan, Scharlau. They were directly used without further processing.

### (1) Synthesis and Structural Characterization of Precursors of Tetradentate Ligands

Schematics for the synthesis of precursors of ligands are shown below:

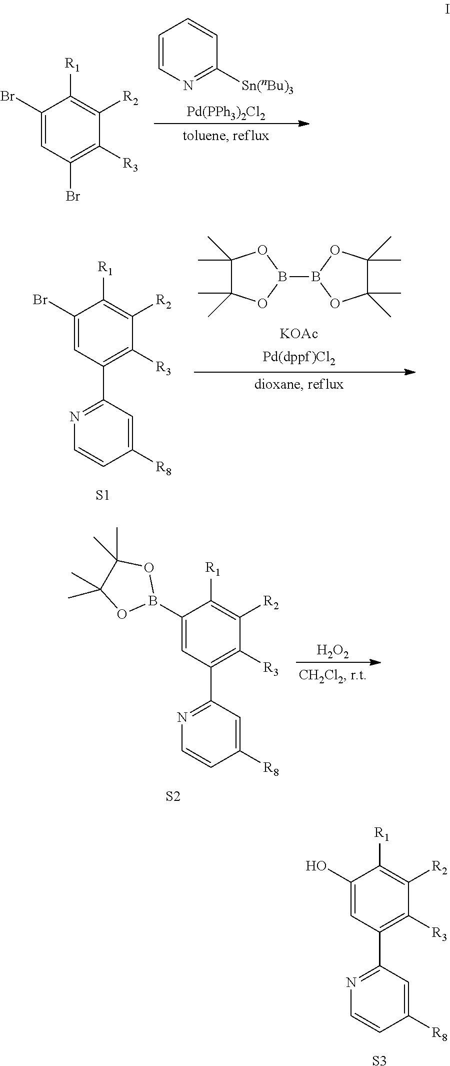

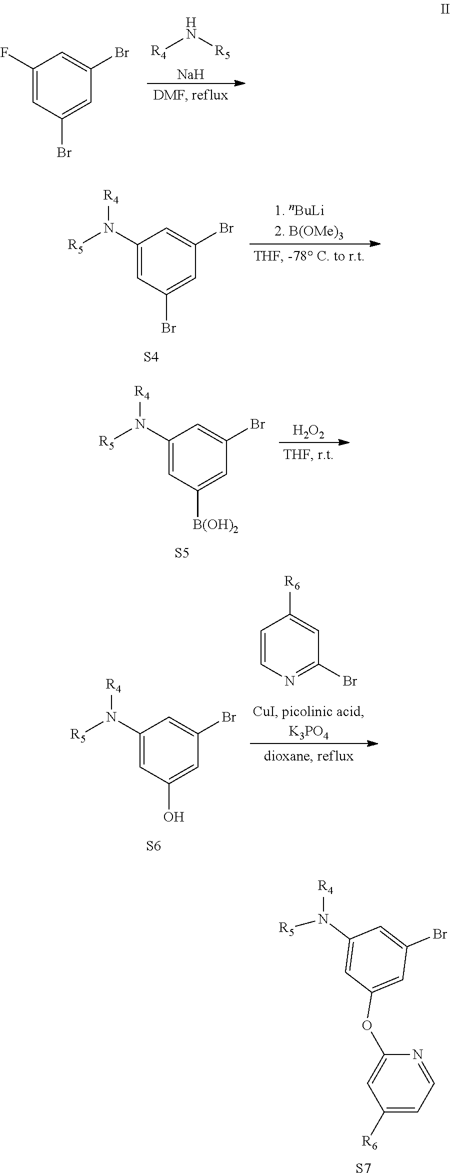

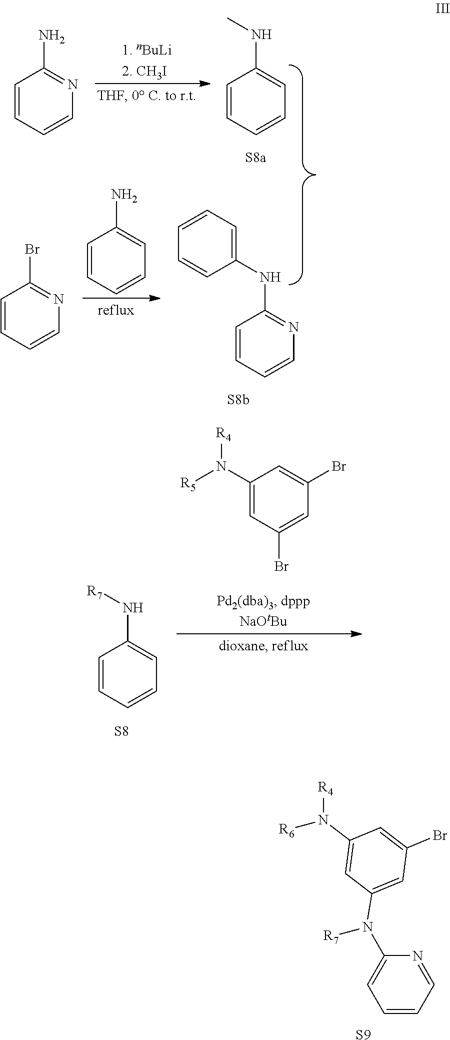

### (a) General Preparation of S1a and S1b

To a 100 mL two-necked round bottom flask containing 8 mL anhydrous toluene, substituted dibromobenzene (1.0 eq.), 2-(tributylstannyl)pyridine (1.0 eq.) and bis(triphenylphosphine) palladium chloride (5 mol %) were added under nitrogen atmosphere. The reaction mixture was refluxed overnight. After cooling down to room temperature, the crude product was filtered with Celite. The filtrate was concentrated under reduce pressure and the resulting residue was purified by flash chromatography on silica gel (10 weight % K₂CO₃ packed) using n-hexane/ethyl acetate=15:1 as eluent to provide product as white solid.

S1a (R₁=R₃=F): Yield: 64%. ¹H NMR (CDCl₃, 300 MHz) δ (ppm): 6.97-7.04 (t, 1H), 7.26-7.32 (m, 2H), 7.77-7.81 (m, 2H), 8.26-8.32 (t, 1H), 8.72-8.73 (d, 1H).

S1b (R₁=R₂=R₃=F): Yield: 52%. ¹H NMR (CD₂Cl₂, 400 MHz) δ (ppm): 6.92-6.97 (t, 1H), 7.29-7.32 (t, 1H), 7.60-7.64 (dd, 1H), 7.74-7.80 (m, 2H), 8.67-8.69 (d, 1H).

### (b) General Preparation of S2

Bis(pinacolato)diboron (1.0 eq.), potassium acetate (3.0 eq.) and [1,1′-bis(diphenylphosphino) ferrocene]palladium(II) dichloride (5 mol %) were added into a reaction mixture containing S1 (1.0 eq.) in anhydrous 1,4-dioxane (20 mL) under argon atmosphere. The reaction mixture was heated to 85° C. overnight. The crude mixture was filtered with funnel packed with Celite and silica gel two times. The filtrate was evaporated by reduced pressure to give the crude product for further reaction.

### (c) General Preparation of S3a and S3b

A mixture containing S2 (1.0 eq.), hydrogen peroxide (10 eq.) in dichloromethane was stirred for 24 hours. The crude product is washed with brine and extracted with dichloromethane for three times. The combined organic extracts were dried over MgSO₄ and evaporated to dryness to provide white solid.

S3a (R₁=R₃=F; R₈=H): Yield: 41%. ¹H NMR (CD₂Cl₂, 300 MHz) δ (ppm): 7.30-7.34 (dt, 1H), 7.75-7.83 (m, 2H), 8.08-8.14 (dt, 1H), 8.68-8.70 (d, 1H).

S3b (R₁=R₂=R₃=F; R₈=H): Yield: 25%. ¹H NMR (MeOD, 400 MHz) δ (ppm): 7.17-7.21 (t, 1H), 7.40-7.43 (dd, 1H), 7.74-7.77 (d, 1H), 7.89-7.94 (t, 1H), 8.64-8.66 (d, 1H).

### (d) General Preparation of S4

To a Schleck flask was added 1,3-dibromo-5-fluorobenzene (2.02 g, 1.00 mL, 7.96 mmol, 1.0 equiv), NaH (60% dispersion in mineral oil, 493 mg, 12.3 mmol, 1.55 equiv) and the corresponding amine (11.9 mmol, 1.5 eq.). 40 mL of anhydrous DMF was added to the flask. The resultant mixture was heated up to 80° C. until all bubbles were released out. The mixture was stirred at 120° C. for 24 hours. After cooling down, the DMF was removed under reduced pressure. The crude product was purified by flash silica gel column chromatography using n-hexane:ethyl acetate=95:1 as eluent to give S4 as a white solid.

S4 (R₄=R₅=Ph; 3,5-dibromo-N,N-diphenylaniline): Isolated yield: 44%; ¹H NMR (500 MHz, CDCl₃) δ=7.31 (t, J=7.9 Hz, 4H), 7.19 (t, J=1.6 Hz, 1H), 7.14-7.07 (m, 6H), 7.05 (d, J=1.6 Hz, 2H).

### (e) General Preparation of S5

n-BuLi (2.4 M in hexane, 2.41 mL, 5.8 mmol) was added dropwise to a solution of S4 (1.78 g, 5.3 mmol) in THF (58 mL) at −78° C. After the solution was stirred for 1 hour, B(Oi-Pr)₃ (1.46 mL, 6.3 mmol) was added. The mixture was stirred at room temperature for overnight. The resulting mixture was quenched with 1 M HCl, extracted with CH₂Cl₂ (3×20 mL) and washed with brine. The crude product was purified by column chromatography on silica gel using n-hexane:ethyl acetate=1:1 v/v as eluent to give (3-bromo-5-(diphenylamino)phenyl)boronic acid as an off-white solid.

S5 (R₄=R₅=Ph; (3-bromo-5-(diphenylamino)phenyl)boronic acid): Isolated yield: 85%.

### (f) General Preparation of S6

To a solution of S5 (5.7 mmol) in a mixture of THF/H₂O v/v=1:1 (30 mL), H₂O₂ (30%, 1.75 mL, 57.1 mmol, 10 equiv.) was added. After stirring for 24 hours at room temperature, the resulting mixture was concentrated under reduced pressure and was extracted with CH₂Cl₂ (3×20 mL). The crude product was purified by column chromatography on silica gel using n-hexane:ethyl acetate=3:1 v/v as eluent to give S6 as tan solid.

S6 (R₄=R₅=Ph; 3-bromo-5-(diphenylamino)phenol): Isolated yield: 98%.

### (g) General Preparation of S7

To a Schlenk flask was added CuI (109 mg, 0.57 mmol, 10 mol %), picolinic acid (140 mg, 1.14 mmol, 20 mol %), K₃PO₄ (1.82 g, 8.55 mmol, 1.5 eq.) and S6 (5.70 mmol, 1.0 eq.). The flask was evacuated and subsequently filled with argon for 3 times. 100 mL of degassed anhydrous dioxane mixed with 2-bromopyridine (1.09 mL, 11.4 mmol, 2.0 eq.) was added to the flask. The mixture was stirred at 110° C. for 24 hours. After cooling down, the resultant mixture was filtered with a pad of silica gel and Celite. The filtrate was concentrated under reduced pressure. The crude product was purified by flash silica gel column chromatography using n-hexane:ethyl acetate=10:1 as eluent to give S7 as a white solid.

S7 (R₄=R₅=Ph; 3-bromo-N,N-diphenyl-5-(pyridin-2-yloxy)aniline): Isolated yield: 84%; ¹H NMR (500 MHz, CDCl₃) δ=8.20 (dd, J=4.8, 1.6 Hz, 1H), 7.67-7.58 (m, 1H), 7.27 (t, J=7.8 Hz, 4H), 7.16 (d, J=7.7 Hz, 4H), 7.06 (t, J=7.3 Hz, 2H), 7.03-7.00 (m, 1H), 6.97 (dd, J=6.9, 5.2 Hz, 1H), 6.91 (t, J=1.7 Hz, 1H), 6.87 (d, J=8.3 Hz, 1H), 6.80 (t, J=1.9 Hz, 1H).

### (h) General Preparation of S8a and S8b

S8a: 2-aminopyridine (1 g, 11.7 mmol, 1 eq.) was loaded into a two-necked round bottom flask. The flask was pumped and refilled to argon atmosphere. Dry THF was added and n-butyl lithium (0.7 g, 10.9 mmol, 1 eq.) was added by a syringe. The mixture was stirred in ice bath for 30 minutes. Methyl iodide (1.6 g, 11.2 mmol, 1 equiv.) was added slowly by a syringe. The mixture was stirred in room temperature for 1 hour. After reaction, ammonium chloride in water was added to the mixture, which was further extracted with dichloromethane (3×50 mL). The organic phase was dried and concentrated. The product was purified by flash column chromatography using ethyl acetate as eluent. Yellow oil of 0.37 g, yield: 18%. ¹H NMR (CDCl₃, 300 MHz) δ (ppm): 4.07-4.15 (q, 1H), 6.36-6.39 (d, 1H), 6.54-6.58 (t, 1H), 7.40-7.44 (t, 1H), 8.07-8.09 (d, 1H).

S8b: Aniline (1.7 g, 21 mmol, 1 eq.) and 2-bromopyridine (3.0 g, 21 mmol, 1 eq.) were loaded into a conical flask. The mixture was heated to reflux overnight. Saturated NaHCO₃ solution was added to the cooled mixture and extracted with ethyl acetate. The organic phase was dried and evaporated to dryness. The product was purified by flash column chromatography using n-hexane:ethyl acetate=9:1 as eluent. Pink solid of 3.0 g, yield: 84%. ¹H NMR (CDCl₃, 400 MHz) δ (ppm): 6.71-6.74 (q, 1H), 6.81 (s, 1H), 7.02-7.08 (septuplet, 1H), 7.33-7.33 (d, 4H), 7.46-7.51 (t, 1H), 8.19-8.21 (d, 1H).

### (i) General Preparation of S9

To a Schlenk flask was added Pd₂(dba)₃ (95 mg, 0.10 mmol, 7.5 mol %), 1,3-bis(diphenylphosphino)propane (86 mg, 0.21 mmol, 15 mol %), t-BuONa (200 mg, 2.08 mmol, 1.5 equiv.) and 3-bromo-5-(diphenylamino)phenol (1.12 g, 2.77 mmol, 2.0 equiv.). The flask was evacuated and subsequently filled with argon for 3 times. 100 mL of degassed anhydrous dioxane mixed with the corresponding S8 (1.39 mmol, 1.0 eq.) was added to the flask. The mixture was stirred at 110° C. for 16 hours. After cooling down, the resultant mixture was filtered with a pad of silica gel and Celite. The filtrate was concentrated under reduced pressure. The crude product was purified by flash silica gel column chromatography using n-hexane:ethyl acetate=10:1 as eluent to give S9 as a yellow solid.

S9a (R₄=R₅=Ph, R₇=Me): Isolated yield: 69%; ¹H NMR (500 MHz, CDCl₃) δ=8.26-8.18 (m, 1H), 7.39-7.31 (m, 1H), 7.28 (t, J=7.9, 4H), 7.15 (d, J=7.7, 4H), 7.06 (t, J=7.3, 2H), 7.03-6.98 (m, 2H), 6.90 (t, J=1.9, 1H), 6.69 (d, J=8.5, 1H), 6.63 (dd, J=6.7, 5.3, 1H), 3.41 (s, 3H).

S9b (R₄=R₅=R₇=Ph): Isolated yield: 60%; ¹H NMR (500 MHz, CDCl₃) δ=8.22 (dd, J=4.6, 0.6, 1H), 7.46-7.39 (m, 1H), 7.32 (t, J=7.8, 2H), 7.23 (t, J=7.8, 4H), 7.16 (d, J=8.0, 3H), 7.09 (d, J=7.9, 4H), 7.02 (t, J=7.3, 2H), 6.86-6.82 (m, 2H), 6.82-6.80 (m, 1H), 6.79 (dd, J=6.7, 5.4, 1H), 6.74 (d, J=8.4, 1H).

### (2) Synthesis and Structural Characterization of Precursor Ligands

Synthetic schemes of the tetradentate ligands and Pd(II) complexes are shown below:

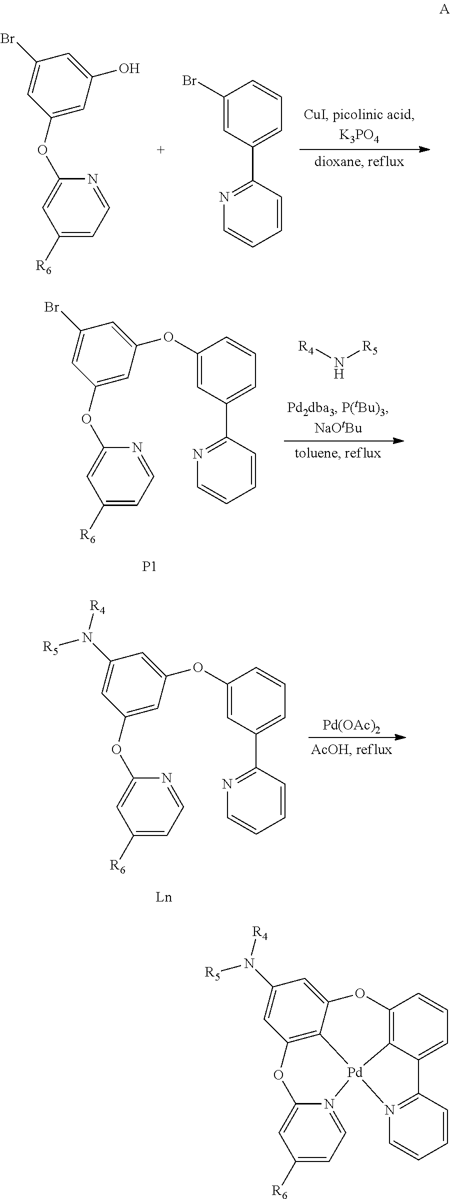

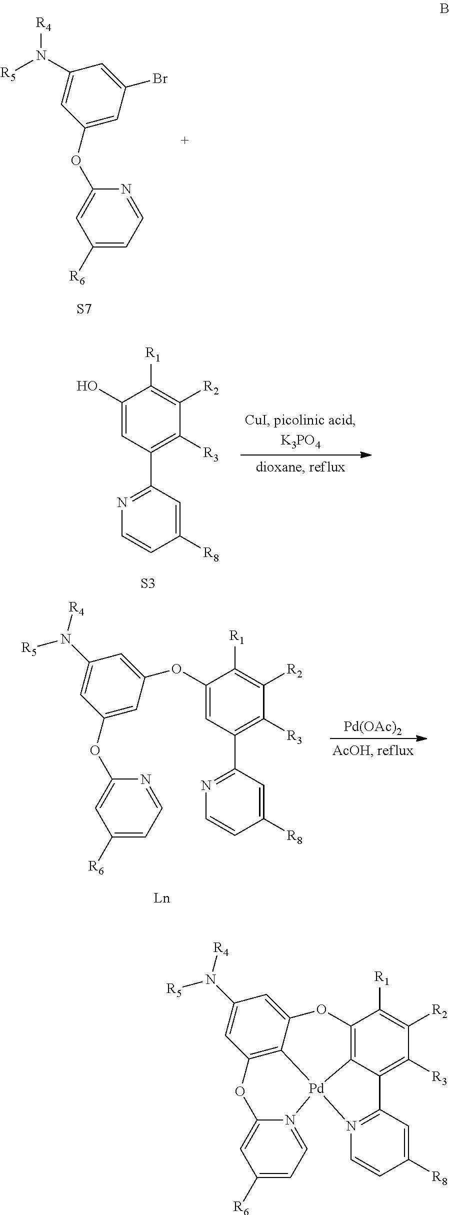

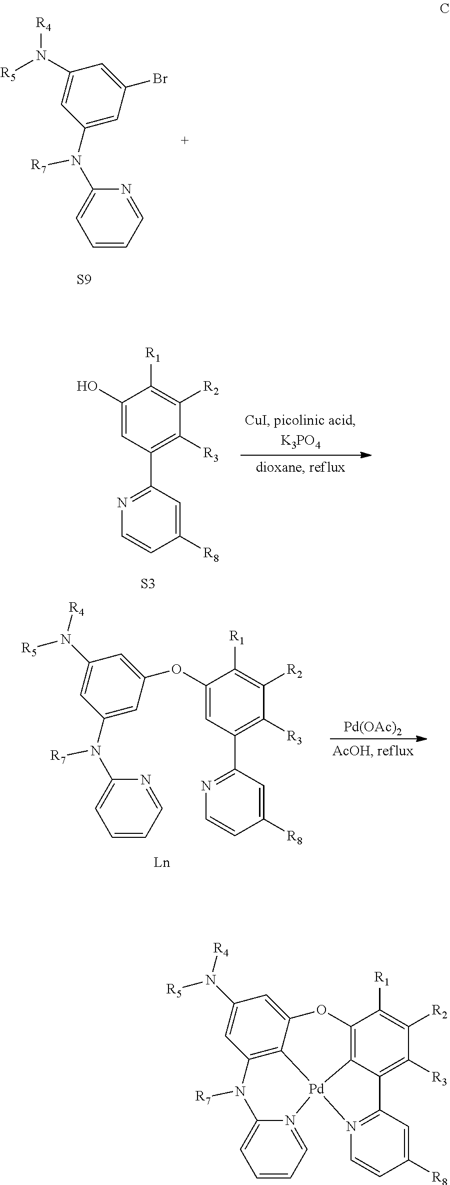

### (a) Preparation of Bromo-Substituted Tetradentate Ligand Precursor (P1)

To a Schlenk flask was added CuI (8.6 mg, 45 μmol, 10 mol %), picolinic acid (11 mg, 0.09 mmol, 20 mol %), K₃PO₄ (287 mg, 1.35 mmol, 3.0 equiv.) and 3-bromo-5-((4-(tert-butyl)pyridin-2-yl)oxy)phenol (145 mg, 0.45 mmol, 1 equiv.). The flask was evacuated and subsequently filled with argon for 3 times. 2.5 mL of degassed anhydrous dioxane mixed with (3-bromophenyl)pyridine (158 g, 0.68 mmol, 1.5 eq.) was added to the flask. The mixture was stirred at 110° C. for 24 hours. After cooling down, the resultant mixture was filtered with a pad of silica gel and Celite. The filtrate was concentrated under reduced pressure. The crude product was purified by flash silica gel column chromatography using n-hexane:ethyl acetate=10:1 as eluent to give P1 as a white solid. Isolated yield: 36%; ¹H NMR (400 MHz, CDCl₃) δ=8.68 (d, J=4.3 Hz, 1H), 8.08 (d, J=5.4 Hz, 1H), 7.80 (d, J=7.9 Hz, 1H), 7.78-7.71 (m, 2H), 7.69 (d, J=7.9 Hz, 1H), 7.46 (t, J=7.9 Hz, 1H), 7.26-7.21 (m, 1H), 7.14-7.09 (m, 1H), 7.05-7.00 (m, 2H), 6.97 (t, J=1.9 Hz, 1H), 6.91 (d, J=1.2 Hz, 1H), 6.77 (t, J=2.1 Hz, 1H), 1.30 (s, 9H).

### (b) General Preparation of Tetradentate Ligands (L01-L02)

To a Schlenk flask was added Pd₂dba₃ (17 mg, 18.3 μmol, 5 mol %), tri-tert-butylphosphine (10 wt/wt %) in hexane, 163 μL, 54.9 μmol, 15 mol %), t-BuONa (53 mg, 0.55 mmol, 1.5 eq.), the corresponding diphenylamine (68 mg, 0.40 mmol, 1.1 eq.) and the bromo-substituted tetradentate ligand precursor (174 mg, 0.36 mmol, 1.0 eq.). The flask was evacuated and subsequently filled with argon for 3 times. 3 mL of degassed toluene was added to the flask. The mixture was stirred at 110° C. for 24 hours. After cooling down, the resultant mixture was filtered with a pad of silica gel and Celite. The filtrate was concentrated under reduced pressure. The crude product was purified by flash silica gel column chromatography using n-hexane:ethyl acetate=10:1 as eluent to give the tetradentate ligand as a tan solid.

L01: Isolated yield: 58%; ¹H NMR (500 MHz, CDCl₃) δ=8.66 (d, J=4.3 Hz, 1H), 8.06 (d, J=5.4 Hz, 1H), 7.74 (s, 1H), 7.70 (d, J=7.2 Hz, 1H), 7.68-7.66 (m, 1H), 7.63 (d, J=7.8 Hz, 1H), 7.37 (t, J=7.9 Hz, 1H), 7.23-7.13 (m, 9H), 7.10 (dd, J=8.0, 1.7 Hz, 1H), 6.98 (t, J=6.8 Hz, 2H), 6.94 (dd, J=5.3, 1.0 Hz, 1H), 6.84 (s, 1H), 6.62 (dd, J=8.4, 1.8 Hz, 2H), 6.44 (s, 1H), 1.24 (s, 9H).

L02: Isolated yield: 77%; ¹H NMR (500 MHz, CDCl₃) δ=8.68 (d, J=4.6 Hz, 1H), 8.08 (d, J=5.4 Hz, 1H), 7.77-7.65 (m, 4H), 7.38 (t, J=7.9 Hz, 1H), 7.27-7.19 (m, 5H), 7.14-7.08 (m, 5H), 6.96 (dd, J=5.4, 1.4 Hz, 1H), 6.84 (d, J=0.8 Hz, 1H), 6.58 (dt, J=11.8, 1.9 Hz, 2H), 6.35 (t, J=2.0 Hz, 1H), 1.28 (s, 18H), 1.26 (s, 9H).

### (c) General Preparation of Tetradentate Ligands (L03-L09)

To a Schlenk flask was added CuI (16 mg, 87 μmol, 10 mol %), picolinic acid (21 mg, 0.17 mmol, 20 mol %), K₃PO₄ (276 mg, 1.3 mmol, 1.5 eq.), the corresponding phenol (S3) (195 mg, 0.87 mmol, 1.0 eq.) and the corresponding phenyl bromide (S7 or S9) (633 mg, 1.47 mmol, 1.7 eq.). The flask was evacuated and subsequently filled with argon for 3 times. 10 mL of degassed anhydrous DMSO was added to the flask. The mixture was stirred at 110° C. for 24 hours. After cooling down, the resultant mixture was diluted with CH₂Cl₂ and filtered with a pad of silica gel and Celite. The filtrate was concentrated under reduced pressure. The crude product was purified by flash silica gel column chromatography using n-hexane:ethyl acetate=5:1 as eluent to give the tetradentate ligand as a white solid.

L03: Isolated yield: 64%; ¹H NMR (500 MHz, CDCl₃) δ=8.31 (d, J=5.9 Hz, 1H), 8.16 (dd, J=4.8, 1.5 Hz, 1H), 7.67-7.62 (m, 2H), 7.62-7.57 (m, 1H), 7.36 (t, J=7.9 Hz, 1H), 7.22 (t, J=7.8 Hz, 4H), 7.15 (d, J=7.7 Hz, 4H), 7.05 (dd, J=8.0, 1.9 Hz, 1H), 7.00 (t, J=7.3 Hz, 2H), 6.93 (dd, J=6.8, 5.2 Hz, 1H), 6.84 (t, J=5.3 Hz, 2H), 6.59 (t, J=1.9 Hz, 1H), 6.55 (t, J=1.9 Hz, 1H), 6.47 (dd, J=5.9, 2.5 Hz, 1H), 6.39 (t, J=1.9 Hz, 1H), 3.03 (s, 6H).

L04: Isolated yield: 46%; ¹H NMR (500 MHz, CDCl₃) δ=8.71 (d, J=4.8 Hz, 1H), 8.17 (dd, J=4.9, 1.7 Hz, 1H), 7.90 (dd, J=8.9, 7.9 Hz, 1H), 7.79-7.69 (m, 2H), 7.66-7.55 (m, 1H), 7.28-7.23 (m, 1H), 7.23-7.19 (m, 4H), 7.17 (d, J=7.3 Hz, 4H), 7.04-6.97 (m, 3H), 6.97-6.91 (m, 1H), 6.84 (d, J=8.3 Hz, 1H), 6.58 (dt, J=10.3, 2.0 Hz, 2H), 6.39 (t, J=2.0 Hz, 1H). ¹⁹F NMR (471 MHz, CDCl₃) δ=−117.75 (dd, J=16.7, 7.0 Hz), −125.23 (td, J=9.6, 6.4 Hz).

L05: Isolated yield: 23%; ¹H NMR (500 MHz, CDCl₃) δ=8.72 (dd, J=4.8, 0.7 Hz, 1H), 8.16 (dd, J=4.9, 1.2 Hz, 1H), 7.82-7.71 (m, 2H), 7.68-7.59 (m, 2H), 7.33-7.27 (m, 1H), 7.20 (t, J=7.8 Hz, 4H), 7.15 (d, J=7.4 Hz, 4H), 7.01 (t, J=7.2 Hz, 2H), 6.98-6.93 (m, 1H), 6.85 (d, J=8.3 Hz, 1H), 6.56 (dt, J=8.4, 2.0 Hz, 2H), 6.38 (t, J=2.0 Hz, 1H). ¹⁹F NMR (471 MHz, CDCl₃) δ=−143.31 (dt, J=20.7, 5.2 Hz), −148.61 (ddd, J=19.4, 8.4, 5.4 Hz), −156.65-−156.81 (m).

L06: Isolated yield: 45%; ¹H NMR (500 MHz, CDCl₃) δ=8.69 (d, J=4.6 Hz, 1H), 8.23 (d, J=5.0 Hz, 1H), 7.94-7.85 (m, 1H), 7.79-7.69 (m, 2H), 7.26-7.22 (m, 1H), 7.22-7.12 (m, 8H), 7.00 (t, J=7.5 Hz, 2H), 6.97-6.93 (m, 1H), 6.92 (s, 2H), 6.78 (d, J=4.9 Hz, 1H), 6.66 (s, 1H), 6.61-6.55 (m, 2H), 6.40 (s, 1H), 2.31 (s, 3H), 1.96 (s, 6H). ¹⁹F NMR (471 MHz, CDCl₃) δ=−117.59 (dd, J=16.4, 7.1 Hz), −125.00-−125.15 (m).

L07: Isolated yield: 66%; ¹H NMR (500 MHz, CDCl₃) δ=8.71 (d, J=4.2, 1H), 8.19 (d, J=4.3 Hz, 1H), 7.95 (t, J=8.4 Hz, 1H), 7.78 (d, J=7.8 Hz, 1H), 7.72 (t, J=7.7 Hz, 1H), 7.30-7.19 (m, 6H), 7.19-7.14 (m, 4H), 7.04-6.96 (m, 3H), 6.74 (d, J=8.6 Hz, 1H), 6.71 (s, 1H), 6.61 (s, 1H), 6.60-6.56 (m, 1H), 6.54 (s, 1H), 3.42 (s, 3H). ¹⁹F NMR (471 MHz, CDCl₃) δ=−117.70 (dd, J=15.0, 7.5 Hz), −125.43 (dd, J=15.7, 9.4 Hz).

L08: Isolated yield: 30%; ¹H NMR (500 MHz, CDCl₃) δ=8.77-8.67 (m, 1H), 8.17 (dd, J=5.0, 1.2 Hz, 1H), 7.85-7.72 (m, 2H), 7.69-7.60 (m, 1H), 7.31 (ddd, J=6.7, 4.8, 1.6 Hz, 1H), 7.29-7.24 (m, 1H), 7.21 (dd, J=11.2, 4.6 Hz, 4H), 7.16-7.11 (m, 4H), 7.00 (t, J=7.3 Hz, 2H), 6.70 (d, J=8.6 Hz, 1H), 6.67 (t, J=1.9 Hz, 1H), 6.59 (dd, J=6.7, 5.4 Hz, 1H), 6.54 (t, J=2.1 Hz, 1H), 6.50 (t, J=2.0 Hz, 1H), 3.39 (s, 3H). ¹⁹F NMR (471 MHz, CDCl₃) δ=−143.34 (dt, J=20.8, 5.2 Hz), −148.81 (ddd, J=19.5, 8.5, 5.3 Hz), −156.46-−156.87 (m).

L09: Isolated yield: 15%; ¹H NMR (500 MHz, CDCl₃) δ=8.75 (d, J=4.4 Hz, 1H), 8.17 (d, J=4.4 Hz, 1H), 7.79 (t, J=7.6 Hz, 1H), 7.73 (d, J=7.8 Hz, 1H), 7.61 (t, J=7.3 Hz, 1H), 7.39 (t, J=7.7 Hz, 1H), 7.35-7.29 (m, 1H), 7.26 (t, J=7.6 Hz, 2H), 7.22-7.14 (m, 6H), 7.12 (d, J=7.9 Hz, 4H), 7.10-7.05 (m, 1H), 6.96 (t, J=7.1 Hz, 2H), 6.81 (d, J=8.4 Hz, 1H), 6.78-6.71 (m, 1H), 6.65 (s, 1H), 6.45 (d, J=11.3 Hz, 2H). ¹⁹F NMR (471 MHz, CDCl₃) δ=−143.96 (d, J=20.8 Hz), −149.26 (ddd, J=19.3, 8.1, 4.9 Hz), −156.93 (t, J=20.1 Hz).

### (3) Synthesis and Structural Characterization of Pd(II) Complexes (Pd01-Pd09)

A mixture of Pd(OAc)₂ (86 mg, 0.38 mmol, 1.2 eq.) and the corresponding tetradentate ligand (200 mg, 0.35 mmol, 1.0 eq.) in degassed glacial acetic acid (35 mL) was refluxed for 18 hours. After cooling down, the acetic acid was removed under reduced pressure. The crude products were purified by flash silica gel column chromatography using CH₂Cl₂ as eluent to give the Pd(II) complex as a yellow crystalline solid.

Pd01: Prepared from L01 (60 mg, 0.11 mmol) and Pd(OAc)₂ (49 mg, 0.12 mmol). Isolated yield: 85%; ¹H NMR (500 MHz, CD₂Cl₂) δ=8.38 (dd, J=5.4, 3.8 Hz, 2H), 7.96 (d, J=8.0 Hz, 1H), 7.93-7.85 (m, 1H), 7.53 (d, J=7.5 Hz, 1H), 7.32-7.23 (m, 7H), 7.21 (t, J=7.7 Hz, 1H), 7.13 (d, J=7.9 Hz, 4H), 7.05 (d, J=7.9 Hz, 1H), 7.01 (t, J=7.3 Hz, 2H), 6.81 (d, J=2.1 Hz, 1H), 6.71 (d, J=2.1 Hz, 1H), 1.36 (s, 9H).

Pd02: Prepared from L02 (65 mg, 0.10 mmol) and Pd(OAc)₂ (44 mg, 0.11 mmol). Isolated yield: 41%; ¹H NMR (500 MHz, CD₂Cl₂) δ=8.40 (t, J=4.9, 2H), 7.98 (d, J=8.1, 1H), 7.94-7.87 (m, 1H), 7.54 (d, J=7.5 Hz, 1H), 7.32-7.24 (m, 7H), 7.22 (t, J=7.7 Hz, 1H), 7.05 (d, J=8.5 Hz, 5H), 6.75 (d, J=2.1 Hz, 1H), 6.68 (d, J=2.1 Hz, 1H), 1.37 (s, 9H), 1.33 (s, 18H).

Pd03: Prepared from L03 (45 mg, 0.082 mmol) and Pd(OAc)₂ (22 mg, 0.098 mmol). Isolated yield: 56%; ¹H NMR (400 MHz, CD₂Cl₂) δ=8.52 (dd, J=5.6, 1.7, 1H), 7.94 (d, J=6.6, 1H), 7.89 (ddd, J=8.9, 7.3, 1.9 Hz, 1H), 7.49 (d, J=7.0 Hz, 1H), 7.29-7.20 (m, 6H), 7.17 (t, J=7.7 Hz, 1H), 7.12 (dd, J=8.6, 0.9 Hz, 5H), 7.03-6.96 (m, 3H), 6.78 (d, J=2.2 Hz, 1H), 6.69 (d, J=2.2 Hz, 1H), 6.47 (dd, J=6.6, 2.8 Hz, 1H), 3.13 (s, 6H).

Pd04: Prepared from L04 (100 mg, 0.18 mmol) and Pd(OAc)₂ (45 mg, 0.20 mmol). Isolated yield: 55%; ¹H NMR (400 MHz, CD₂Cl₂) δ=8.50 (dd, J=6.0, 1.8, 1H), 8.35 (d, J=4.6, 1H), 8.29 (d, J=8.3, 1H), 7.99-7.89 (m, 2H), 7.34-7.27 (m, 4H), 7.25 (dd, J=6.9, 1.5, 3H), 7.11 (dd, J=8.6, 1.0, 4H), 7.02 (t, J=7.3, 2H), 6.87 (d, J=2.2 Hz, 1H), 6.80 (dd, J=11.3, 10.6 Hz, 1H), 6.73 (d, J=2.2 Hz, 1H). ¹⁹F NMR (377 MHz, CD₂Cl₂) δ=−117.49 (dd, J=10.8, 5.2 Hz), −126.61 (dd, J=10.4, 6.0 Hz).

Pd05: Prepared from L05 (79 mg, 0.14 mmol) and Pd(OAc)₂ (35 mg, 0.15 mmol).

Isolated yield: 32%; ¹H NMR (500 MHz, CD₂Cl₂) δ=8.49 (dd, J=5.9, 1.7, 1H), 8.36 (d, J=4.9 Hz, 1H), 8.28 (d, J=8.2 Hz, 1H), 8.02-7.91 (m, 2H), 7.39-7.33 (m, 1H), 7.32-7.28 (m, 2H), 7.26 (t, J=7.9 Hz, 4H), 7.11 (d, J=7.7 Hz, 4H), 7.02 (t, J=7.4 Hz, 2H), 6.89 (d, J=2.1 Hz, 1H), 6.74 (d, J=2.1 Hz, 1H). ¹⁹F NMR (471 MHz, CD₂Cl₂) δ=−142.92 (d, J=19.9 Hz, 1F), −150.95 (dd, J=19.0, 3.9 Hz), −164.42-−164.56 (m).

Pd06: Isolated yield: 80%; Prepared from the corresponding ligand (101 mg, 0.15 mmol) and Pd(OAc)2 (38 mg, 0.17 mmol). ¹H NMR (500 MHz, CD₂Cl₂) δ=8.53 (d, J=5.7, 1H), 8.40 (d, J=4.7, 1H), 8.27 (d, J=8.4 Hz, 1H), 7.96-7.89 (m, 1H), 7.34-7.29 (m, 1H), 7.24 (t, J=7.9, 4H), 7.10 (d, J=7.6, 4H), 7.07 (d, J=1.2 Hz, 1H), 7.04 (dd, J=5.7, 1.6 Hz, 1H), 7.01 (t, J=7.4 Hz, 2H), 6.97 (s, 2H), 6.87 (d, J=2.2 Hz, 1H), 6.79 (t, J=10.9 Hz, 1H), 6.71 (d, J=2.2 Hz, 1H), 2.32 (s, 3H), 2.04 (s, 6H). ¹⁹F NMR (471 MHz, CD₂Cl₂) δ=−117.33 (dd, J=10.7, 4.8 Hz), −126.79 (dd, J=10.4, 5.8 Hz).

Pd07: Prepared from L07 (98 mg, 0.18 mmol) and Pd(OAc)₂ (43 mg, 0.19 mmol). Isolated yield: 43%; ¹H NMR (500 MHz, CD₂Cl₂) δ=8.53 (dd, J=5.6, 1.5 Hz, 1H), 8.27 (d, J=4.6 Hz, 1H), 8.24 (d, J=8.3 Hz, 1H), 7.93-7.86 (m, 1H), 7.83 (ddd, J=8.8, 7.2, 1.8 Hz, 1H), 7.24 (t, J=7.9 Hz, 5H), 7.15-7.07 (m, 5H), 7.03 (dd, J=9.4, 3.3 Hz, 1H), 6.98 (t, J=7.3 Hz, 2H), 6.80 (d, J=1.9 Hz, 1H), 6.79-6.73 (m, 1H), 6.64 (d, J=2.0 Hz, 1H), 3.38 (s, 3H). ¹⁹F NMR (471 MHz, CD₂Cl₂) δ=−118.04 (dd, J=11.3, 5.1 Hz), −127.32 (dd, J=10.4, 5.7 Hz).

Pd08: Prepared from L08 (200 mg, 0.35 mmol) and Pd(OAc)₂ (86 mg, 0.38 mmol). Isolated yield: 33%; ¹H NMR (500 MHz, CD₂Cl₂) δ=8.59-8.46 (m, 1H), 8.35-8.26 (m, 1H), 8.23 (d, J=7.0 Hz, 1H), 8.04-7.88 (m, 1H), 7.88-7.78 (m, 1H), 7.38-7.27 (m, 1H), 7.27-7.18 (m, 4H), 7.18-7.06 (m, 5H), 7.06-7.01 (m, 1H), 7.01-6.90 (m, 2H), 6.81 (s, 1H), 6.64 (s, 1H), 3.38 (s, 3H). ¹⁹F NMR (471 MHz, CD₂Cl₂) δ=−143.39 (d, J=20.2 Hz), −151.55 (d, J=19.3 Hz), −164.91-−165.05 (m).

Pd09: Prepared from L09 (123 mg, 0.19 mmol) and Pd(OAc)2 (52 mg, 0.23 mmol). Isolated yield: 42%; ¹H NMR (500 MHz, CD₂Cl₂) δ=8.61 (dd, J=5.6, 1.5 Hz, 1H), 8.26 (dd, J=5.4, 0.9 Hz, 1H), 8.23 (d, J=8.3 Hz, 1H), 7.95-7.89 (m, 1H), 7.74 (ddd, J=8.8, 7.2, 1.9 Hz, 1H), 7.31-7.25 (m, 3H), 7.21-7.14 (m, 5H), 7.14-7.09 (m, 2H), 7.07 (dd, J=8.5, 1.0 Hz, 2H), 7.01 (dd, J=8.5, 1.0 Hz, 4H), 6.96 (t, J=7.3 Hz, 2H), 6.84 (d, J=2.2 Hz, 1H), 6.51 (d, J=2.2 Hz, 1H). ¹⁹F NMR (471 MHz, CD₂Cl₂) δ=−143.25 (d, J=20.3 Hz), −151.40 (dd, J=19.2, 3.6 Hz), −164.82-−164.94 (m).

The structures of the synthesized compounds are shown below:

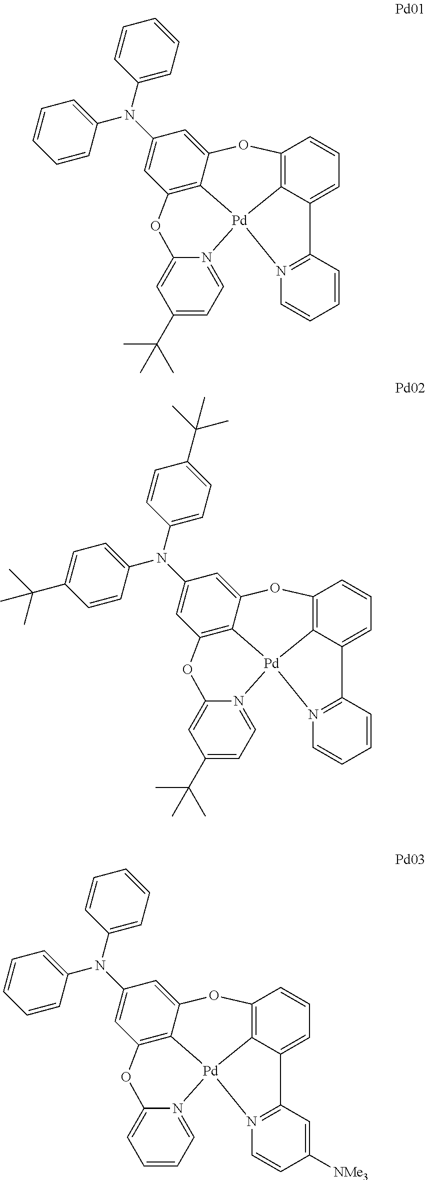

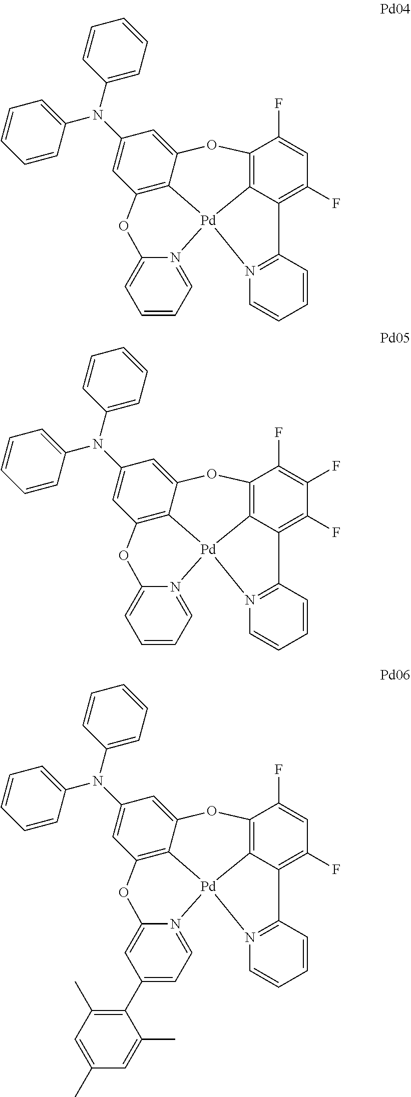

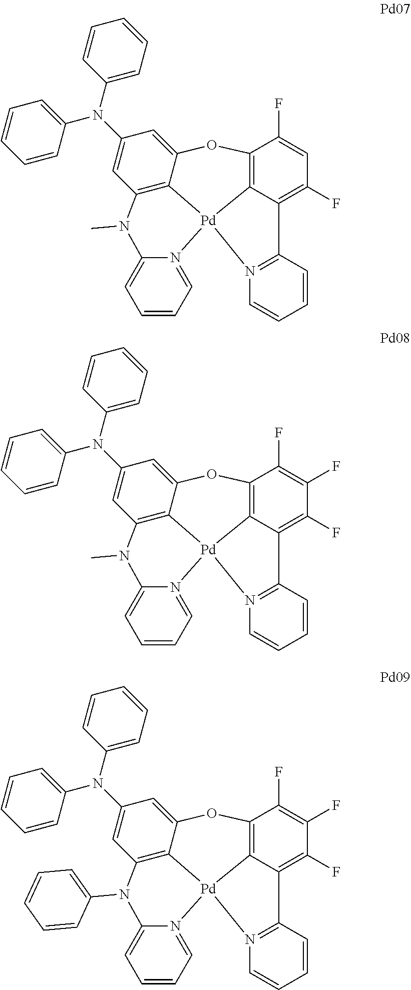

### (4) Photophysical Characterization of the Compounds

The absorption and emission data, and related photophysical data are shown in Table 1.

TABLE 1
Photophysical data for Pd(II)-complexes in degassed solutions and PPF films
at room temperature

| | | λ_{abs}/nm (ε × | | | kᵣ (×10⁴ s⁻¹)/ |
|---|---|---|---|---|---|
| Emitter | Medium^{[a]} | 10³ M⁻¹cm⁻¹) | λₘₐₓ/nm (τ/μs)^{[a],[b]} | QY | kₙᵣ(×10⁴ s⁻¹) |
| Pd01 | CH₂Cl₂ | 302 (33.0), | 523 (3.7) | 70 | 19/8 |
| | | 336 (17.0), | | | |
| | | 364 (10.3) | | | |
| | Toluene | 302 (34.2), | 470, 498, 537 (31.1) | 65 | 2.1/1.1 |
| | | 342 (15.1), | | | |
| | | 374 (9.8) | | | |
| | 5% in | | 466 (τ₁ = 7.0 (8%), τ₂ = 56 | 51 | 1.5/1.4 |
| | PPF | | (92%)); 497 | | |
| | | | (τ₁ = 6.7(10%), τ₂ = 67 | | |
| | | | (90%)), 534 (τ₁ = 5.9 | | |
| | | | (10%), τ₂ = 73 (90%)) {35} | | |
| Pd02 | CH₂Cl₂ | 260 (38.6), | 558 (1.1) | 66 | 60/31 |
| | | 302 (34.9), | | | |
| | | 337 (15.7), | | | |
| | | 370 (9.5), 414 | | | |
| | | (2.1) | | | |
| | Toluene | 304 (35.0), | 494 (11.2) | 74 | 6.6/2.3 |
| | | 342 (13.8), | | | |
| | | 375 (9.0), 420 | | | |
| | | (2.2) | | | |
| | 5% in | | 466 (τ₁ = 4.6 (19%); τ₂ = 39 | 44 | 4.4/5.6 |
| | PPF | | (81%)), | | |
| | | | 496 (τ₁ = 3.1 (23%); τ₂ = 30 | | |
| | | | (77%)), | | |
| | | | 536 (τ₁ = 3.3 (24%); τ₂ = 32 | | |
| | | | (76%)) {10} | | |
| Pd03 | CH₂Cl₂ | 271 (50.4), | 445, 484, 563 (8.7) | 18 | 2.1/9.6 |
| | | 300 (44.3), | | | |
| | | 344 (19.7), | | | |
| | | 384 (3.2) | | | |
| | Toluene | 302 (41.9), | 450, 478, 513 (42) | 27 | 0.6/1.6 |
| | | 350 (16.0), | | | |
| | | 390 (2.7) | | | |
| | 5% in | | 447 (τ₁ = 11 (17%); τ₂ = 57 | 30 | 0.9/2.1 |
| | PPF | | (83%)), | | |
| | | | 476 (τ₁ = 10 (13%); τ₂ = 54 | | |
| | | | (87%)), | | |
| | | | 512 (τ₁ = 6.3 (11%); τ₂ = 50 | | |
| | | | (89%)) {34} | | |
| Pd04 | CH₂Cl₂ | 257 (35.8), | 540 (1.6) | 77 | 48/14 |
| | | 299 (29.0), | | | |
| | | 338 (14.3), | | | |
| | | 360 (9.0), 393 | | | |
| | | (4.0) | | | |
| | Toluene | 304 (27.7), | 484 (11.6) | 71 | 6.1/2.5 |
| | | 338 (12.5), | | | |
| | | 367 (7.3), 406 | | | |
| | | (2.7) | | | |
| | 5% in | | 457 (τ = 3.7 (21%); τ₂ = 37 | 45 | 5.2/6.4 |
| | PPF | | (79%)), | | |
| | | | 484 (τ₁ = 3.1 (28%); τ₂ = 28 | | |
| | | | (72%)). | | |
| | | | 520 (τ₁ = 2.1 (35%); τ₂ = 18 | | |
| | | | (65%)) {8.6} | | |
| Pd05 | Toluene | 303 (27.1), | 493 (5.2) | 77 | 15/4.4 |
| | | 334 (12.0), | | | |
| | | 367 (7.0), 412 | | | |
| | | (2.2) | | | |
| | CH₂Cl₂ | 255 (33.6), | 552 (1.02) | 73 | 72/26 |
| | | 299 | | | |
| | | (29.0), 330 | | | |
| | | (14.5), 363 | | | |
| | | (8.0), 403 | | | |
| | | (2.3) | | | |
| | 5% in | | 460 (τ₁ = 3.0 (28%); τ₂ = 19 | 50 | 11/11 |
| | PPF | | (72%)) | | |
| | | | 489 (τ₁ = 2.2 (39%); τ₂ = 16 | | |
| | | | (61%)) {4.6} | | |
| Pd06 | CH₂Cl₂ | 297 (31.4), | 525 (1.6) | 75 | 47/16 |
| | | 336 (15.2), | | | |
| | | 362 (8.6), 401 | | | |
| | | (2.8) | | | |
| | Toluene | 300 (32.7), | 478 (10) | 66 | 6.6/3.4 |
| | | 341 (13.6), | | | |
| | | 369 (8.4), 405 | | | |
| | | (3.5) | | | |
| | 5% in | | 455 ((τ₁ = 4.2 (23%); τ₂ = 34 | 37 | 3.8/6.5 |
| | PPF | | (77%)) | | |
| | | | 483 ((τ1 = 3.4 (27%); τ₂ = 33 | | |
| | | | (73%)) {9.7} | | |
| Pd07 | CH₂Cl₂ | 303 (33.5), | 553 (1.5) | 71 | 47/19 |
| | | 335 (16.4), | | | |
| | | 368 (8.6), 400 | | | |
| | | (3.6) | | | |
| | Toluene | 306 (31.0), | 496 (4.4) | 71 | 16/6.6 |
| | | 330 (17.5), | | | |
| | | 376 (7.7), 409 | | | |
| | | (3.2) | | | |
| | 5% in | | 457 (τ₁ = 3.0 (40%); τ₂ = 15.0 | 60 | 14/9 |
| | PPF | | (60%)) | | |
| | | | 488 (τ₁ = 2.7 (52%); τ₂ = 13 | | |
| | | | (48%)) {4.4} | | |
| | 5% in | | 488 (2.3) | 51 | 22 |
| | DPEPO | | | | |
| Pd08 | CH₂Cl₂ | 305 (31.5), | 566 (0.94) | 58 | 62/45 |
| | | 330 (16.5), | | | |
| | | 366 (8.4), 409 | | | |
| | | (2.6) | | | |
| | Toluene | 305 (30.6), | 509 (3.17) | 84 | 26/5.0 |
| | | 333 (15.1), | | | |
| | | 375 (7.6), 418 | | | |
| | | (2.4) | | | |
| | 5% in | | 460 (τ₁ = 1.9 (41%); τ₂ = 8.5 | 60 | 24/16 |
| | PPF | | (59%)) | | |
| | | | 493 (τ₁ = 1.7 (57%); τ₂ = 6.8 | | |
| | | | (43%)){2.5} | | |
| Pd09 | CH₂Cl₂ | 287 (39.0), | 564 (0.93) | 62 | 67/41 |
| | | 308 (31.8), | | | |
| | | 369 (9.0), 410 | | | |
| | | (2.8) | | | |
| | Toluene | 302 (39.0), | 506 (1.86) | 43 | 23/31 |
| | | 313 (30.6), | | | |
| | | 377 (8.0), 417 | | | |
| | | (2.7) | | | |
| | 5% in | | 463 (τ₁ = 2.1 (46%); τ₂ = 10 | 46 | 17/20 |
| | PPF | | (54%)) | | |
| | | | 492 (τ₁ = 1.8 (58%); τ₂ = 8.2 | | |
| | | | (42%)){2.7} | | |

${}^{[ a ]} Area \% of decay time {τ}_{1} = ( \frac{{A}_{1} {τ}_{1}}{\text{?} \text{?} + \text{?} \text{?}} ) \times 100 \% and {τ}_{2} ( \frac{{A}_{2} {τ}_{2}}{\text{?} \text{?} + \text{?} \text{?}} ) \times 100 \% .$ ^{[b]} Weighted average

The OLED data for Pd02, Pd04, Pd05, Pd05: v-DABNA, Pd07, and Pd08 are shown below.

TABLE 2
OLED data for Pd02

| | | CE [cd A⁻¹] | | PE [lm W⁻¹] | | EQE [%] | | | | |
|---|---|---|---|---|---|---|---|---|---|---|
| | | | at | | at | | at | | | |
| | L [cd | | 1000 | | 1000 | | 1000 | CIE | FWHM | λmax |
| Pd02 | m⁻²] | Max | cd m⁻² | Max | cd m⁻² | Max | cd m⁻² | [(x, y)] | [nm] | [nm] |
| 4 wt/wt % | 4300 | 30.8 | 10.1 | 37.2 | 3.81 | 13.1 | 4.21 | 0.20, 0.45 | 75 | 499 |
| 10 wt/wt % | 8400 | 26.6 | 11.9 | 28.8 | 4.95 | 11.1 | 4.96 | 0.22, 0.48 | 77 | 503 |

Structure: ITO/HAT-CN (5 nm)/TAPC (40 nm)/TCTA (10 nm)/Pd02:DBF (10 nm)/TmPyPb (50 nm)/LiF (1.2 nm)/Al (100 nm)

TABLE 3
OLED data for Pd04

| | | CE [cd A⁻¹] | | PE [lm W⁻¹] | | EQE [%] | | | | |
|---|---|---|---|---|---|---|---|---|---|---|
| | | | at | | at | | at | | | |
| | L [cd | | 1000 | | 1000 | | 1000 | CIE | FWHM | λmax |
| Pd04 | m⁻²] | Max | cd m⁻² | Max | cd m⁻² | Max | cd m⁻² | [(x, y)] | [nm] | [nm] |
| 3 wt/wt % (A) | 2900 | 21.9 | 7.09 | 24.4 | 2.58 | 11.9 | 3.78 | 0.18, 0.32 | 69 | 486 |
| 6 wt/wt % (A) | 5600 | 35.3 | 16.9 | 39.7 | 7.36 | 18.2 | 8.67 | 0.18, 0.35 | 69 | 486 |
| 12 wt/wt % (A) | 9600 | 46.8 | 36.9 | 45.6 | 19.2 | 21.3 | 16.7 | 0.19, 0.39 | 70 | 490 |
| 16 wt/wt % (B) | 10600 | 69.2 | 26.9 | 39.6 | 12.8 | 30.3 | 11.6 | 0.19, 0.43 | 71 | 494 |
| 32 wt/wt % (B) | 11400 | 70.1 | 32.6 | 36.7 | 14.8 | 28.2 | 12.9 | 0.21, 0.48 | 74 | 501 |
| 4 wt/wt % (C) | 6400 | 39.3 | 24.3 | 41.1 | 18.2 | 21.1 | 13.0 | 0.16, 0.33 | 70 | 488 |
| 8 wt/wt % (C) | 11900 | 46.5 | 35.0 | 51.2 | 27.4 | 23.2 | 17.5 | 0.17, 0.36 | 68 | 490 |
| 16 wt/wt % (C) | 17100 | 48.5 | 42.1 | 50.4 | 33.1 | 22.6 | 19.6 | 0.18, 0.39 | 71 | 497 |

(A) ITO/HAT-CN (5 nm)/TAPC (40 nm)/TCTA (10 nm)/Pd04:PPF (10 nm)/TmPyPb (50 nm)/LiF (1.2 nm)/Al (100 nm);
(B) ITO/HAT-CN (5 nm)/TAPC (40 nm)/TCTA (10 nm)/Pd04:PPF (10 nm)/DBF(10 nm)/TmPyPb (40 nm)/LiF (1.2 nm)/Al (100 nm);
(C) (C) ITO/HAT-CN (5 nm)/TAPC (40 nm)/CCP (10 nm)/Pd04:PPF (10 nm)/PPF(10 nm)/TmPyPb (40 nm)/LiF (1 nm)/Al (100 nm)

TABLE 4
OLED data for Pd05

| | | CE [cd A⁻¹] | | PE [lm W⁻¹] | | EQE [%] | | | | |
|---|---|---|---|---|---|---|---|---|---|---|
| | | | at | | at | | at | | | |
| | L [cd | | 1000 | | 1000 | | 1000 | CIE | FWHM | λmax |
| Pd05 | m⁻²] | Max | cd m⁻² | Max | cd m⁻² | Max | cd m⁻² | [(x, y)] | [nm] | [nm] |
| 10 wt/wt % (A) | — | — | — | — | — | — | — | 0.20, 0.41 | 73 | 491 |
| 20 wt/wt % (A) | 14000 | 51.8 | 47.9 | 49.4 | 28.9 | 20.1 | 18.6 | 0.21, 0.46 | 74 | 495 |
| 4 wt/wt % (B) | 11000 | 51.6 | 34.9 | 56.8 | 22.2 | 24.9 | 16.7 | 0.17, 0.34 | 68 | 485 |
| 8 wt/wt % (B) | 21400 | 57.0 | 47.0 | 61.9 | 32.5 | 24.8 | 20.3 | 0.18, 0.39 | 69 | 490 |
| 16 wt/wt % (B) | 33000 | 56.3 | 50.0 | 62.5 | 34.8 | 24.1 | 21.4 | 0.19, 0.40 | 69 | 490 |

Structure:
(A) ITO/HAT-CN (5 nm)/TAPC (40 nm)/CCP (10 nm)/Pd05:PPF (10 nm)/PPF(10 nm)/TmPyPb (40 nm)/Liq (2 nm)/Al (100 nm);
(B) (B) ITO/HAT-CN (5 nm)/TAPC (40 nm)/CCP (10 nm)/Pd05:PPF (10 nm)/PPF(10 nm)/TmPyPb (40 nm)/Liq (2 nm)/Al (100 nm)

TABLE 5
OLED data for Pd07

| | | CE [cd A⁻¹] | | PE [lm W⁻¹] | | EQE [%] | | | | |
|---|---|---|---|---|---|---|---|---|---|---|
| | | | at | | at | | at | | | |
| | L [cd | | 1000 | | 1000 | | 1000 | CIE | FWHM | λmax |
| Pd07 | m⁻²] | Max | cd m⁻² | Max | cd m⁻² | Max | cd m⁻² | [(x, y)] | [nm] | [nm] |
| 4 wt/wt % (A) | 13800 | 26.0 | 17.5 | 22.8 | 4.75 | 10.7 | 7.21 | 0.22, 0.46 | 78 | 498 |
| 10 wt/wt % (A) | 17900 | 36.4 | 25.1 | 25.4 | 7.23 | 14.0 | 9.66 | 0.25, 0.50 | 80 | 505 |
| 14 wt/wt % (A) | 28300 | 44.4 | 36.5 | 27.9 | 10.9 | 16.4 | 13.5 | 0.25, 0.52 | 79 | 506 |
| 4 wt/wt % (B) | 2000 | 24.5 | 6.2 | 25.7 | 3.5 | 12.8 | 3.2 | 0.24, 0.36 | 80 | 487 |
| 8 wt/wt % (B) | 9030 | 29.6 | 19.4 | 31.0 | 13.2 | 11.5 | 7.5 | 0.22, 0.41 | 82 | 491 |
| 16 wt/wt % (B) | 25000 | 31.8 | 31.1 | 27.1 | 21.9 | 12.9 | 12.6 | 0.23, 0.46 | 78 | 496 |

Structure:
(A) ITO/HAT-CN (5 nm)/TAPC (40 nm)/TCTA (10 nm)/Pd07:PPF (10 nm)/DBF(10 nm)/TmPyPb (50 nm)/Liq (2 nm)/Al (100 nm);
(B) ITO/HAT-CN (5 nm)/TAPC (40 nm)/CCP(10 nm)/Pd07:PPF (10 nm)/PPF(10 nm)/TmPyPb (40 nm)/LiF (1.2 nm)/Al (100 nm)

TABLE 6
OLED data for Pd08

| | | CE [cd A⁻¹] | | PE [lm W⁻¹] | | EQE [%] | | | | |
|---|---|---|---|---|---|---|---|---|---|---|
| | | | at | | at | | at | | | |
| | L [cd | | 1000 | | 1000 | | 1000 | CIE | FWHM | λmax |
| Pd08 | m⁻²] | Max | cd m⁻² | Max | cd m⁻² | Max | cd m⁻² | [(x, y)] | [nm] | [nm] |
| 4 wt/wt % | 7200 | 37.0 | 25.5 | 41.0 | 20.9 | 15.7 | 10.8 | 0.21, 0.36 | 80 | 486 |
| 8 wt/wt % | 21400 | 40.2 | 35.3 | 39.5 | 28.6 | 15.4 | 13.5 | 0.23, 0.43 | 84 | 492 |
| 16 wt/wt % | 36000 | 39.9 | 39.2 | 34.2 | 30.8 | 14.9 | 14.7 | 0.26, 0.48 | 88 | 502 |

Structure: ITO/HAT-CN (5 nm)/TAPC (40 nm)/CCP (10 nm)/Pd08:PPF (10 nm)/PPF(10 nm)/TmPyPb (40 nm)/Liq (2 nm)/Al (100 nm)

TABLE 7
Hyper-fluorescence OLED data for Pd05:ν-DABNA

| | | CE [cd A⁻¹] | | PE [lm W⁻¹] | | EQE [%] | | | | |
|---|---|---|---|---|---|---|---|---|---|---|
| | | | at | | at | | at | | | |
| Pd05:ν- | L [cd | | 1000 | | 1000 | | 1000 | CIE | FWHM | λmax |
| DABNA | m⁻²] | Max | cd m⁻² | Max | cd m⁻² | Max | cd m⁻² | [(x, y)] | [nm] | [nm] |
| 10 wt/wt %:1 | 17300 | 51.7 | 45.2 | 46.4 | 32.4 | 23.1 | 21.8 | 0.14, 0.24 | 24 | 476 |
| wt/wt % | | | | | | | | | | |
| 20 wt/wt %:1 | 17700 | 33.8 | 32.9 | 33.8 | 21.4 | 18.8 | 18.4 | 0.15, 0.28 | 26 | 476 |
| wt/wt % | | | | | | | | | | |

Structure: ITO/HAT-CN (5 nm)/TAPC (40 nm)/CCP(10 nm)/Pd05:ν-DABNA:PPF (20 nm)/PPF(10 nm)/TmPyPb (40 nm)/LiF (1.2 nm)/Al (100 nm)

In summary, the tetradentate Pd(IJ)-TADF complexes (Pd01-Pd09) described herein emit strong yellow to sky blue photoluminescence with PLQY up to about 8400 in solutions and thin films at room temperature. The emission energy could be readily adjusted by modulating the donor strength of the amino group and the acceptor strength of aryl pyridine moiety. The TADF emission mechanism brings the emission lifetime (τ) of these emitters down to 0.9 μs, in some instances, leading to unprecedentedly large radiative rate constants of up to 7.2×10⁵ s⁻¹ which is hardly achievable by typical Pt(IJ) emitters. Depending on the device structure, maximum EQE and CE of between 13.1% and 30.3%, inclusive, and between 44.4 cd/A and 70.1 cd/A, inclusive, respectively, were achieved with the sky blue vacuum deposited OLEDs fabricated with Pd02, Pd04, Pd05 and Pd07.

Unless defined otherwise, all technical and scientific terms used herein have the same meanings as commonly understood by one of skill in the art to which the disclosed invention belongs. Publications cited herein and the materials for which they are cited are specifically incorporated by reference.

Those skilled in the art will recognize, or be able to ascertain using no more than routine experimentation, many equivalents to the specific embodiments of the invention described herein. Such equivalents are intended to be encompassed by the following claims.

1. A compound having a structure: 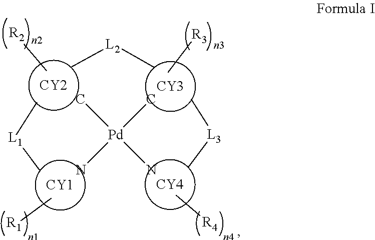
wherein:
the compound has an overall neutral, negative, or positive charge,
CY1 and CY4 are independently unsubstituted heteroaryl, substituted heteroaryl, unsubstituted polyheteroaryl, substituted polyheteroaryl, unsubstituted C₂-C₂₀ heterocyclyl, or substituted C₂-C₂₀ heterocyclyl,
CY2 and CY3 are independently unsubstituted aryl, substituted aryl, unsubstituted polyaryl, substituted polyaryl, unsubstituted heteroaryl, substituted heteroaryl, unsubstituted polyheteroaryl, substituted polyheteroaryl, unsubstituted C₃-C₂₀ cycloalkyl, substituted C₂-C₂₀ cycloalkyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl,
each R₁, R₂, R₃, and R₄ is independently, absent, hydrogen, substituted amino, unsubstituted amino, substituted alkyl, unsubstituted alkyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl, wherein at least one of R₁, R₂, R₃, and R₄ is present and is an electron donating group,
n1, n2, n3, and n4 are independently an integer between zero and 10, inclusive, with the proviso that at least one of n1, n2, n3, and n4 is not zero, and
L₁, L₂, and L₃ are independently a bond (single, double, or triple), absent, oxygen, sulfur, substituted amino, unsubstituted amino, unsubstituted alkylene, substituted alkylene, unsubstituted alkyl, substituted alkyl, substituted carbonyl, unsubstituted carbonyl, substituted amido, unsubstituted amido, substituted sulfonyl, unsubstituted sulfonyl, substituted sulfonic acid, unsubstituted sulfonic acid, substituted phosphoryl, unsubstituted phosphoryl, substituted phosphonyl, or unsubstituted phosphonyl.

2. (canceled)

3. The compound of claim 1, wherein each R₁, R₂, R₃, and R₄ is independently absent, hydrogen, substituted amino, unsubstituted amino, substituted alkyl, unsubstituted alkyl, substituted aryl, halogen, hydroxyl, thiol, unsubstituted alkoxy, substituted alkoxy, unsubstituted aroxy, substituted aroxy, unsubstituted alkylthio, or substituted alkylthio.

4. (canceled)

5. The compound of claim 1, wherein CY1 and CY4 are independently unsubstituted heteroaryl or substituted heteroaryl, or wherein CY2 and CY3 are independently unsubstituted aryl, substituted aryl, unsubstituted heteroaryl, or substituted heteroaryl, or a combination thereof.

6. (canceled)

7. The compound of claim 1, wherein L₁, L₂, and L₃ are independently a single bond, oxygen, substituted alkyl, or substituted amino.

8. The compound of claim 1, wherein at least one R₂ has a structure —NRₐR_{b}, wherein Rₐ and R_{b} are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl, or —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl.

9.-10. (canceled)

11. The compound of claim 1, having a structure: 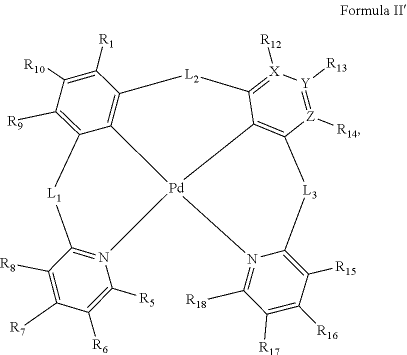
wherein for Formula II′:
either X and Z are nitrogen, and Y is carbon, or X and Z are carbon and Y is nitrogen,
R₅-R₈ are independently selected from R₁,
R₉-R₁₁ are independently selected from R₂,
R₁₂-R₁₄ are independently selected from R₃, and
R₁₅-R₁₈ are independently selected from R₄.

12. The compound of claim 11, wherein for Formula II′, L₁ is oxygen or NR_{c}, wherein R_{c} is hydrogen, unsubstituted alkyl, substituted alkyl, unsubstituted aryl, substituted aryl, unsubstituted heteroaryl, or substituted heteroaryl, or L₂ is oxygen or substituted alkyl, or L₃ is a single bond, or a combination thereof.

13.-16. (canceled)

17. The compound of claim 11, wherein for Formula II′ R₁₀ has a structure —NRₐR_{b}, wherein Rₐ and R_{b} are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl, or —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl.

18.-19. (canceled)

20. The compound of claim 11, wherein for Formula II′ R₁₀ has a structure:

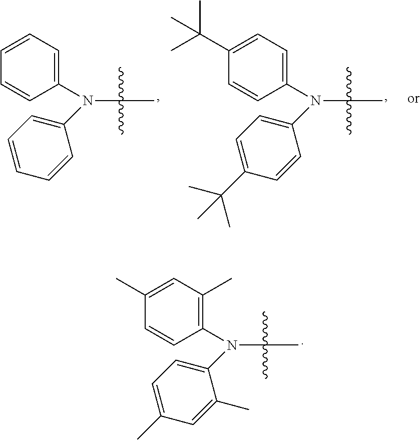 [SMILES: *N(c1ccccc1)c1ccccc1 ; *N(c1ccc(C(C)(C)C)cc1)c1ccc(C(C)(C)C)cc1 ; *N(c1ccc(C)cc1C)c1ccc(C)cc1C]

21. The compound of claim 11, wherein for Formula II′ R₇ is hydrogen, unsubstituted alkyl, substituted alkyl, unsubstituted aryl, or substituted aryl.

22.-23. (canceled)

24. The compound of claim 11, wherein for Formula II′ R₇ has a structure:

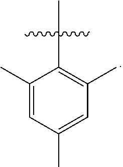

25. The compound of claim 11, wherein for Formula II′ R₁₂-R₁₄ are independently hydrogen or halogen.

26. (canceled)

27. The compound of claim 11, wherein for Formula II′ R₁₆ is hydrogen, substituted alkyl, unsubstituted alkyl, substituted aryl, unsubstituted aryl, substituted alkoxy, unsubstituted alkoxy, or NRₐRₑ, wherein R_{d} and Rₑ are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl, or —NRₐRₑ together form a substituted polyheteroaryl, unsubstituted polyheteroaryl, substituted polyheterocyclyl, unsubstituted polyheterocyclyl, substituted heterocyclyl, or unsubstituted heterocyclyl.

28. (canceled)

29. The compound of claim 1, having a structure: 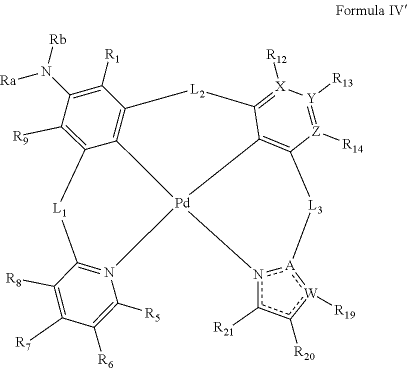
wherein for Formula IV′:
either X and Z are nitrogen, and Y is carbon, or X and Z are carbon and Y is nitrogen,
A is nitrogen or carbon,
W is nitrogen, carbon, oxygen, or sulfur,
the dashed lines denote the presence or absence of a bond, according to valency,
R₅-R₉, R₁₁-R₁₄, and R₁₉-R₂₁ are independently absent, hydrogen, substituted amino, unsubstituted amino, substituted alkyl, unsubstituted alkyl, substituted aryl, unsubstituted aryl, halogen, hydroxyl, thiol, cyano, nitro-, unsubstituted alkoxy, substituted alkoxy, unsubstituted aroxy, substituted aroxy, unsubstituted heteroaryl, substituted heteroaryl, unsubstituted polyheteroaryl, substituted polyheteroaryl, unsubstituted alkylthio, substituted alkylthio, unsubstituted carbonyl, substituted carbonyl, unsubstituted carboxyl, substituted carboxyl, unsubstituted ester, substituted ester, substituted C₃-C₂₀ cycloalkyl, unsubstituted C₃-C₂₀ cycloalkyl, substituted C₂-C₂₀ heterocyclyl, unsubstituted C₂-C₂₀ heterocyclyl, substituted C₃-C₂₀ cycloalkenyl, unsubstituted C₃-C₂₀ cycloalkenyl, substituted C₃-C₂₀ cycloalkynyl, or unsubstituted C₃-C₂₀ cycloalkynyl,
Rₐ and R_{b} are independently hydrogen, substituted aryl, unsubstituted aryl, substituted heteroaryl, unsubstituted heteroaryl, substituted C₃-C₂₀ cycloalkyl, unsubstituted C₃-C₂₀ cycloalkyl, substituted heterocyclyl, unsubstituted heterocyclyl, substituted alkyl, or unsubstituted alkyl, or —NRₐR_{b} together form a substituted polyheteroaryl, unsubstituted polyheteroaryl, substituted polyheterocyclyl, unsubstituted polyheterocyclyl, substituted heterocyclyl, or unsubstituted heterocyclyl, and
L₁, L₂, and L₃ are independently a bond (single, double, or triple), absent, oxygen, sulfur, substituted amino, unsubstituted amino, unsubstituted alkylene, substituted alkylene, unsubstituted alkyl, substituted alkyl, substituted carbonyl, unsubstituted carbonyl, substituted amido, unsubstituted amido, substituted sulfonyl, unsubstituted sulfonyl, substituted sulfonic acid, unsubstituted sulfonic acid, substituted phosphoryl, unsubstituted phosphoryl, substituted phosphonyl, or unsubstituted phosphonyl.

30. The compound of claim 11, having a structure:

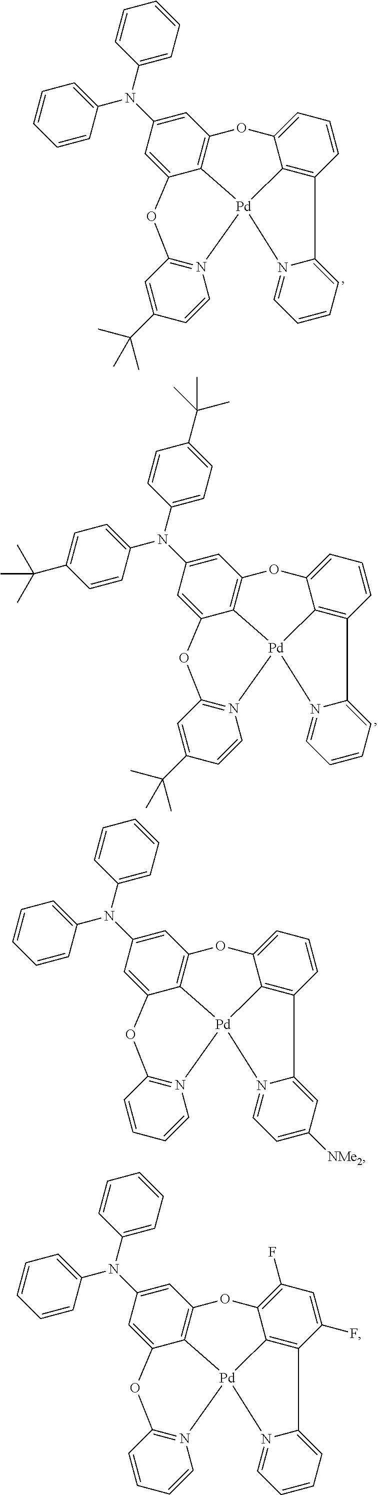

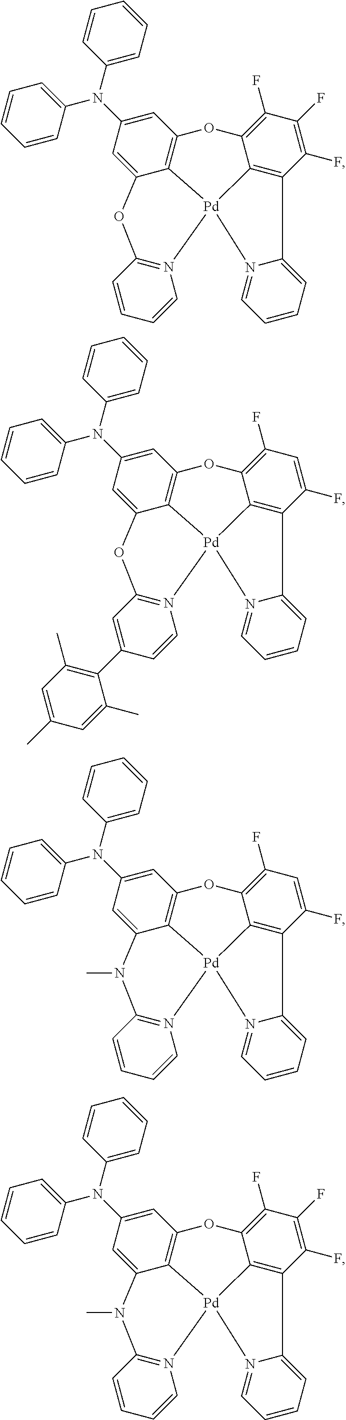

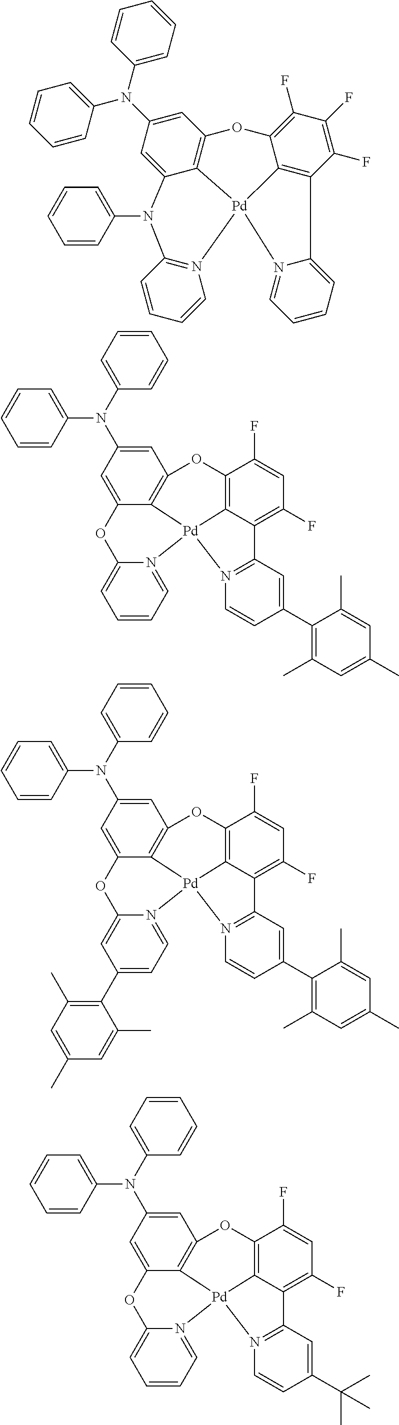

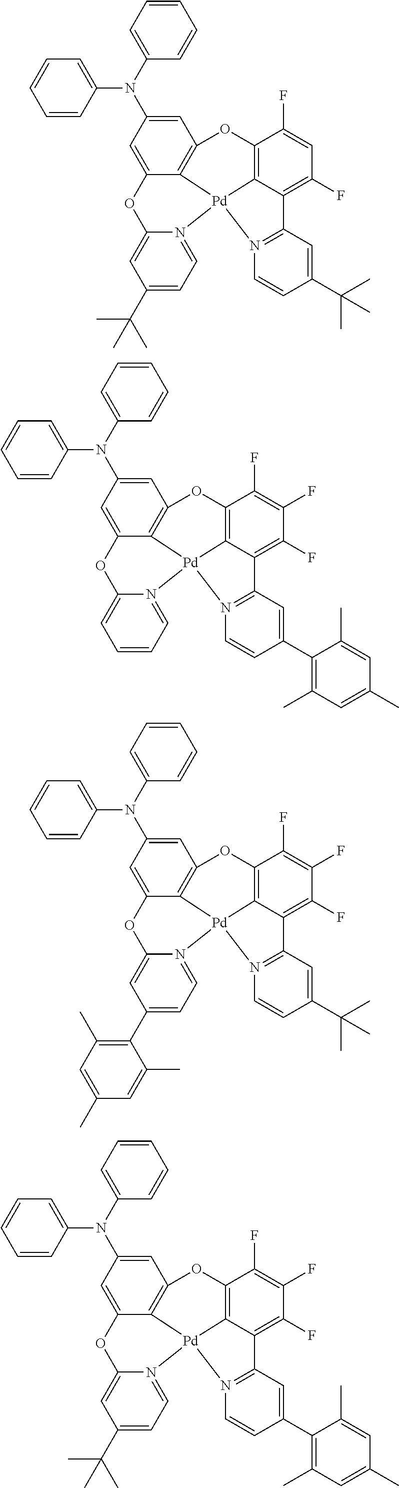

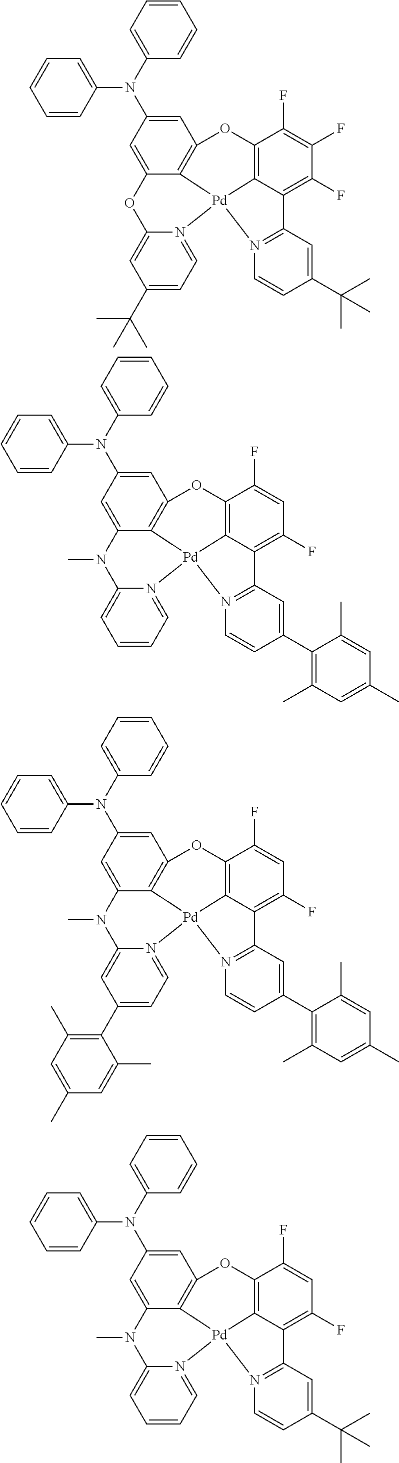

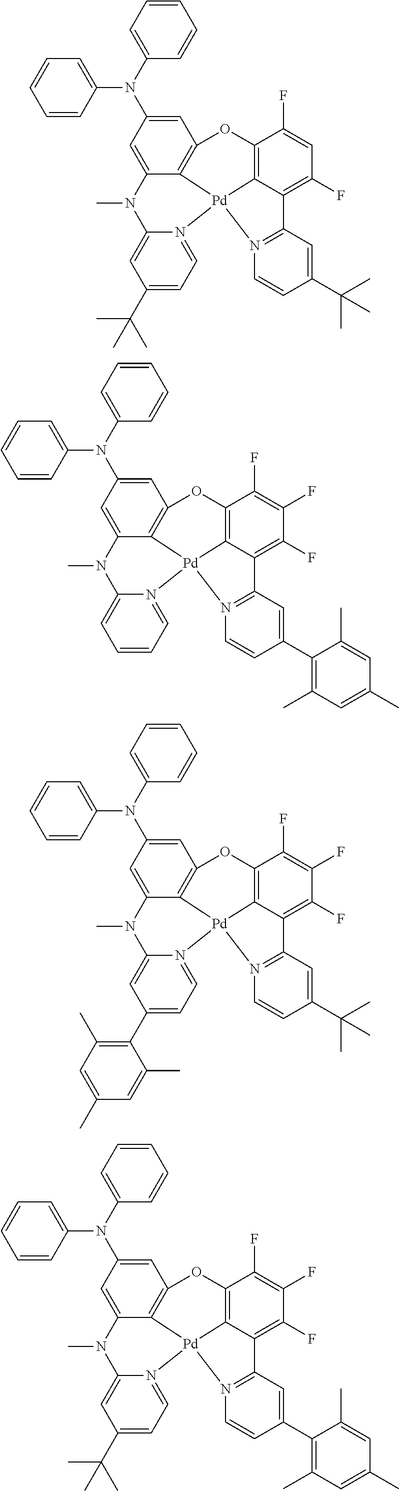

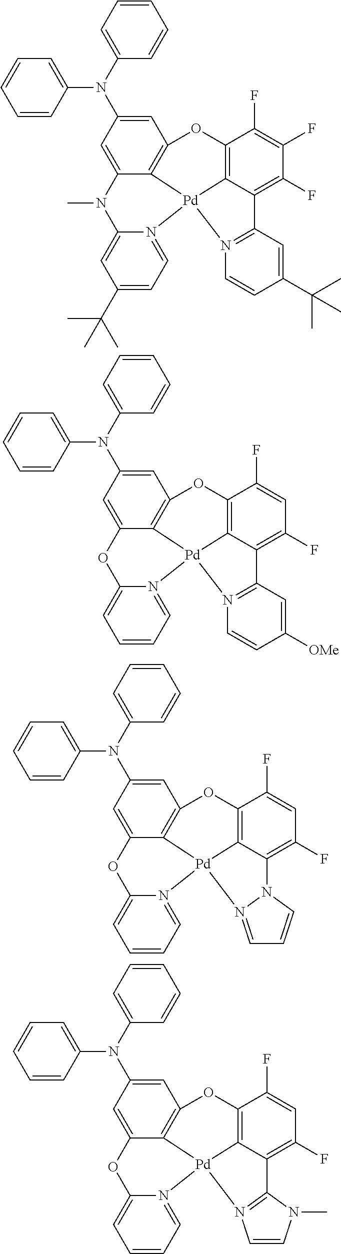

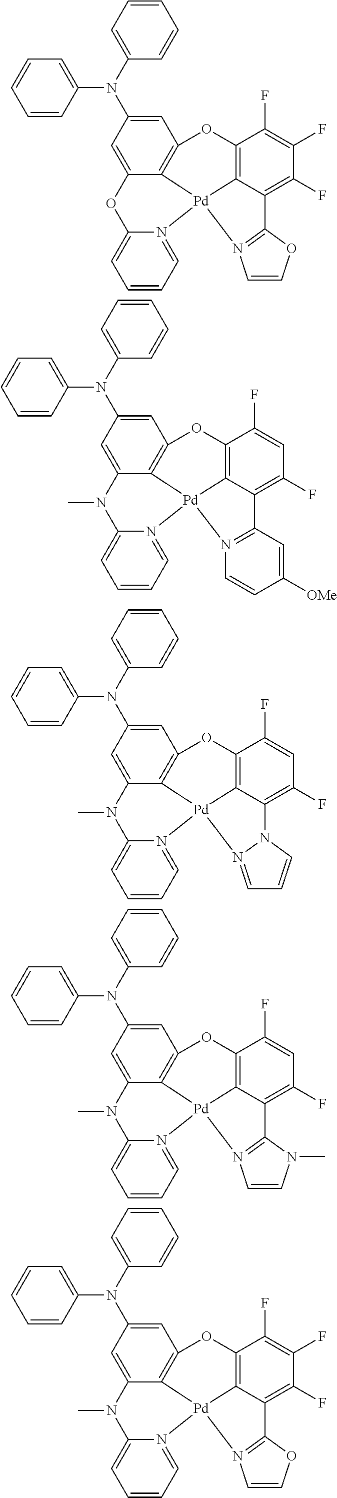

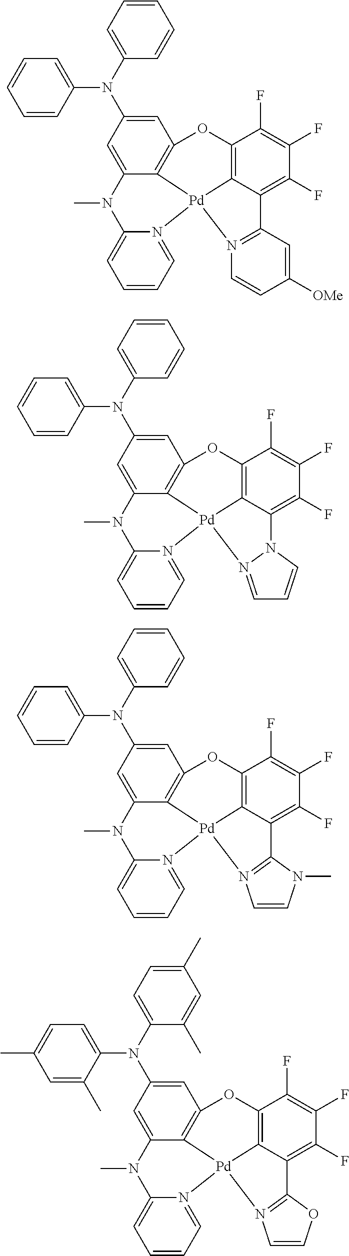

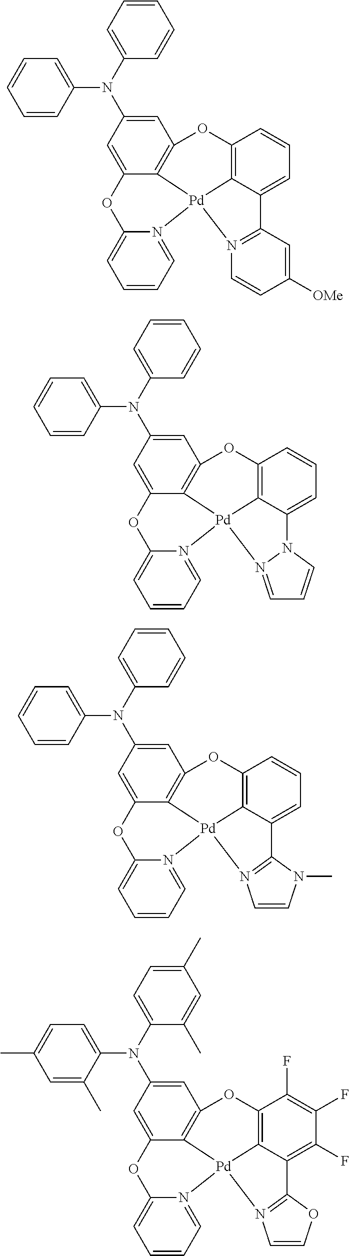

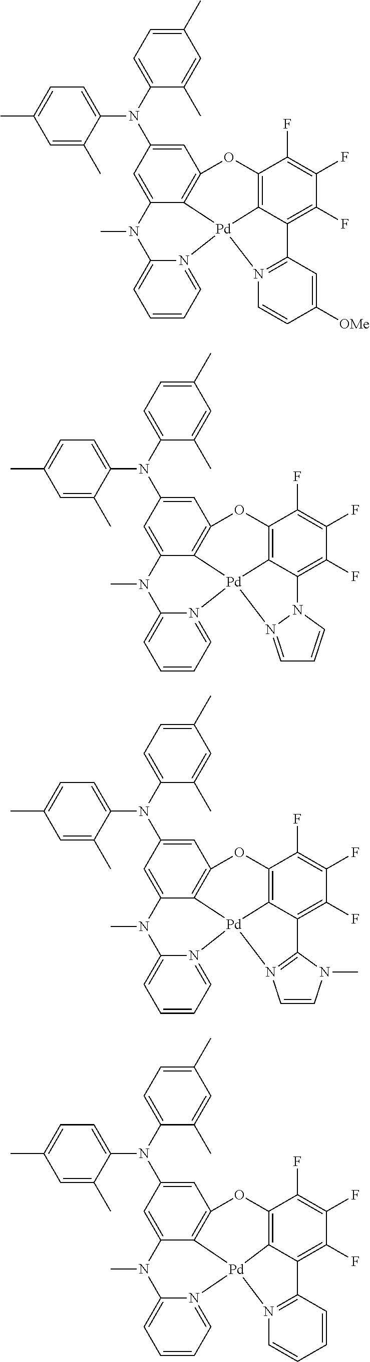

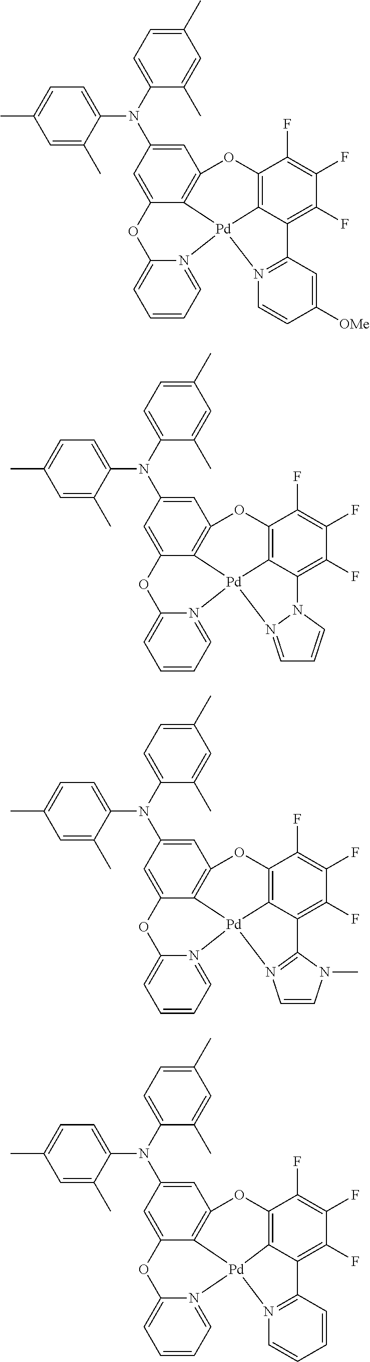

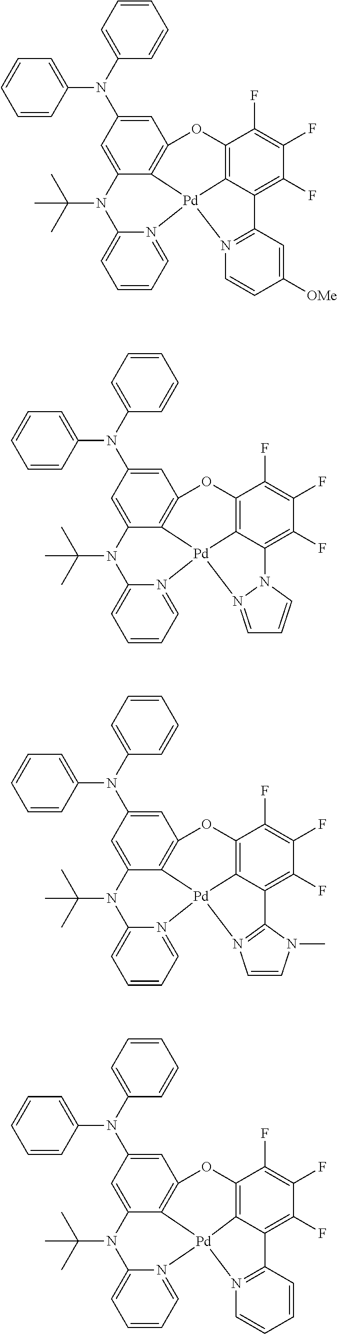

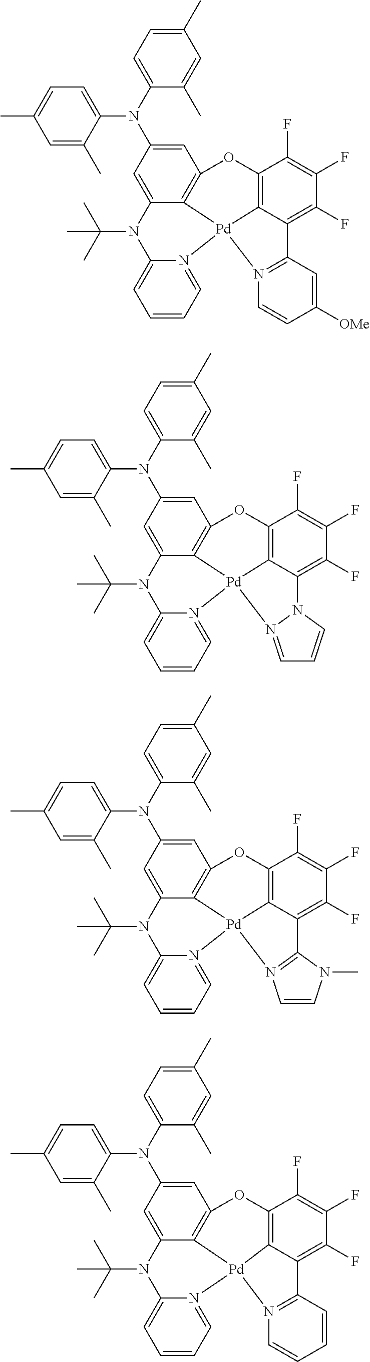

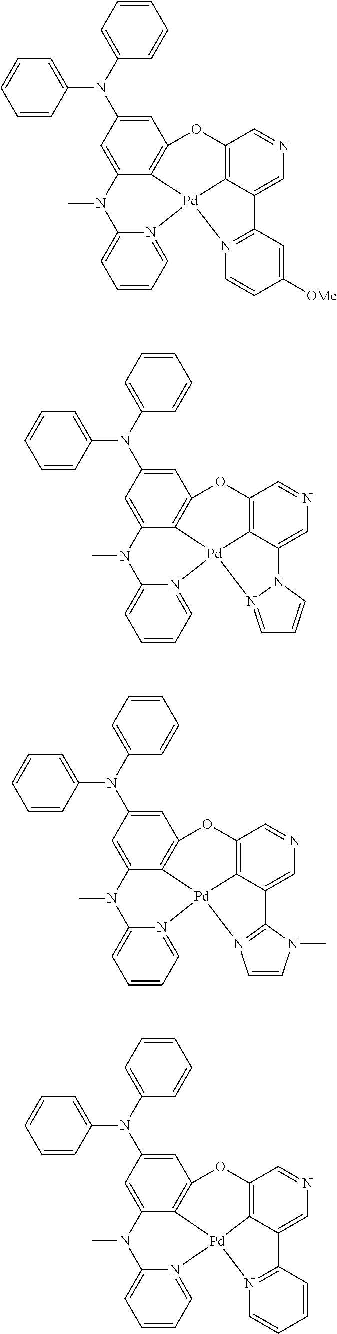

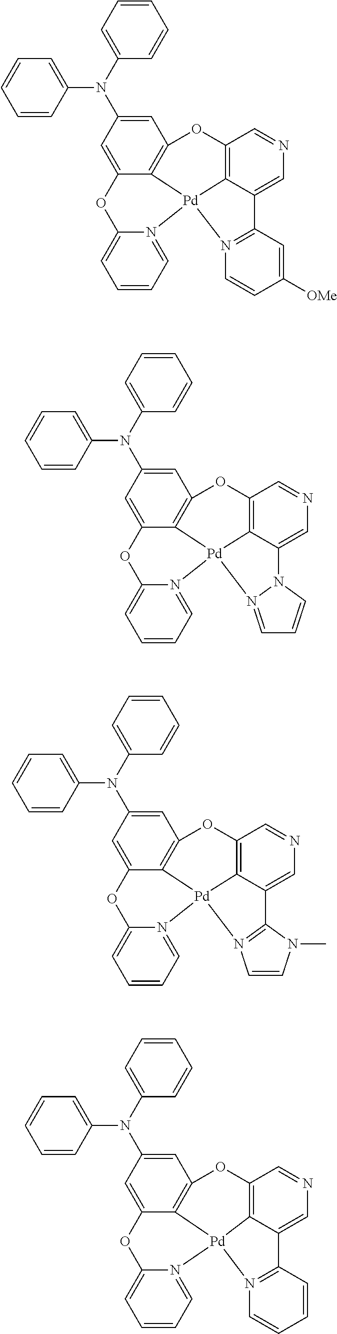

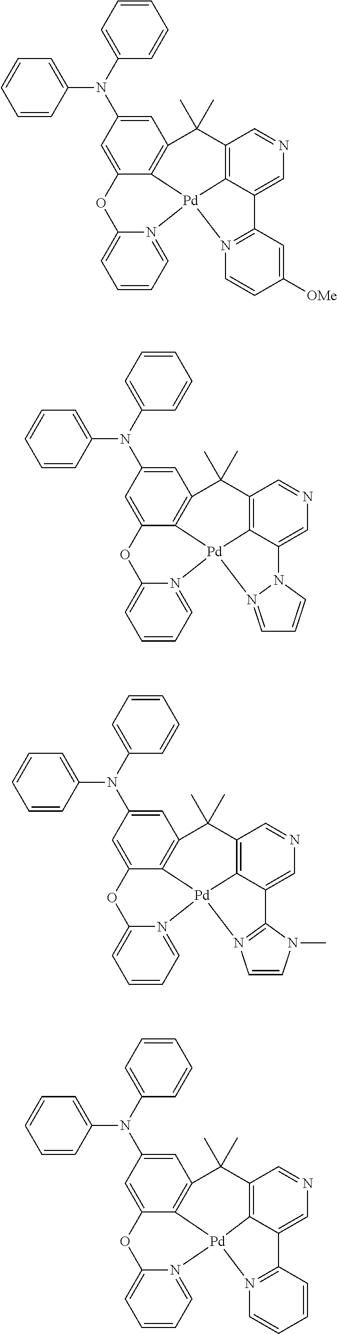

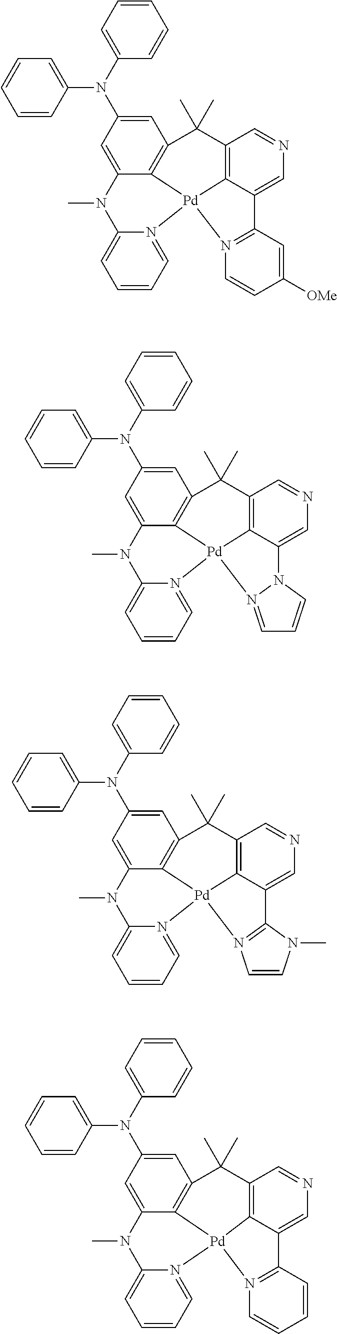

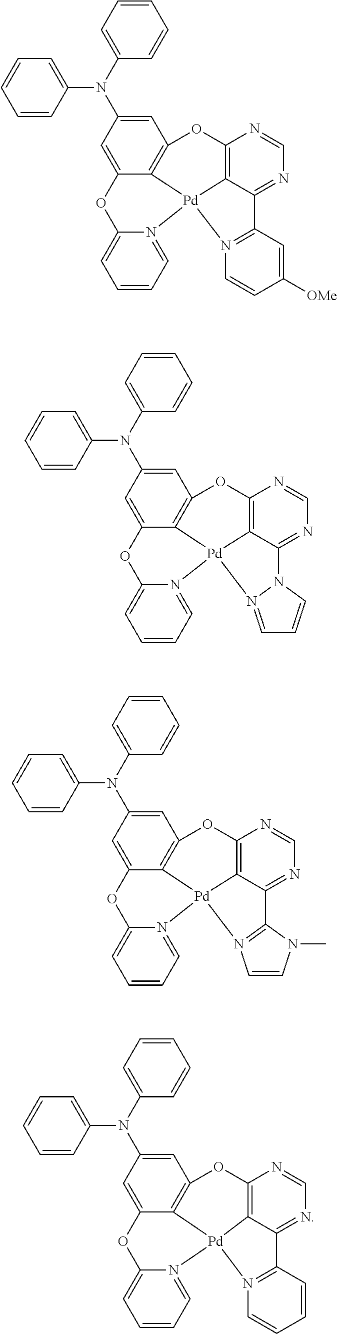

31. The compound of claim 1, having an emission lifetime (i) between 1.0 μs and 10 μs, inclusive, or between 1.1 μs and 8.7 μs, inclusive, in solution, such as 1.1 μs or 8.7 μs; or an emission lifetime (i), between 3.5 μs and 40 μs, inclusive, or between 4.4 μs and 35 μs, inclusive, such as 4.4 μs or 35 μs, in thin films having a thickness between 10 nm and 50 μm, such as between 10 nm and 200 nm.

32. (canceled)

33. The compound of claim 1, having a radiative rate constant between 1.0×10⁵ s⁻¹ and 10.0×10⁵ s⁻¹, inclusive, between 1.0×10⁵ s⁻¹ and 8.0×10⁵ s⁻¹, inclusive, or between 2.0×10⁵ s⁻¹ and 7.0×10⁵ s⁻¹, inclusive, in solution, such as 6.0×10⁵ s⁻¹; or a radiative rate constant between 1.0×10⁵ s⁻¹ and 7.5×10⁵ s⁻¹, inclusive, between 1.0×10⁵ s⁻¹ and 5.0×10⁵ s⁻¹, inclusive, or between 1.5×10⁵ s⁻¹ and 4.0×10⁵ s⁻¹, inclusive, such as 2.2×10⁵ s⁻¹, in thin films, having a thickness between 10 nm and 50 μm, such as between 10 nm and 200 nm.

34. (canceled)

35. The compound of claim 1, having a photoluminescence quantum yield (PLQY) between 10% and 80%, inclusive, in solution (such as organic solution) at room temperature, optionally wherein the PLOY in solution is for an emission maximum between 430 nm and 650f nm, inclusive, such as between 496 nm and 558 nm, inclusive; or
a PLOY between 15% and 65%, inclusive, between 40% and 65%, inclusive, between 45% and 65%, inclusive, between 50% and 65%, inclusive, or between 55% and 60%, inclusive, at room temperature, in thin films having a thickness between 10 nm and 50 μm, such as between 10 nm and 200 nm, optionally wherein PLOY in thin films is for an emission maximum between 430 nm and 650 nm, inclusive, such as between 476 nm and 560 nm, inclusive.

36-41. (canceled)

42. A light-emitting layer comprising the compound of claim 1.

43. An OLED, comprising the light-emitting layer of claim 42.

44. A device, comprising the OLED of claim 43, wherein the device is selected from stationary visual display units, mobile visual display units, illumination units, keyboards, clothes, ornaments, garment accessories, wearable devices, medical monitoring devices, wall papers, tablet computers, laptops, advertisement panels, panel display units, household appliances, or office appliances.

45. (canceled)

46. A device, comprising a light-emitting layer comprising the compound of claim 1, wherein the device has a maximum external quantum efficiency (EQE) between 10% and 40%, inclusive, between 10% and 35%, inclusive, between 15% and 40%, inclusive, or between 15% and 35%, inclusive, such as between 16.4% and 30.3%, inclusive; or a current efficiency (CE) between 30 cd/A and 80 cd/A, inclusive, between 30 cd/A and 75 cd/A, inclusive, between 35 cd/A and 80 cd/A, inclusive, between 35 cd/A and 75 cd/A, inclusive, between 40 cd/A and 80 cd/A, inclusive, or between 40 cd/A and 75 cd/A, inclusive, such as between 44.4 cd/A and 70.1 cd/A, inclusive; or a combination thereof.

47.-48. (canceled)
